(19) United States
(12) Patent Application Publication
(10) Pub. No.: US 2009/0198759 A1
(43) Pub. Date: Aug. 6, 2009

(54) Circuits for computational set theory

(76) Inventor: Robert William Schmieder, Walnut Creek, CA (US)

Correspondence Address: ROBERT WILLIAM SCHMIEDER, 4295 Walnut Blvd., Walnut Creek, CA, 94596, US

(21) Appl. No.: 12/322,722

(22) Filed: Feb. 6, 2009

Related U.S. Application Data
(60) Provisional application No. 61/063,700, filed on Feb. 6, 2008.

(51) Int. Cl. G06G 7/00; G06G 7/28; H03K 19/177; G06F 17/10; H03K 19/20

(52) U.S. Cl. 708/801; 327/334; 326/39; 706/56; 326/104

(57) ABSTRACT

The present invention provides a set of analog circuit modules and procedures for assembling them into circuits that represent fundamental expressions and operations in mathematics, and more specifically to circuits for performing computations on problems formulated as constraints in Set Theory.

In this invention, physical analogues of mathematical sets are realized by the current flowing through electronic circuit devices, or by the voltage across such devices. A circuit assembled from set analogue devices appropriately connected together can generate analogues of the basic operations in Set Theory, such as intersection, union, complement, difference, subset, etc. Using these basic circuit modules, the analogues of arbitrarily complex expressions and operations can be obtained by combination. A complete circuit that is the analogue of Set Theory expressions defining the problem specification can be assembled by requiring the circuit and the Set Theory expressions to have the same topology.

Assuming that some of the sets (input) implemented by the circuit are considered known, the remaining sets (output) can be found by varying the circuit parameters. The output sets so determined are considered the solution to the computational problem.

Computation is considered to be a combination of various cycles of aggregation and evaluation. Aggregation involves the combination of smaller circuit modules hierarchically to form larger modules. Evaluation involves replacing a complex circuit with a simpler one, thereby limiting the demand for more circuits and maintaining the precision at the defined level. This invention comprises a set of basic circuits modules used in aggregation.

The preferred embodiment of this invention is analog electronic circuits, although in principle the circuits can be fabricated using any technology, including non-electronic (e.g., fluidic, optical, magnetic, etc.). Due to the requirements for analog array architecture (which implies large numbers of nonlinear and complex devices), and high performance (which implies high device speed and low power), use of nanoelectronics for individual devices is indicated.

The usefulness of this invention is associated with its potential for very high efficiency computation by using instances of sets as the data elements. Appropriate applications of this invention will be conventionally intractable problems, high-performance simulation, and control.

### CROSS REFERENCE TO RELATED APPLICATION

This application claims priority of U.S. Provisional Patent Application No. 61/063,700, filed 06 Feb. 2008, the entire contents of which is hereby incorporated by reference.

### FEDERALLY SPONSORED RESEARCH OR DEVELOPMENT

Not applicable

### SEQUENCE LISTING, A TABLE, OR A COMPUTER PROGRAM

Not applicable

### LISTING COMPACT DISC APPENDIX

Not applicable

CONTENTS

| | |
|---|---|
| BACKGROUND - FIELD OF THE INVENTION | 5 |
| BACKGROUND - PRIOR ART | 5 |
| BRIEF SUMMARY OF THE INVENTION | 9 |
| BRIEF DESCRIPTION OF THE FIGURES | 11 |
| DETAILED DESCRIPTION OF THE INVENTION | 13 |
| INTRODUCTION AND DEFINITIONS | 14 |
| Overview of the invention | 14 |
| Computation defined | 15 |
| Data defined | 16 |
| Dynamical data | 17 |
| Set Theory | 18 |
| Set-level operations | 19 |
| Chain set expressions | 20 |
| Logical operators | 21 |
| Computational Set Theory | 21 |
| Computers for Computational Set Theory | 22 |
| Devices defined | 23 |
| Analog devices | 24 |
| 1-terminal devices | 24 |
| 2-terminal devices | 24 |
| 3-terminal devices | 25 |
| Data flow | 25 |
| Current-voltage duality | 25 |
| Control devices | 26 |
| Switches | 26 |
| Sensors | 26 |
| Controls | 26 |
| Clones | 26 |
| Circuits defined | 27 |
| Modularity | 27 |
| Characteristic functions | 27 |
| Oscillatory states | 28 |
| DEVICE AND CIRCUIT ANALOGUES OF SETS | 29 |
| Physical variables of devices | 29 |
| Device analogues of sets | 30 |
| Modal device-set analogues | 31 |
| Non-uniqueness of device-set analogues | 32 |
| Non-electrical analogues | 32 |
| Example: Modal 2-terminal device analogues | 33 |
| Device analogues as input-output relations | 34 |
| Discontinuous behavior | 35 |
| Hysteresis | 35 |
| Cyclic sets | 36 |
| Circuit analogues of sets | 37 |
| Modal circuit analogues | 37 |
| Stability | 38 |
| Accessibility | 39 |
| Discrete sets | 40 |
| Multi-interval sets | 41 |
| Device parameter analogue sets | 42 |
| Analog precision | 43 |
| Circuit analogues of the empty and universal sets | 44 |
| Circuit analogues of logical implication | 45 |
| Circuit analogue of the membership relation | 46 |
| Ordered vs. unordered sets | 47 |
| Higher dimension sets and dimensional reduction | 48 |
| Meaning of the analogue symbol [symbol] | 48 |
| CIRCUIT ANALOGUES OF SET OPERATIONS | 49 |
| The fundamental set operations | 49 |
| Combination sets | 50 |
| Boolean sets | 50 |
| Analogues rigorously defined | 51 |
| Circuits and sets | 51 |
| Simple analogues | 51 |
| Compound analogues | 51 |
| Multiple devices | 52 |
| Operation: Intersection | 53 |
| Operation: Union | 55 |
| Operation: Complement | 57 |
| Operation: Set difference | 59 |
| Operation: Symmetric set difference | 59 |
| Operation: Equality | 59 |
| Operation: Subset | 60 |
| Operation: Proper subset | 61 |
| Summary: Current-mode circuit analogues | 62 |
| Summary: Voltage-mode circuit analogues | 62 |
| Summary: Transfer modules | 62 |
| Summary: Dataflow modules | 62 |
| ASSEMBLING SET ANALOGUE CIRCUITS | 63 |
| Assembling analogue circuits | 63 |
| Circuits: Tautologies | 64 |
| Circuits: Device-level | 65 |
| Circuits: Canonical | 66 |
| Circuits: Hierarchical | 67 |
| Circuits: Flattened | 68 |
| Circuits: Modular | 69 |
| Circuits: Boolean | 69 |
| Circuits: Logic flow | 70 |
| Circuits: Set bits | 71 |
| Circuits: Mixed-mode | 72 |
| COMPUTATION WITH SET ANALOGUE CIRCUITS | 73 |
| The process of computing | 73 |
| Possible-value computing | 74 |
| Example: A simple fixed constraint | 74 |
| Circuit analogues of solutions | 75 |
| Intractable problems | 76 |
| Example: Set packing | 76 |
| Example: Set splitting | 78 |
| Infinite sets | 79 |
| Dynamic constraints | 80 |
| Algebras | 81 |
| Preconditioning | 81 |
| Example: Interval set algebra | 82 |
| Example: Fuzzy set algebra | 82 |
| Set-level computation | 83 |
| Set-level evaluation | 83 |
| Distributed computing and emergent behavior | 84 |
| IMPLEMENTATION OF THIS INVENTION | 85 |
| The language | 85 |
| Computational tasks | 86 |
| Design procedure | 87 |
| Design issues | 87 |
| Purely graphical transformations | 88 |
| Preferred embodiment | 89 |
| Analog circuits | 90 |
| Nanoelectronics | 91 |
| Nanoelectronic devices | 91 |
| Nanoelectronic circuits | 91 |
| Advantages | 92 |
| Disadvantages | 92 |
| Alternative technologies | 93 |
| Programming | 93 |
| DISCUSSION | 94 |
| The nature of set analogue computing | 94 |
| Fidelity of the analogue | 96 |
| Modal logic and modal circuits | 96 |
| Advantages | 97 |
| Disadvantages | 97 |
| Performance | 98 |
| Appropriate applications | 99 |
| Mathematical applications | 100 |
| Conclusion | 101 |
| BIBLIOGRAPHY | 102 |
| CLAIMS | 104 |
| FIGURE REFERENCES FOR CLAIMS | 109 |
| ABSTRACT | 110 |

### BACKGROUND

1. Field of the Invention

This invention relates to circuits used for performing mathematical computation, and more specifically to circuits for representing fundamental expressions and operations in Computational Set Theory.

2. Prior Art

One of the most extensive uses of computers is for computation: the determination of unknown quantities in terms of known quantities. Electronic computers have special value for computation because of their low cost and flexibility. Unfortunately, there are large classes of computations that cannot be done with available computers; these problems are part of a larger group of mathematical problems referred to as intractable.

Computers can fail to solve problems for a variety of intrinsic and practical reasons, including overly restrictive boundary conditions, excessive numbers of boundaries (e.g., multi-dimensional grids), combinatorial explosion (e.g., unrestricted branching), accumulation of unacceptable error, discontinuous variables, unknown dynamics, data that are ambiguous, vague, incomplete, dirty, fuzzy, etc., excessive unused precision, excessive signal propagation times, large numbers of sensors/actuators, stringent limitations on size, weight, power, speed, etc.

Many of the reasons for failure can be traced to the use of numbers to represent data. Numbers are used because they are system-independent and they enable arbitrary precision. However, a general principle in computation is that the more closely the computer resembles the structure and function of the system defining the problem, the more efficient (=fast) it will be. Unfortunately, digital computers, which use circuits with a restricted set of stable states to represent numbers, have no structural similarity to the systems defining the computations, hence are highly inefficient. Indeed, in a digital computer almost all the time almost all the data is doing nothing at all (it is merely stored). Thus, a digital computer, while being convenient, is actually an extremely inefficient computer. Nature does a much better job of computing, if efficiency is the criterion.

It should be noted that there are no numbers in Nature; natural processes, which are often described as computations, proceed without any numbers. A computer that does not use numbers is called an analog computer. Analog computers are common, although they are not always called computers. Any system that has structure and function similar to the defining system but does not use numbers can be considered an analog computer, and the more similar it is to the defining system, the faster it will be. Thus, a computation involving, say, 10000 boundaries at which some conditions must be satisfied will execute far faster if these conditions can be satisfied by hardware in which they are satisfied electrically, rather man by manipulating date using a set of instructions. This argues forcefully for analog computers with application-specific architectures, which is the domain of this invention.

The original electronic analog computers, developed during the mid-20^{th} Century, were large, configurable-architecture, single-purpose circuits used for tasks such as trajectory calculations [Scott, 1960]. Modern analog computers are integrated circuits, often with modular architecture that enables considerable programmable re-configurability and adaptive capability. They are therefore far more powerful than the original analog computers, and in fact have the potential for successfully attacking problems conventionally considered intractable on digital computers.

In the past decade, considerable progress has been made on designing and fabricating analog circuit arrays: integrated circuits containing a set of functional modules, accessible to outside connections, and capable of being configured by using internal switches. For example, Hasler and colleagues at the Georgia Institute of Technology [Twigg, et al., 2008] have developed Field Programmable Analog Arrays (FPAA) containing 42 configurable analog blocks (CAB); chips containing as many as 1000 CABs are quite feasible. Such chips would enable development of application-specific analog array computers, which are projected to have computational capability up to 100,000 times equivalent digital computers.

In computation, an important aspect is precision. Digital computers have precision fixed by hardware connectivity (e.g., 64-bit words), although through software this precision can be extended arbitrarily, with concomitant increase of computation management overhead. A difficult but important goal is adaptive precision, in which the hardware imposed-precision is adaptable. Analog computers offer a distinct advantage in this regard: adjusting the precision of an analog signal can be done by adjusting a filter using analog circuits, which is not only intrinsically faster than software and can be implemented in parallel within a large computer, but also can be locally adjustable within the machine.

Among the important classes of computational problems that are often intractable are problems expressed in the language of Set Theory in which the input sets are allowed to increase in size. Often the number of steps necessary to determine the output sets increases as a high power (even exponentially) of the input size, and eventually (sometimes rapidly) become impossible due to reasons listed earlier.

Set Theory refers to a formal system defined with first-order logic augmented with a single non-logical operation (membership ∈), from which any (symbolic) mathematical system (such as calculus, geometry, etc.) can be formulated. It therefore provides a universal formalism for computation: any problem expressible mathematically can be cast into the formalism of Set Theory; the problem typically takes the form of collections of sets related by explicit constraints. Assuming some of the sets are known, the computational task is to determine the sets that are not known.

It is common in such problems that we are not interested in the detailed, exact determination of the output sets, but only in an approximation, or a subset of the exact sets, and we are willing to accept some imprecision for significant computational speedup. This is essentially a topological concept: we seek neighborhoods of data (i.e., sets) as functions of other neighborhoods (other sets). We will exploit this concept in this invention, allowing loss of detail in maintaining a defined level of precision, but obtaining in return a vast speedup that can make otherwise intractable problems computable.

A central requirement on any practical computer system is that it be scalable—it can be built up to arbitrary size by combining smaller parts into larger parts. Fortunately, many if not most computational problems of interest can be analyzed into a relatively small number of component pieces, and the number of different pieces is small. For instance, the operations of addition, subtraction multiplication, division, exponentiation, and negation provide all the operations for implementing almost all numerical algorithms. This suggests that we should seek an analog computer that can be built from standard modules by connecting them in the same way (or more accurately, a similar way) as the system, and in fact several such systems have been invented. For instance, Shannon's General Purpose Analog Computer [Shannon, 1941] uses just 4 operations: constant, integration, addition, and multiplication. Conventional analog computers use modules for operations in calculus: differentiation, integration, plus addition, multiplication, etc. In another patent by the present author [Schmieder, 2008], a set of analog modules was defined representing geometric pieces of a 3D ribbon structure used to define chaotic dynamical systems. These pieces provide a complete set of analog modules for a general purpose (analog) computer. The present invention provides a set of modules appropriate for Set Theory expressions, and constituting a complete set for general purpose computing.

The implied need for large numbers of modules suggests that limitations will be encountered with microelectronic VLSI technology. Nanoelectronics offers a substantial advantage here: smaller device size, lower power, and monolithic compound devices with complex transfer functions [Dragoman et al., 1999]. Using complex devices as the basic logic element offers increase in logic density, increased logic throughput, reductions of the number of devices, and simplifications in design. In addition, the general aspect of nanoelectronic analog signal processing as the fundamental computational process is consistent with reduced (or adaptable) precision appropriate for computation.

Thus, the present goal of practical general-purpose electronic computers for computational Set Theory is consistent with VLSI analog array technology [Geiger, et al., 1990; Hurst, 1999; Liu, et al., 2002]. Implementation of such computers with nanoelectronics will provide significantly increased advantages in design and performance.

What is needed to realize these goals is a set of basic standard modules that can be connected together, and a procedure for assembling a circuit that is the analogue of the computational problem. It is this need to which this invention is directed, and for which this invention provides one practical approach.

### BRIEF SUMMARY OF THE INVENTION

This invention provides analog circuits for implementing computational Set Theory. It comprises a set of simple, standard circuit modules that are electronic analogues of fundamental operations in Set Theory, and a procedure for assembling these modules into complete circuits that are electronic analogues of arbitrarily complex Set Theory expressions. The task of finding a solution to a problem in Set Theory is thereby converted to the task of configuring an electronic circuit. Because the circuits have behavior that corresponds one-to-one to the sets, the circuit is guaranteed to provide the solution of the problem, and it is guaranteed to be correct and unique.

Problems are very often expressed as constraints between sets. Set constraints are conventionally expressed using a small set of basic operations expressing how two or more sets can be combined to form new sets. The simplest and most common of these operations are: intersection, union, complement, set difference, symmetric set difference, set equality, subset, and proper subset. Note that the last three of these generate the Boolean set: {TRUE, FALSE}.

This invention provides simple circuit modules that generate the analogues of the set operations listed above. For instance, given devices that are the analogues of sets A and B, connecting the devices in series gives a compound device that is the analogue of the intersection A∩B. Using circuit modules such as these, we can hierarchically assemble a complete circuit that is the analogue of an arbitrary set of constraints between the sets, hence a mathematical problem. Solution of the problem, i.e., computation, is performed by determining unknown sets in terms of known sets.

Preliminary to using this invention, the computational problem must be expressed in the language of Set Theory. This provides a specific set of expressions, some of which are known (inputs) and others are not known (outputs), coupled together with various expressions such as intersection, union, etc. This constitutes the problem specification.

The first step in using this invention is to associate an electronic device with each set in the specification. This might be done in any of several ways, generally called modalities. Thus, the current through a particular device might be the analogue of a particular set; the device is being used in current-mode. The voltage across the same device might be the analogue of another set; here the device is being used in voltage-mode.

The second step in using this invention is to connect the devices to one another with the same connectivity (topology) as the Set Theory expressions. At the lowest level, the connected devices implement the analogues of the basic relations listed above (intersection, etc.). The complete circuit can be assembled hierarchically using modules previously defined. This process produces a circuit that is the analogue of the problem specification.

The third step in using this invention is to vary some parameters of the complete circuit while observing others. Suppose the circuit involves sets X as known and sets Y as unknown We vary parts of the circuit, searching for sets Y for which the circuit is stable, i.e., that Y satisfies the set constraints in the problem specification. The sets Y constitute the “solution” to the problem, i.e., the result of a computation.

This invention assumes the devices and circuits are used in analog mode; there are no numbers anywhere in this invention. In analog mode, the entire circuit is involved in performing the computation, hence the present invention offers a path to extremely high efficiency (=speed).

It is assumed that the states of the devices defining the sets are stationary—they are stable states of the devices and circuits. Computation implies finding new stable states; a dynamical system can be represented as a series of stable states.

In summary, this invention provides a set of simple, standard analog circuit modules that implement the fundamental operations in Set Theory, and a procedure for assembling them to form a complete circuit that is an electronic analogue of any mathematical problem.

These and other objects, features, and advantages of the present invention will become more apparent upon reading the following specification in conjunction with the accompanying drawings.

### BRIEF DESCRIPTION OF THE FIGURES

FIG. 1 shows an overview of this invention.

FIG. 2 shows examples of static data appropriate to this invention.

FIG. 3 shows examples of dynamic data appropriate to this invention.

FIG. 4 shows examples of individual devices used to implement this invention.

FIG. 5 shows examples of control devices and circuits used to implement this invention.

FIG. 6 shows examples of device characteristic functions.

FIG. 7 shows how sets can be generated by device characteristic functions.

FIG. 8 shows how discontinuous and hysteretic sets can be generated.

FIG. 9 shows how cyclic sets can be generated.

FIG. 10 shows how different sets can be generated with a single device or circuit.

FIG. 11 shows the set is affected by the stability of a circuit.

FIG. 12 shows how a simple circuit can produce a variety of discrete sets.

FIG. 13 shows how a simple circuit can generate multi-interval sets.

FIG. 14 shows how the value of a device parameter can affect the sets.

FIG. 15 shows how to conceptualize analog precision.

FIG. 16 shows circuit analogues for the null and universal sets Ø,1.

FIG. 17 shows circuit analogues of logical implication S→β→S′.

FIG. 18 shows a circuit analogue of the set membership relation x∈X.

FIG. 19 shows circuit analogues of an unordered set of sets {A,B}.

FIG. 20 shows circuit analogues of the set intersection A∩B.

FIG. 21 shows circuit analogues of the set union A∪B.

FIG. 22 shows circuit analogues of the set complement 1\A.

FIG. 23 shows circuit analogues of the set difference A\B.

FIG. 24 shows circuits analogues of the symmetric set difference A÷B.

FIG. 25 shows circuit analogues for set equality A=B.

FIG. 26 shows circuit analogues for subset A⊂B.

FIG. 27 shows circuit analogues for proper subset A⊂B.

FIG. 28 shows the current-mode circuit analogues for all the fundamental operations.

FIG. 29 shows the voltage-mode circuit analogues for all the fundamental operations.

FIG. 30 shows all the fundamental circuit analogues as input/output modules.

FIG. 31 shows all the fundamental circuit analogues as dataflow modules.

FIG. 32 shows examples of circuit aggregation.

FIG. 33 shows examples of circuit analogues of tautologies.

FIG. 34 shows a examples of device-level circuit analogues.

FIG. 35 shows a device-level canonical circuit analogue of (A∪B)\C)∩D.

FIG. 36 shows a device-level hierarchical circuit analogue of A\X⊂(B∪X)∩C.

FIG. 37 shows a device-level flattened circuit analogue of (E÷F)\G⊂(A∩B)∪(C\D).

FIG. 38 shows a device-level data module circuit analogue.

FIG. 39 shows a device-level Boolean circuit analogue of (A∪X)\B≠Ø, B⊂X∩C.

FIG. 40 shows device-level logic flow circuit analogues.

FIG. 41 shows circuit analogues of set bits.

FIG. 42 shows a circuit analogues of a 4-member ordered set.

FIG. 43 shows examples of mixed-mode circuit analogues.

FIG. 44 shows a circuit analogue of A∪X⊂B.

FIG. 45 shows a circuit analogue of X⊂B|A⊂B.

FIG. 46 shows a circuit analogue of the intractable problem SP3.

FIG. 47 shows a circuit analogue of the intractable problem SP4.

FIG. 48 shows examples of circuit transformations that add components.

FIG. 49 shows examples of circuit transformations that remove components.

FIG. 50 shows examples of circuit transformations that move and combine components.

### DETAILED DESCRIPTION OF THE INVENTION

This part of the specification of this invention is organized as follows:

Introduction and Definitions
Overview, definition of computation, static and dynamic data, Computational Set Theory, devices, data flow, circuits, modularity, stability.

Device and Circuit Analogues of Sets
Representation of sets with devices and circuits, modal analogues, discontinuous and hysteretic behavior, discrete and interval sets, analog precision, formalism.

Circuit Analogues of Set Operations
Representation of Set Theory operations with circuits, combining sets, Boolean sets, the fundamental operations and their circuit analogues, summaries.

Assembling Set Analogue Circuits
Various forms of circuits representing sets as operations: tautologies, device-level, canonical, hierarchical, flattened, modular, Boolean, logic flow, set bits, mixed-mode.

Computation with Set Analogue Circuits
Aggregation/evaluation computing, possible-value computing, circuit analogues of solutions, intractable problems, infinite sets, dynamic constraints, algebras, set-level computation, distributed computing.

Implementation of this Invention
The language, tasks, design procedure, graphical transformations, analog nanoelectronics, programming.

Discussion
The nature of set analogue computing, fidelity of the analogue, modal logic and modal circuits, advantages and disadvantages, performance, appropriate applications, mathematical applications, conclusion.

Bibliography

### Introduction and Definitions

We provide here some basic background on computation, data, Set Theory, computers, electronic devices, and circuits necessary for a full understanding of this invention. Part of our motivation here is to define terms used in this specification of the invention, and part is to highlight the unique nature and usefulness of this invention.

The material in this section is not part of this invention per se, but is part of the foundation necessary to understand it and implement it in practice. This invention is based on certain mathematical and physical relationships that have not been fully documented, hence a considerable portion of this specification is devoted to the foundations of the subject.

### Overview of the Invention

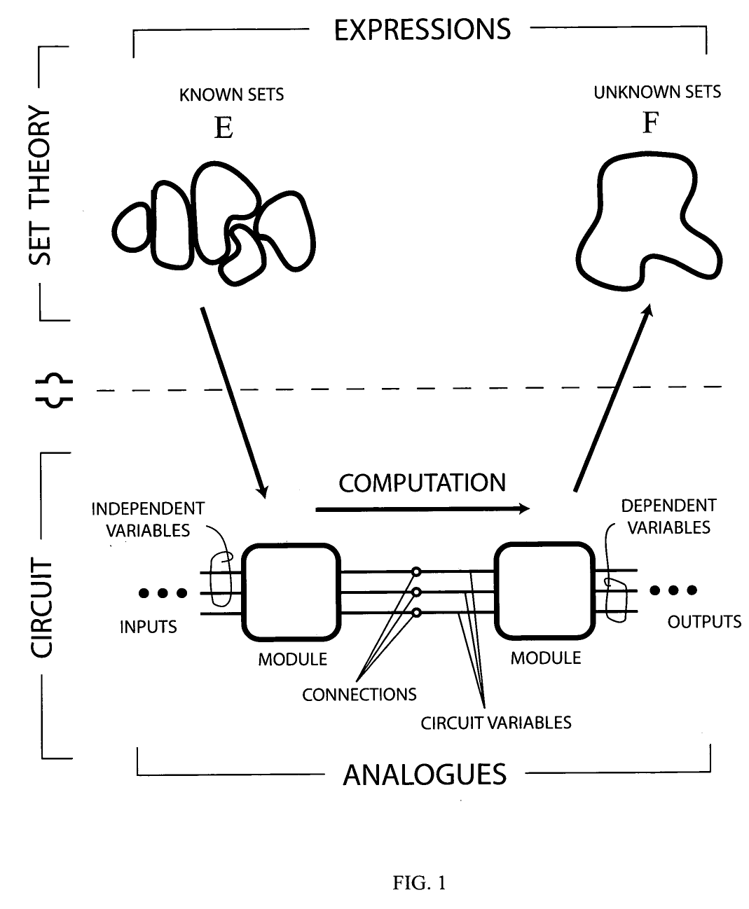

FIG. 1 shows an overview of the core concept of this invention.

The invention associates an electronic circuit, comprised of modules, with a problem expressed in the language of Set Theory. This association is an analogue relationship, in which the circuit has states that correspond one-to-one with the members of sets and with set operations. The character [symbol] expresses this analogue relationship; it associates a physical electronic circuit with a purely mathematical expression, implying the correspondence of the physical system with the mathematical system.

The invention is predicated on the ability to resolve the mathematical problem into a collection of fundamental, relatively simple, standard pieces, and to associate a circuit fragment with each piece. With an inventory of such pieces, we can assemble any arbitrary mathematical expression, together with a complete circuit that is the analogue of that expression. This process is done by connecting the circuit fragments in the same topology (connectedness) as the mathematical expression.

Once a circuit analogue of a mathematical problem is assembled, we can use it to solve problems by setting certain parameters to represent known values and sets, and varying the circuit variables to determine other values and sets. The circuit topology ensures that the circuit is a faithful analogue of the mathematical expression.

This invention thus constitutes a computer, built as an analogue to a problem.

### Computation Defined

Computation is transformation of data. A computational problem is specified by defining a transformation. We define the data before transformation as input data, and the data after transformation as output data. Given the input data and the transformation, the output data is the solution to the problem. A computer is a machine that associates internal states with the data, and uses its structure and processes to perform the transformation. An electronic computer associates electronic signals (voltages, currents, etc.) with the data, and implements transformations of those data. The data defines the class of the computer; it must be able to represent and process data of a defined class. Computers of one class cannot process data of a different class.

Computation can be described as a sequence of two kinds of procedures: aggregation and evaluation. Aggregation is the joining of individual pieces to form a compound structure. An example is the expression E=2−(3+1)/4, which is composed of pieces (digits and operations). Evaluation is the replacement of a compound structure with a (usually simpler) structure. Thus, the expression E evaluates to 1. Aggregation increases the dimensionality of the sets; evaluation reduces dimensionality. Aggregation enables us to include arbitrary complexity; evaluation enables us to keep the processing system finite, and to interpret the final result.

This invention involves primarily the aggregation part of computation. Evaluation will be discussed briefly to help make clear the procedure for developing circuits capable of performing computation and providing examples of the procedure.

### Data Defined

Data has various meanings, of which the following are important to this invention:

(1) Numbers;

(2) Values of physical variables in a machine.

(3) Values constituting a human-important concept;

The first meaning is the most common way of conceptualizing and representing data; it is often believed to be synonymous with data. However, numbers are neither necessary nor always desirable for computation. In particular, there are no numbers in Nature—processes that can legitimately be called computation have no intrinsic need for numbers.

The second meaning is the one used in this invention. The states of a physical system (the “machine”) are data, and transformations of those states constitutes computation.

The third meaning applies to any form of the values—it is not necessary that they be in any concrete form. These values are present in the embodied mind, independent of any physical or mental representation. It is this meaning that we seek as the goal of computation.

Data is naturally separated into discrete data (having a finite set of disjoint values) and continuous data (having an infinite set of connected values). Discrete data have isolated values, e.g., bits {a,b}, multi-bits {a,b,c, . . .}, etc. Continuous data can have values in intervals, e.g., [a,b]. Computers that store and process discrete data are called digital computers, while computers that store and process continuous data are called analog computers.

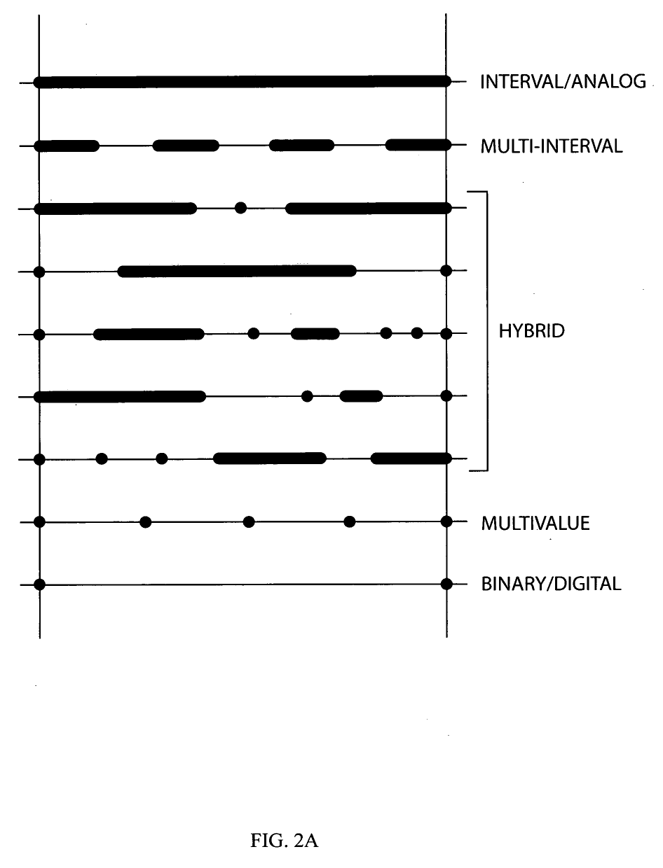

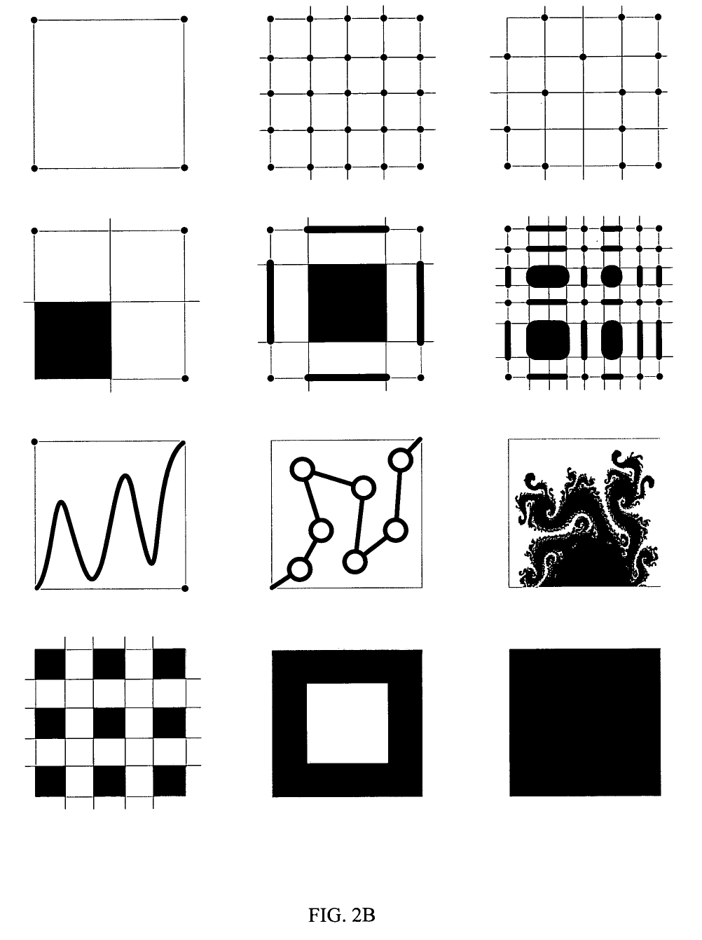

FIG. 2 shows data types appropriate to this invention.

FIG. 2A shows examples of 1D data. The wide lines indicate the values or intervals that are possible values for the device; values between the lines imply the device is unstable. Dots are meant to indicate a discrete value, while extended lines indicate intervals.

In this invention, data can have an arbitrary combination of discrete and continuous parts. For instance, {a,[b,c],d,e,[f,g],[h,i],j}, with 4 discrete values and 3 interval values, is a valid data class for this invention. Each class of data defines a corresponding class of computer. For instance, data of the form {a,[b,c],d,e} defines one class of computers, while data of the form{a,[b,c],[d,e]} defines another class. Computers operating with different data classes operate on completely different computational schemes: the two classes {a,[b,c],d,e} and {a,[b,c],[d,e]}are as different from each other as binary data {a,b} is from continuous data [a,b]. For simplicity, all data can be considered as intervals, since the interval [a,a] is the same as the discrete value a.

FIG. 2B shows examples of 2D data. The examples range from double-binary to double-interval. Any patterning of the 2D double interval defines a data class, hence a computer class.

Various computers have been designed and proposed as general-purpose computers, both digital and analog. However, no general-purpose computers have been developed capable of representing and manipulating data containing both discrete and continuous parts. This invention provides one path to realization of such a hybrid computer.

### Dynamical Data

Data is conceptualized in this invention as being static. However, a computation, i.e., a transformation of a value, produces a new value, and repeated transformations can produce a series of values, which therefore can be considered a time-dependent value. For a fixed set, the allowed values are restricted to the given set, but may vary arbitrarily.

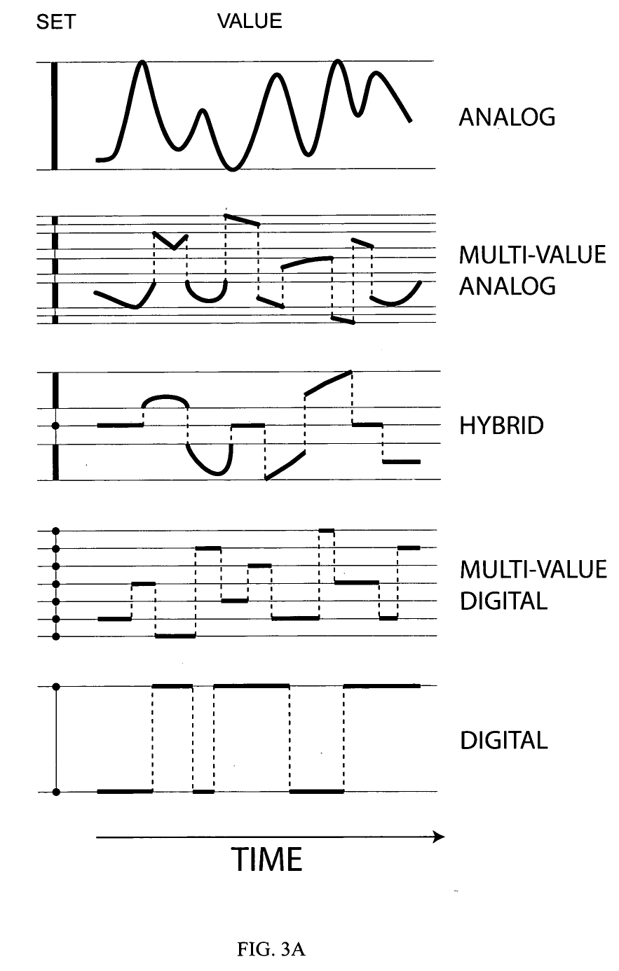

FIG. 3 shows various time-dependent values for some relatively simple sets.

FIG. 3A shows examples of 1D data evolving continuously in time.

By definition, the values must be “allowed,” by which we mean they correspond to members of the given set. The transitions across “forbidden” values must occur in (effectively) zero time—the transitions are discontinuous. We will impose this requirement on any candidate computer within this invention: the states must be stable (static), and any jumps between states must be done in essentially zero time.

However, there is no requirement to keep the sets themselves fixed throughout the entire computation. Indeed, we are interested in the transformations of instances of sets, not the transformations of members of sets. Thus, the schemes in this figure, while constituting computation on values within constant sets, do not satisfy our desire to perform computation at the set-level. They are computations of a single member of the set, not of the set itself.

FIG. 3B shows an example of a 1D data set that evolves continuously in time. The initial set, which consists of intervals and discrete values, evolves into another set. Some parts of the data experience smooth changes, while other parts experience discontinuous changes. Thus, the scheme shown in this figure constitutes an example of set-level computing.

### Set Theory

Set Theory is the fundamental formalism from which all mathematical expression can be constructed. It provides a unified approach to defining mathematical objects and procedures for manipulating those objects. While there are many versions of Set Theory [Suppes, 1972; Stoll, 1979], defined by one or another set of axioms, of which the set most widely accepted is that of Zermelo-Fraenkel, all versions have in common a fundamental set of definitions and expressions. In this invention we will deal only with entities that are common to all versions of Set Theory.

A set is generally defined as a collection of objects regarded as a single object. If x represents a single object, {x} represents a collection of such objects, where “{}” means “all possible instances of . . . ”. If we refer to the collection as A, then a member x of the set A is written x|xA, where “∈” means “is a member of”, and the vertical bar “|” represents condition: “given that . . . ” or “such that . . . ”. The set A consists of all of its members x:

A≡{x|x∈A}.

Sets can have a finite or an infinite number of members x.

In this invention, we identify “members” as “values corresponding to real numbers.” We will most often assume that the sets can have a finite number of interval sets, in which an interval contains an infinite number of values. The identification of members with values does not imply that the values are numbers, although we could assign a number to each value if we wish.

Sets can be defined by (almost) any condition:

A≡{x|f(x)}

which is referred to as definition by abstraction. Furthermore, conditions can be compounded, viz.:

A≡{x|f(x)| . . . |g(x)}

by which we mean that all conditions f(x) . . . g(x) must be satisfied.

Much of Set Theory is concerned with constructing sets from other sets. The manipulation of such sets is enabled by accumulating an inventory of expressions, definitions, and different forms of the same set. This constitutes an algebra that is convenient for computations, and in this invention we will develop such an algebra using graphical forms (electronic circuit diagrams) that are the analogues of sets.

### Set-Level Operations

We list here the fundamental set-level operations in Computational Set Theory.

Suppose we are given two (arbitrary) sets A,B defined by

| | |
|---|---|
| Set | A ≡ {x\|x∈A} |
| Set | B ≡ {x\|x∈B}. |

There are systematic procedures for combining A and B to form other sets. The most important fundamental binary set-level operations are:

| | |
|---|---|
| Intersection | A ∩ B ≡ {x\|x∈A [symbol] x∈B} |
| Union | A ∪ B ≡ {x\|x∈A [symbol] x∈B} |
| Difference | A\B ≡ {x\|x∈A [symbol] x∉B} |
| Symmetric difference | A ÷ B ≡ (A\B) ∪ (B\A). |

Two particular sets have special status:

| | |
|---|---|
| Null Set | Ø ≡ {x\|x≠x} |
| Universal Set | 1 ≡ {x\|x = x}. |

The null set Ø is similar to zero. For example, A\A=Ø, A∩Ø=Ø, and A∪Ø=A. The universal set 1 is similar to unity. For example, A∪(\A)=1, A∩1=A and A∪1=1.

The universal set allows us to define the complement of the set A:

Complement 1\A≡{x|∉A}.

Thus, we have the basic relations 1\Ø=1 and 1\1=Ø.

There are a variety of set-level operations that yield the Boolean set {TRUE, FALSE}, of which the most important are:

| | |
|---|---|
| Equality | A = B ≡ {x\|x∈A→x∈B [symbol] x∈B→x∈A} |
| Subset | A ⊂ B ≡ {x\|x∈A→x∈B} |
| Proper Subset | A ⊂ B ≡ {x\|x∈A→x∈B [symbol] A ≠ B}. |

In each of these cases (and numerous others that are similar), the symbol→means implication: x→y means “if x is TRUE then y is TRUE.” Thus, the expressions above are Boolean, that is, they are either TRUE or FALSE. For example, A⊂TRUE if (for all x) (x∈A=TRUE→x∈B=TRUE). If unambiguous, we will use T=TRUE,F=FALSE.

We emphasize again the difference between operations on instances of sets (termed set-level) and on the members of the set. Set-level operations will operate on all members of the set simultaneously, and using the same operation on all members of the set. In this invention we seek circuits mat implement set-level operations. We will find that aggregation is intrinsically set-level, but evaluation is generally not set-level (but instances can be found that are set-level).

We also note that sets can have members that are themselves sets, so transformations of members may itself require set-level operations.

### Chain Set Expressions

Most expressions in Set Theory are in the form of a chain:

S₁O₁₂S₂O₂₃S₃O₃₄S₄O₄₅S₅ . . . ,

where S₁ are sets and Oᵢⱼ are operations, generally members of the set {∩, ∪,\,÷,=,⊂, ⊂, . . . }.

This form does not unambiguously specify the expression E; we also need to specify how the factors are grouped within the operations. Thus, E might represent any of the following (among many others):

O₁₂(O₂₃(S₁,S₂),O₃₄(O₄₅(S₃,S₄),S₅))

O₁₂(S₁,S₂,O₂₃(O₃₄(S₄),O₄₅(S₅))

S₁O₁₂(O₂₃(O₃₄(O₄₅(S₂,S₃),S₄),S₅)).

The first of these expressions involves only operations of the form O(S,S), while the second involves operations of the forms O(S), O(S,S), and O(S,S,S), and the third involves only the forms O(S), and O(S,S).

A typical example of such expressions is

E÷F)\G⊂(A∩B)∪(C\D).

where some of the sets might be the same (e.g., F=A=D≡X).

Each set S in a chain expression can be generated with an appropriate device D or circuit C. Likewise, each operation can be implemented with the circuit analogues presented above (intersection, union, etc.). The circuit analogue for the complete expression is obtained by merely connecting the modules in series (in a chain).

The normal precedence of the operators is that all set-generating operations (∩, ∪,\,÷, . . . ) are done before any set logical tests (=, ⊂, ⊂, . . . ).

### Logical Operators

Set Theory includes first-order logic, and expressions in Set Theory often explicitly involve logical operators. In this invention, we will use logical operators defined conventionally by the standard symbols:
[symbol] ≡ NOT
[symbol] ≡ AND (also represented as “,” and [symbol] )
[symbol] ≡ OR (also represented as [symbol] )
→ ≡ IF . . . THEN . . .
[symbol] ≡ IF AND ONLY IF.

We will interpret A [symbol] B to mean A [symbol] B [symbol] ( [symbol] A [symbol] B). We will find that this operation will require switches, which is not unreasonable, since “or” implies alternatives.

### Computational Set Theory

Computational Set Theory is that branch of Set Theory concerned with manipulating set expressions to achieve a particular purpose, e.g., to obtain “solution” sets representing unknowns in the problem [Cantone, et al., 2001]. This program involves operations such as combining given sets to form new sets, testing relationships between sets, etc.

Most problems in computational set theory are cast into the form of a set of constraints; they are referred to as (set) constraint satisfaction problems (CSP). CSPs are commonly generated in artificial intelligence applications such as machine vision, belief maintenance, temporal reasoning, graph theory, circuit design, and diagnostic reasoning. CSPs on finite domains are typically solved using a form of search. There is considerable literature on CSPs [Tsang, 1993], and we will give examples of such problems in this specification. This invention provides a path to designing a circuit that can attack not only classical intractable problems, but also a generalization in which some or all of the discrete sets are replaced by interval sets.

It is important to note the difference between solving a problem expressed as a set of equations, in which the relationships require two or more objects to be equal, and solving a problem expressed as a set of constraints. All CSPs have solutions that are sets. Equality is the strongest form of constraint, and problems expressed as equations have solutions that are the smallest possible set. In general, CSPs can be considerably weaker than equations, and a problem posed as a collection of weaker constraints will in general have a solution that is a larger set.

Computational problems of human importance often have a qualitative nature, and may involve concepts that cannot be captured with equations. Rather, constraints that express qualitative relations between generalized objects are more appropriate. For example, we might say that mere are more hurricanes than tsunamis, but the words in this constraint are not precise. Such concepts can be captured with set constraints, and a CSP is defined as a collection of such constraints. Such collections of constraints can be satisfied (if the collection is consistent) by a collection of objects (sets), which thereby constitute the solution to the CSP. To the extent that some sets in a CSP are known and others are unknown, determination of the latter constitutes the computational problem.

Computers for Computational Set Theory

In seeking a machine that can assist in solving CSPs, we encounter a surprising disconnect: At one extreme, we think of a machine as having a single state, which is the analogue of a member of a set. Processing the entire set involves processing all of the members of the set. This approach is numerical; the data are instances of members of a set. At the other extreme, we can use a machine to represent a set by a symbol, arid to manipulate such symbols according to given rules. This approach is symbolical; the data are (symbols of) sets.

What is missing in this scheme is computation in which the data are instances of sets. Such a machine would store and process specific instances of sets, but the storage and manipulation would be at the set-level. The term “set-level” means that an operation on an instance of a set would be performed on all members of the set, considered logically to be a single operation.

This invention provides one means to realize a computer of the kind just described. It is qualitatively different from conventional digital and analog computers, and from numerical and symbolic computers. It defines a new class of computers, in which the data are instances of sets and the operations are set operations performed on these instances. The core of this invention is the definition of electronic devices and circuits that implement this computational concept and computers based on it.

### Devices Defined

An electronic device is a physical piece of matter having a set of points at which we can define the voltage V and a set of points (which can be the same as the voltage points) at which we define the current I into the device. The device itself can hold electric charge Q, and can have physical properties such as resistivity R, susceptibility S, thermal properties K, etc. In addition, there can be global variables such as pressure P, temperature T, electric field E, and magnetic field B, that affect the internal states of the device.

We list here some of the assumptions about electronic devices used in this invention.

(1) The complete set of physical variables defines the device. The combination of the electrical variables {V,I,Q . . .}, properties {R,S,K, . . .}, and external variables {P,T,E,B, . . .}constitute a complete set of physical variables that define the device. No other variables are relevant to the model devices or to physical measurements that might be made on the devices.

(2) All physical variables are finite. While the ranges of the variables are finite, the number of possible values in those ranges will usually be infinite. Thus, the data to be processed by the circuits will be hybrid: a finite number of intervals in a finite global range, but with infinite numbers of values in each interval.

(3) The allowed states are stable. In the absence of perturbations, a device will stay in a particular allowed state. Transitions between allowed states occur in zero time. If an attempt is made to set the variables to forbidden values, the device will spontaneously relax into an allowed state at a very high rate (determined by the circuit inductance and capacitance). For instance, a voltage pulse might cause the sudden jump of the device current into an unstable value, but it will very quickly relax to an allowed, stable value.

(4) All stable states are reachable. In order to change the state of a circuit, we may have to “kick” it with an external circuit, although we do not necessarily have to specify such means. Any states that cannot be reached by available means are irrelevant.

(5) Devices can be operated in various modalities. The device [symbol] is defined by a set of variables, but it is not necessary to observe all variables to define computational sets and perform operations with them. If we observe variables X, we refer to the device as X-mode and represent it as

[symbol]

### Analog Devices

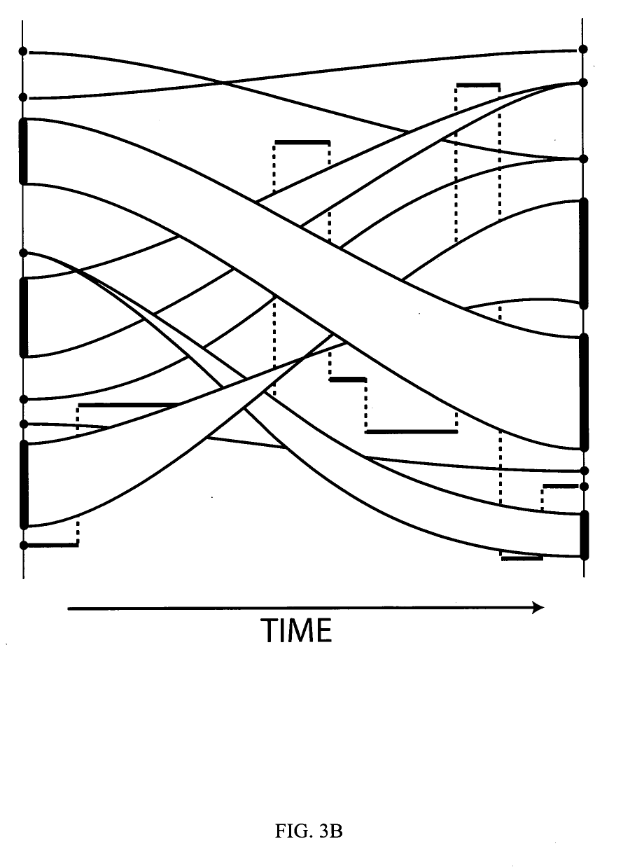

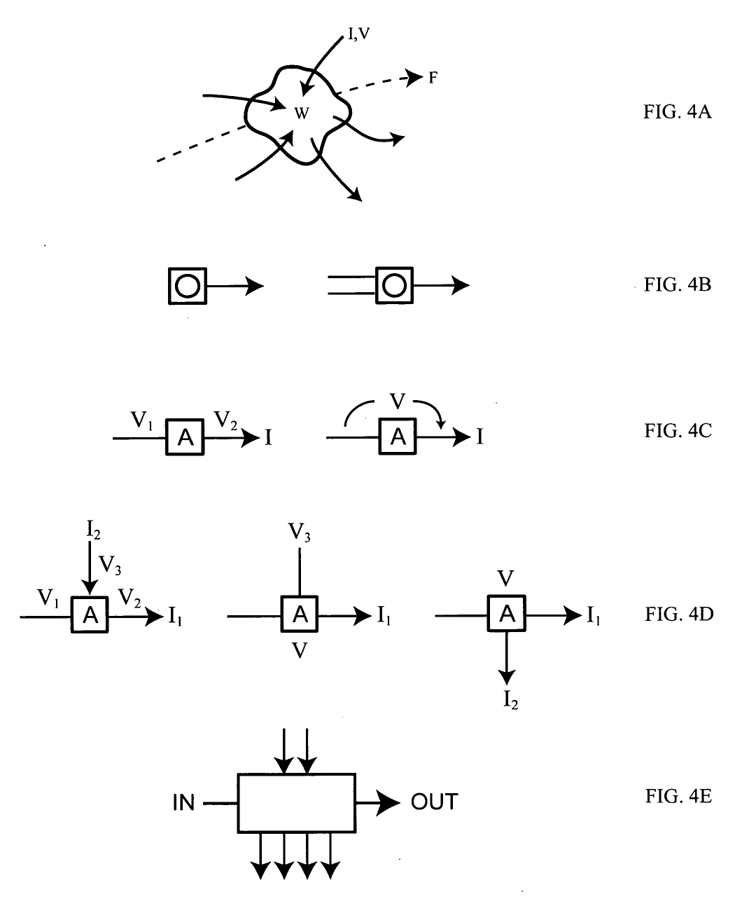

FIG. 4 shows examples of electronic devices that are used in this invention.

FIG. 4A shows a generic device, having various currents I, voltages V, material states W, and external fields F. Most of the formalism used in this invention is applicable to completely general devices of this kind, with any number of variables.

### 1-Terminal Devices

FIG. 4B shows a generic 1-terminal device. This device can be used to set a voltage or supply a current to any other point in a circuit. Thus, this symbol will represent the ability to externally set a local circuit variable. We will use these devices in this invention to set constants in circuits, and to scan ranges of values searching for sets that satisfy the problem specification. We will also assume that this device can have inputs that turn it on and off, and control its properties, as indicated with input lines. Such controls are not part of this invention, and we regard these as logically 1-terminal devices.

### 2-Terminal Devices

FIG. 4C shows generic 2-terminal devices, in the form in which the current through the device represents the data. There is a completely dual set of voltage-data devices. These will be the most common devices in this invention. Generally we assume that these devices cannot accumulate charge, hence the current OUT is equal to the current IN (with reversed sign). The two voltages V₁,V₂ determine the current I through the device. The functional relation I(V₁,V₂) is arbitrary. A particular state of the device is specified by a particular set of values the circuit variables V₁,V₂,I,σ, where σ specifies internal material parameters and external fields, and the entire device is specified by all possible combinations of V₁,V₂,I,σ. In Set Theory this is written {V₁,V₂,I,σ}, where {. . .} means “all possible values of . . . ”. Every set of values V₁,V₂,I,σ must be a valid combination for the particular device.

While the complete set of circuit variables is required to define the state of the device, we are free to ignore some variables (measure only some variables), and consider all other variables as parameters. Furthermore, we are free to perform transformations on the variables, for instance V=V₁-V₂. Such transformations significantly affect how we use such devices to represent sets and set operations.

In this invention we will most often use these devices to represent (=generate) 1D sets. Note that although the set may have only 1 dimension (say, the possible values of the current), if the set has more than 1 member, we will need a second dynamical variable to access those members. In particular, if the device has a continuum of values (i.e., intervals), we will need a second continuous circuit variable to select the device data value. Clearly, this is inherent in the functional relationship I(V) for a voltage-controlled current source. Thus, we begin to see that this invention comprises circuits that manipulate data defined by generalized functions.

### 3-Terminal Devices

FIG. 4D shows generic 3-terminal devices, in current-mode. Typically, these devices are used for control and for signal generation. In this invention, we will use these devices to select particular members of sets, and to scan sets to generate subsets. The general device is defined by the variables V₁,V₂,V₃,I₁,I₂,σ, which must be valid for the particular device. As before, we a free to choose a subset of variables, and to transform the variables.

### Data Flow

FIG. 4E shows a generic multi-terminal device, having input and output data (voltages and currents), and a variety of control inputs and outputs. We will use the convention that the signal (the “data”) moves through the circuit from left-to-right. For instance, if the data is represented as a current, we arrange the circuit so the current enters from the left and exits to the right.

### Current-Voltage Duality

For every circuit operated in current-mode there is an equivalent circuit in voltage-mode. This is suggested by the inverse functions I(V) and V(I). This duality will exist in all the circuits in this invention; that is, there is nothing in this invention that is specific to either current-mode or voltage-mode. We will, in fact, generalize this to arbitrary modes, in which any combination of the physical variables can be used as independent variables and as dependent variables.

### Control Devices

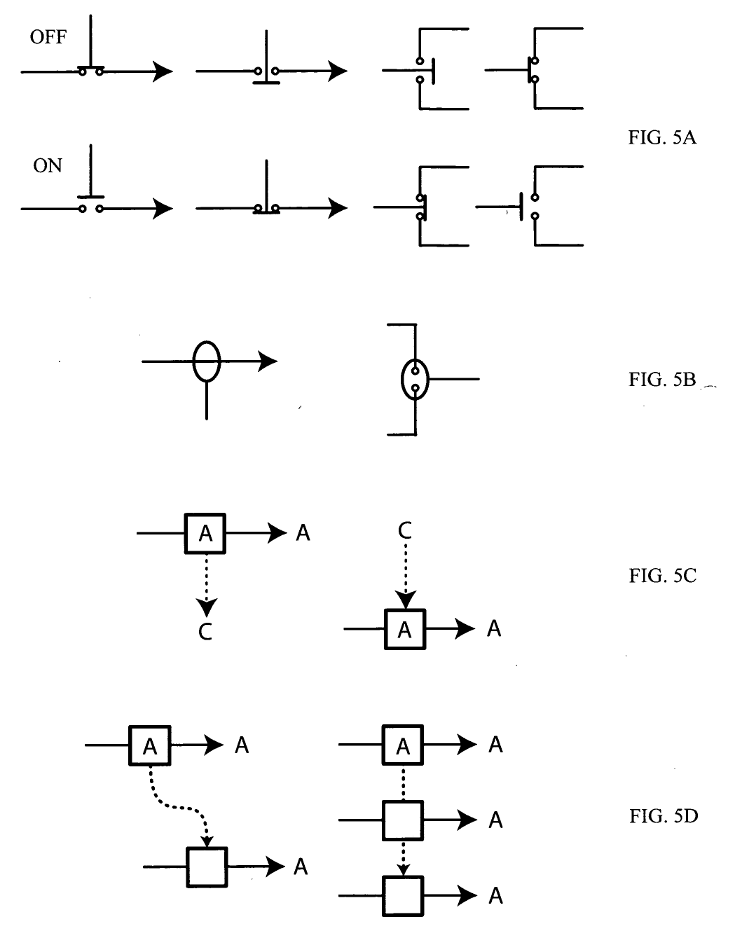

FIG. 5 shows devices or circuits used for control of other devices or circuits.

Control devices have 3 or more inputs and outputs, one of which controls the data with a signal that is not considered part of the data. As with all devices and circuits, there is complete duality of current-mode and voltage-mode devices.

Control devices are devices, hence can be treated with the same formalism as the analog devices we will use for data processing.

### Switches

FIG. 5A shows generic switches used to set currents or voltages to zero, or connect different circuits. Switches are discrete devices that implement alternatives, hence they will be useful for implementing discrete sets, including the Boolean set <TRUE,FALSE>.

### Sensors

FIG. 5B shows generic sensors. The sensors provide a signal that is TRUE if the current (voltage) is nonzero, and FALSE if the current (voltage) is zero.

### Controls

FIG. 5C shows generic controls. In the first case, the device provides a signal that depends on the device and its state. In the left instance, the device [symbol] provides a signal that contains all the information about the set A. In the right instance, the device accepts a signal containing information that is used to configure the device to represent the set A. Together, these controls can be used to create clones, as we now discuss.

### Clones

In this invention, we will frequently find it necessary to generate multiple independent copies (clones) of the same device or circuit. For instance, to represent the set Boolean expression ((A∪X)\(X∩B))⊂(A÷B)\X, we would need 3 clones of the device

[symbol]

FIG. 5D shows how we can use pairs of 3-terminal devices to generate clones. The first device generates a signal containing a description of the set A represented by the device A. The second device accepts the signal as a control, which configures it to represent the same set A. We stipulate that any device and any circuit can be cloned.

### Circuits Defined

A circuit [symbol] is the combination of two or more devices by electrically joining them. We will sometimes use the notation [symbol] to represent circuits constructed by joining devices or other circuits [symbol] Usually we will use the term “circuit” to mean either a single device or a circuit formed by assembling two or more devices or circuits.

### Modularity

It is assumed in this invention that the electrical properties of the various devices and circuit fragments are modular, that is, the current output from one circuit can be used as the current input to another circuit, and the voltage output from one circuit can be used as the input voltage to another circuit. Thus, we anticipate being able to connect various circuits into compound circuits, hierarchically creating larger circuits, scaling up without logical limit.

Characteristic Functions

The individual devices, and by combination the circuits they compose, are determined by the functional relationships between their dynamic circuit variables. For 2-terminal devices these functions are called transfer functions, current-voltage relations, characteristic functions, and similar terms. In this invention we assume completely general multi-variable functional relations. However, it is instructive to review some features of such relations using 2-variable functions.

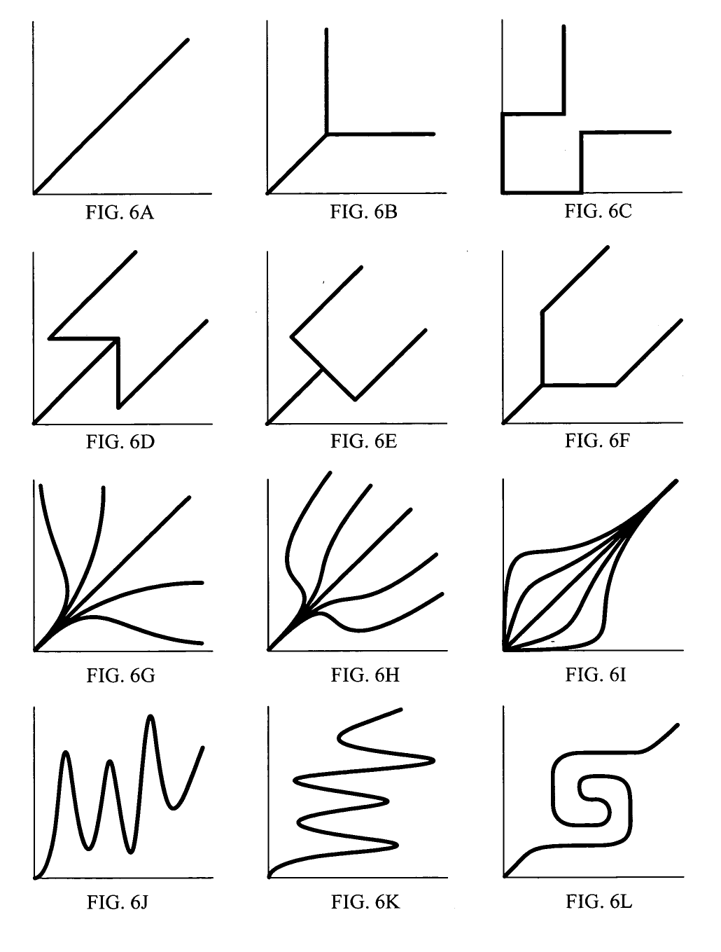

FIG. 6 shows examples of 2-variable functional relations. They could be visualized as the current through the device as a function of the voltage across the device. For these diagrams, we can consider them to represent the signal S_{OUT} vs. the signal S_{IN}.

FIG. 6A shows the ohmic linear function for a simple resistor.

FIGS. 6B,C show idealized cases of saturation, or limiting, typical of diodes. In the first case, the small-signal behavior is ohmic, while in the second it shows a threshold.

FIGS. 6D,E,F show idealized discontinuities. For the first two cases, the discontinuities produce regions of negative differential resistivity (NDR), or negative differential conductivity (NDC), while in the third case it merely inserts an offset into the ohmic function.

FIGS. 6G,H,I show families of smooth functions. These describe actual physical devices, such as Gunn diodes, Josephson junctions, optoelectronic devices, and tunneling diodes [Shaw, et al., 1992].

Generally, NDC is described as either N-type (NNDC), by which is meant that the function S_{OUT}(S_{IN}) is N-shaped,rising sub-linearly and reaching a peak in S_{OUT}, or S-type (SNDC), by which is meant that the function S_{OUT}(S_{IN}) is S-shaped, rising super-linearly and reaching a peak in S_{IN}.

FIGS. 6J,K show an example each of multi-peak NNDC and SNDC functions. Such functions are found in stacks of tunnel diodes and other devices.

FIG. 6L shows a double-spiral function. Behavior this complex is not found in relatively simple devices; rather, we might find it in circuits assembled from several devices of different kinds, e.g., multiple NNDC and SNDC devices. Such circuits will exhibit very complex behavior, and questions might arise as to how to access all parts of the function. However, this example emphasizes that this invention in no way depends on assumed simplicity of the functional relations. We also stipulate that all parts of the characteristic functions defining the devices are accessible.

While these examples may appear whimsical, such complexity will actually arise in compound circuits involving multiple devices with nonlinear individual behavior.

Oscillatory States

In actual circuits, individual devices and circuits can have dynamical states that are unstable; attempts to set the voltages and currents to certain values will drive the device or circuit into oscillation. To the extent that such oscillations are periodic, they could be considered stable oscillatory states. In principle, we could develop circuits that are analogues of sets we could define as data. In this sense, such states are included within the concept of the present invention. However, such considerations introduce new complications in describing various forms of this invention, so in this specification we will limit our definition of data to refer only to literally stable states.

### Device and Circuit Analogues of Sets

In this section we discuss the representation of sets by devices and circuits. The discussion will be detailed and formal, because in order to appreciate the power of this invention, and to effectively implement it in practice, it is necessary to have rigorous definitions and a clear understanding of the symbols arid their meanings.

This section is not part of the claims for this invention, but rather provides the rigorous foundation on which the claims are made.

### Physical Variables of Devices

The complete set of all values of all physical variables of a physical device D define the device. For example, suppose the device has 3 wires, on which the voltages are V₁,V₂,V₃ and in which the currents are I₁, I₂, I₃. The device itself has properties such as material, temperature, pressure, strain, and there might be external fields. The physical variables can be written D={V₁,V₂,V₃,I₁,I₂,I₃,σ}, where σ represents all other variables and properties besides the voltages and currents. All possible combinations of all possible values of these 7+ variables define the device. A particular state of the device D is given by a specific set D of values of all of these variables, and the device itself is defined by all possible values of all variables. A circuit C is a combination of devices connected together.

We seek devices D and circuits C for which the values of the physical variables are in one-to-one correspondence with the members of one or more sets. Alternatively, we seek sets D, C such that the members of the sets are in one-to-one correspondence with the observed physical variables of given devices and circuits. This one-to-one correspondence (either way) thus describes analogues: the devices and circuits are the analogues of sets, and vice-versa.

### Device Analogues of Sets

Consider first a single device [symbol] which for simplicity we will assume is a 2-terminal device. A particular state of this device can be represented by the set {V₁,V₂,I,σ} . This expression includes exactly 4 values of the 4 physical variables. The device itself comprises all possible values of the variables, so we can define a set

D={{V₁,V₂,I,σ}|{V₁,V₂,I,σ}∈D}.

The expression {V₁,V₂,I,aσ}∈D specifies that the 4 values in {V₁,V₂,I,σ} must be such that they are valid for the set D. By assumption, these values correspond one-to-one with the values of the 4 physical variables of the physical device [symbol] Therefore we will write [symbol]
in which we have used the symbol [symbol] to indicate the one-to-one correspondence between a physical object and a mathematical set. All the possible 4-value combinations of the physical variables of the physical device [symbol] must exactly correspond to all the 4-value members of the set D; there can be no “extra” values of the device or “extra” members of the set.

{V₁,V₂,I,σ}∈D is an expression in Set Theory, with no reference to the physical device. However, it seems conceptually valid to use the form {V₁,V₂,I,σ}∈ [symbol] to also indicate that the physical variables corresponding to {V₁,V₂,I,σ} must be a valid combination for the device [symbol] Thus, we can combine the previous two expressions to write [symbol] {{V₁,V₂,I,σ}|{V₁,V₂,I,σ}∈ [symbol] to which we ascribe the meaning: [symbol] is a physical device that is the analogue of a set D whose members {V₁,V₂,I,σ} correspond one-to-one with the values of the physical variables of the device

[symbol]

This rather tortuous, and seemingly circular, definition of the analogue is necessary to establish the rigorous analogy between a physical device and a set. Once established, we will tend to use the set and its device analogue interchangeably. We will use the terms set device to refer to a device [symbol] that is the analogue of a set D, and device set D to refer to the set that is the analogue of a device [symbol] Because the set device and the device set are equivalents, we will often refer to them interchangeably.

### Modal Device-Set Analogues

A set device D whose elements are (unordered) sets Z={z₁,z₂, . . . ,zₙ} can be written

D={Z|Z∈D}.

Suppose we identify a subset X of the set Z, i.e., X⊂Z, or equivalently X∪Y=Z. Related to the set device D is another set

^{X}D={X|∃Y|X∪Y=Z|Z∈D},

where we use sequential condition bars | to indicate multiple simultaneous conditions.

The meaning of this expression is that the set device ^{X}D has members X, subject to the condition that there exists a Y such that X∪Y=Z and Y∈Z. Thus, the second expression above has the form
modal set [symbol] {the list of output variables |
   the list of input variables |
   there are no other variables |
   all the variables define the device}.

Because there can be many possible partitions X∪Y=Z, the expression ^{X}D defines many possible sets; these will be called modal subsets, or simply modes. A device ^{X}D will be referred to as an X-mode device.

The set variables can be separated by the condition bar | into the form {. . .}|∃{. . .}, with the dependent variables placed before the condition bar {. . .}, and the independent variables ∃{. . .} placed after the bar. However, the condition {. . .}∈D must include all the variables, and must always be present.

The expression ∃Y suggests that we must examine values of Y to find those values for which Z is a valid set of values of the device D. With certain restrictions (cf., the discussion on evaluation), we will be able to avoid actually examining the members of the device set, essentially identifying all valid values Y simultaneously.

The device membership relation {. . .}∈D is a notational convenience for representing a functional expression E({. . .}) between the variables. For instance, the resistor {V₁,V₂,I,R}∈D is defined by the relation V₁-V₂=IR. No matter how complicated such relationships might be, it is always indicated by the membership relation {. . .}∈D.

It should be noted that there is no implication of simplicity, continuity, or even single-valuedness in the membership relation {. . .}∈D. Thus, it would be possible to have multi-value, discontinuous, and even pathologic relationships between the variables; the membership relation {. . .}∈D represents all these cases.

When the meaning is unambiguous, we will abbreviate the notation for modal devices to

^{X}D [symbol] {X|X∈D}.

This expression means that X is a set of physical variables of the circuit C, with all other variables left unspecified (or implied).

Non-Uniqueness of Device-Set Analogues

The previous section emphasizes the fact that in general a device D can provide a physical analogue of many different sets. For instance, the current through a device D would be the analogue of a set ^{I}D, whereas the voltage across the same device D would be the analogue of a (different) set ^{V}D.

Similarly, a given set D can be the analogue of a device D₁ and the same set can also be the analogue of a completely different device D₂.

This non-uniqueness of the set-device analogue is characteristic of this invention. In implementing circuits based on this principle, it will always be necessary to define the operating mode, and ensure that the devices are operated consistent with the definitions of the analogues. It is, of course, possible to assemble circuits with more than one mode.

### Non-Electrical Analogues

One of the device modes is ^{σ}D. This signifies a device for which the non-electrical property σ is observed. In principle this is a valid modal device, but it generally will not enable us to carry out computation because we cannot vary σ fast enough to be useful. Therefore, we will usually carry along σ to represent static bulk device properties, such as the resistance of a resistor, rather than dynamical quantities such as voltage, current, or charge.

### Example: Modal 2-Terminal Device Analogues

For 2-terminal devices, the set device is

D [symbol] {{V₁,V₂,I,σ}|{V₁,V₂,I,σ}∈D}.

From this we can define various modal analogues:

^{V}₁,^{V}₂,^{I}D [symbol] {{V₁,V₂,I}|∃σ{V₁V₂,I,σ}∃D}

^{I}D [symbol] {I|∃{V₁,V₂,σ} {V₁,V₂I,σ}∃D} (I-mode)

^{V}₁,^{V}₂D [symbol] {{V₁,V₂}|∃}I,σ} {V₁,V₂,I,σ}∈D}

^{V}₁D [symbol] {{V₁|∃{V₂,I,σ} {V₁,V₂,I,σ}∈D}

^{V}₂D [symbol] {V₂|{V₁,I,σ} {V₁,V₂,I,σ}∈D}

^{V}D [symbol] {V|∃{V₁,V₂,σ}|V=V₁-V₂|{V₁,V₂,I,σ}∈D} (V-mode)

^{σ}D [symbol] {σ|∃{V₁,V₂,I}|{V₁,V₂,I,σ∃D}.

It is clear from these expressions that the condition {V₁,V₂,I,σ}∈D must always be present, since it is the condition that the set of Variables is a valid set for the device D.

Now we transform to a new variable V=V₁-V₂, and omit the reference to σ, which refers to the physical parameters of the device (e.g., resistance). This gives

D [symbol] {{V,I}|∃{V₁,V₂,σ}|V=V₁-V₂|{{V₁,V₂,I,σ}∈D}.

which we can abbreviate as

^{V,I}D [symbol] {{V,I}|{V,I}∈D} (V,I-mode)

and from which we can define two sets

^{I}D [symbol] {I|I∈D} (I-mode)

^{V}D [symbol] {V|V∈D} (V-mode)

which are defined by their functional relationships

I∈D [symbol] I=f(V) (I-mode)

V∈D [symbol] V=f(I) (V-mode)

and equivalently by abstraction

^{I}D [symbol] {I|I=f(V)} (I-mode)

^{V}D [symbol] {V|V=f(I)}. (V-mode)

### Device Analogues as Input-Output Relations

A conceptually easy way to visualize the device-set analogue is to think of the characteristic function as the relation between the input signal S_{IN} and the output signal S_{OUT}. The examples in FIG. 6 may be visualized this way: Think of the input S_{IN} as scanning the device to produce all possible outputs S_{OUT}. The set that is represented by the device is then all the values of S_{OUT} produced by such scan. In the terminology of Set Theory, the domain S_{IN} maps into the image (or range) S_{OUT}.

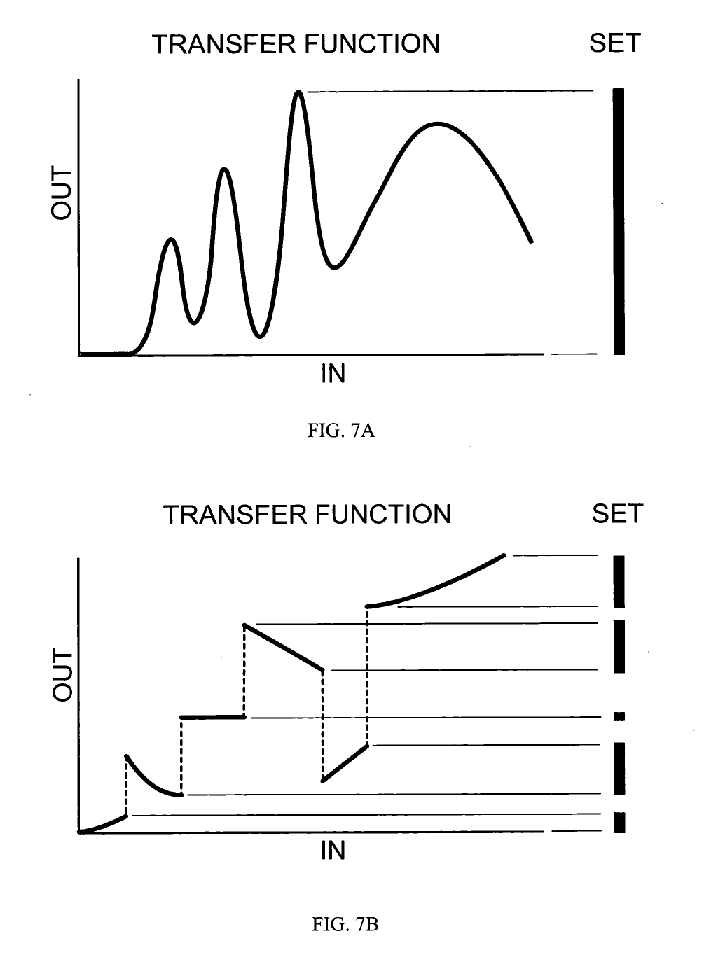

FIG. 7 shows the characteristic functions of hypothetical nonlinear devices as input-output relations. These functions define set analogues.

FIG. 7A shows a continuous function—the set produced by scanning this function is the entire range of the function, indicated by the continuous bar to the right. This set is a single interval.

FIG. 7B shows a discontinuous function—the set produced by scanning this function is a set of disjoint intervals (a multi-interval), consisting of all possible values.

This example shows that one way to generate gaps in the data is to have a device that is stepwise discontinuous. We will show in the next section that another way to generate gaps is to connect two or more devices together, when at least one device exhibits NDC.

### Discontinuous Behavior

The set represented by a device will depend on how it is operated: the device may produce gaps and/or hysteresis in the analogue set.

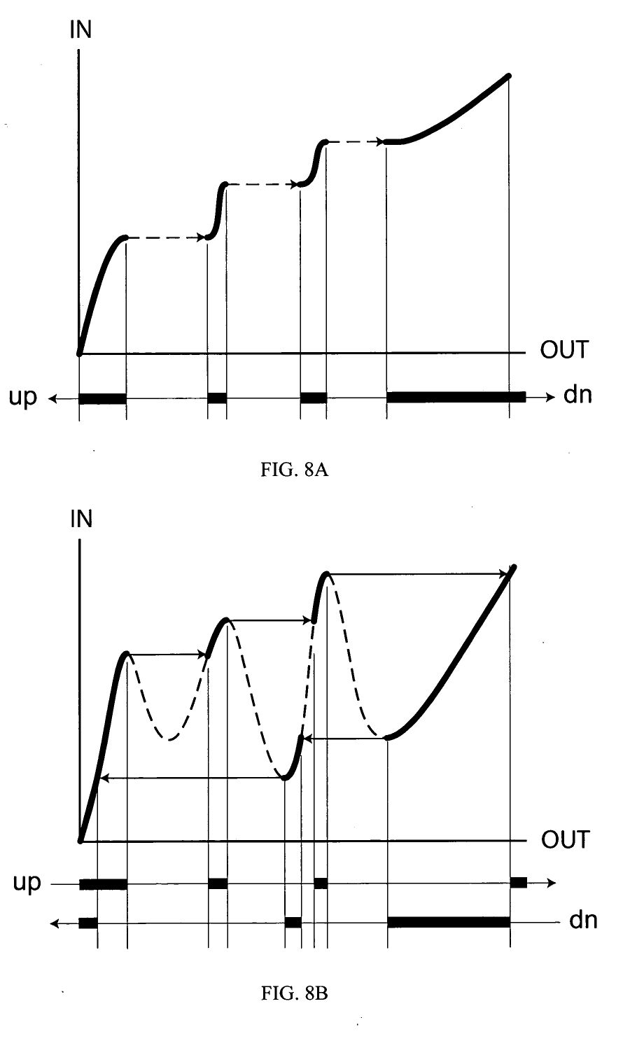

FIG. 8 shows the characteristic functions of two hypothetical nonlinear devices exhibiting discontinuities and hysteresis. In contrast to the previous section, where the abscissa was scanned as IN and the ordinate read as OUT, here we assume we scan the ordinate as IN and read the abscissa a as OUT. If these are current-voltage curves, I(V), this means that we are scanning the devices with a current source and reading the function V(I).

FIG. 8A shows how constant intervals of the function lead to gaps in the analogue set. As the ordinate (IN) is scanned, the abscissa:) suffers sudden jumps. Physically, this would be observed as a sudden jump in the voltage as the current is changed infinitesimally. Note that the set analogue is the same whether the device is scanned up or down.

### Hysteresis

FIG. 8B shows how regions of NDC can produce hysteresis. As the ordinate (IN) is scanned up from the origin, it eventually encounters a peak. Further increase of IN fails to find a stable state, and the device jumps suddenly to the state to the right, producing a gap in the analogue set. This happens twice more as IN is increased further But when IN is decreased from the extreme right side, the device still has stable states along the curve decreasing to the left. Thus, the analogue set includes all the values on this segment. Eventually IN reaches the minimum and fails to find a stable state, so makes a jump to the left, creating a gap in the analogue set. Further decrease produces another gap, until the device is brought back to the quasi-ohmic region and to the origin.

The result of this scanning process is that the analogue set for increasing scans is not the same as the analogue set for decreasing scans. We could reasonably consider the analogue set for the device to be the union of these two sets, which we see in this case still contains gaps.

It may be noted that some of the details of the NDC regions are immaterial to the sets; only the positions of the extrema determine the analogue sets.

### Cyclic Sets

The previous example showed that NDC can generate hysteresis, which defines multiple analogue sets. By controlling the direction and extent of the scans of the IN variable, we can traverse the characteristic curves in various cycles.

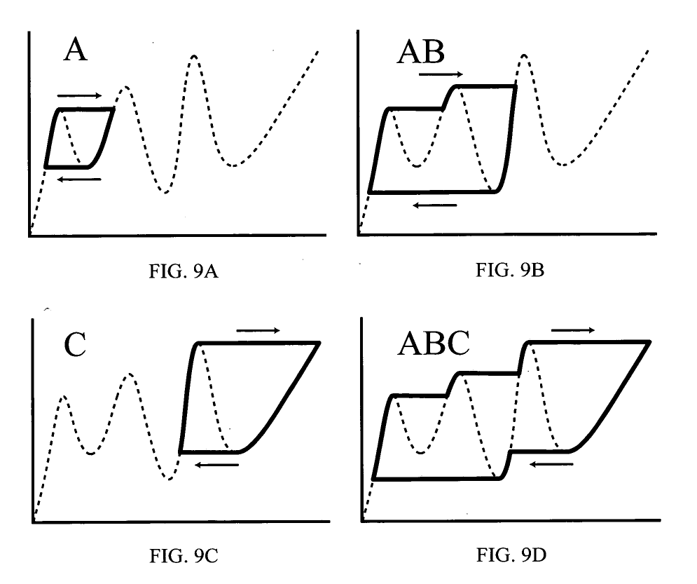

FIG. 9 shows how cycles can be generated using nonlinear devices. This example assumes that the same device is scanned with different starting points and different extents.

All four cases have analogue sets that are single intervals. This happens because the “up” set and the “down” set overlap completely—their union is a single interval.

These cases exhibit a variety of basic relations from Set Theory, e.g.,

S_{A}⊂S_{AB}⊂S_{ABC}

S_{A}∩S_{C}=Ø

S_{AB}∩S_{C}≠Ø

S_{AB}∪S_{C}=S_{ABC}.

In the discussion about discontinuities, hysteresis, and cycles, we referred to the analogue set as being 1D and generated by scanning the IN variable across the nonlinear characteristic function. However, there are other ways to define sets as data. For instance, we could regard the traces of the cycles (the curves enclosing the cycles, rather than the projection on the OUT axis) as the data. In this case some relations will be different, e.g.,

S_{AB}∪S_{C}≠S_{ABC}.

Still another way to regard the cycles as data is to define the area enclosed within the cycles as the data. Again, some of the relations above are different, e.g.,

S_{AB}∩S_{C}=Ø

These remarks emphasize the fact that in realizing this invention it is necessary to carefully define the analogue sets, and provide mechanisms for their uniqueness in computations.

Note that it is not possible to traverse the cycle B alone, because the return jumps back to the A Cycle. Note also that we could specify a characteristic curve for which infinitesimal changes cause finite jumps in the cycles, thus providing a means for analog switching. This switching function is one of the main advantages of using nanoelectronic devices to implement this invention, as will be discussed in later sections.

### Circuit Analogues of Sets

The above development is valid not only for a single device D but also for any circuit C formed by assembling such devices or other circuits. The circuit-set analogue is

C [symbol] C C={Z|Z∈C} Z={Z=Z₁, . . . Z_{N}}

where Z is the set of all physical variables for all devices. The circuit connections are contained in the membership expression Z∈C.

### Modal Circuit Analogues

In the same way we defined modal sets by separating independent and dependent variables, we can define modal circuits. Let Z be the set of all physical variables that define every state of a circuit C, and select a subset X of Z to be observed. The set analogue of the circuit is therefore

^{X}C [symbol] {X|∃Y|X∪Y=Z|Z∈C}.

which will be referred to as an X-mode circuit, or “the circuit C operated in X-mode.”

When the meaning is unambiguous, we will abbreviate the notation for modal circuits to

^{X}C [symbol] {X|X∈C}.

This expression means that X is a set of physical variables of the circuit C, with all other variables left unspecified (or implied).

Essentially all of the discussion above about modal devices is the same here for circuits. In particular, the expression ∃Y indicates that we will need to find values of the subset Y of the physical variables that are valid for the circuit, i.e., ∃Y|X∪Y=Z|Z∈C=TRUE.

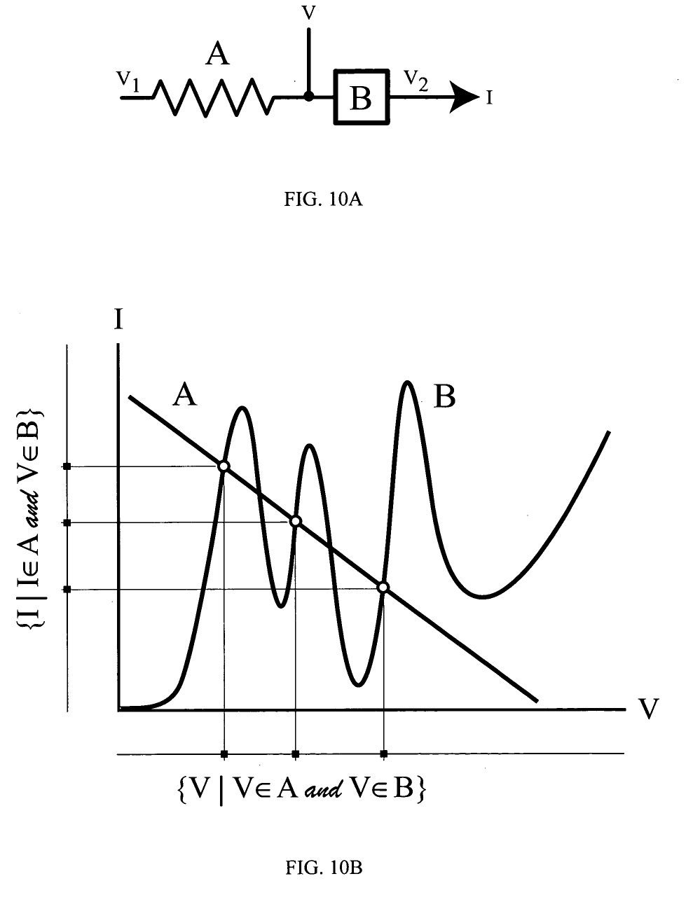

FIG. 10 shows how a simple circuit can provide analogues of different sets. In this example, the resistor A can be defined by 3 circuit variables V₁,V,I and One physical variable R. Together, the variables {V₁,V,I,R} and constraints on their values completely define the device A. Similarly, the variables {V,V₂,I,σ} and constraints completely define device B. If, however, we only observe the current I, we have a circuit operating in current-mode, and if we only observe V≡V₁-V₂ we have a circuit operating in voltage-mode. However, it is always necessary mat {V₁,V,I,R} be a valid set of values for device A and {V,V₂,I,σ} be a valid set of values for device B, regardless of what is observed.

### Stability

We discuss here the effect of stability of the circuit on the analogue sets.

We note that in the previous figure not all the intersections between the two device characteristic functions were marked and included in the analogue sets. The reason for this is that the missing intersections are unstable: if an attempt is made to put the operating point to one of these intersections, it will spontaneously (and very rapidly) relax to a nearby point that is stable. Alternatively, under the right circumstances, the device or circuit can enter a closed limit cycle and oscillate forever in its phase space, e.g., I(V).

FIG. 11 shows the effect of stability on a circuit consisting of two arbitrary devices connected in series.

FIG. 11A shows the circuit. The circuit variables are taken to be the current I through the devices and the voltage V between them.

FIG. 11B shows the characteristic curves for the two devices. Kirchoff's Laws require that the operating point lie on both curves, hence it must lie at their intersection.

The stability of dynamical systems such as these circuits is well-understood. The general approach is to linearize the system in the vicinity of a singular point, and examine the effects of inevitable infinitesimal perturbations. For two devices connected in series, there is a very simple requirement for stability: at their intersection, the curve for the “upper” device (the load line) must be decreasing and the curve for the “lower” device (the drive line) must be increasing. This criterion is purely local: the behavior in the vicinity of other intersections is irrelevant. Furthermore, the criterion is sufficient: if the intersection has the proper sense, it will be stable. Thus, no matter how complicated are the functions, wherever they intersect in the proper sense those points will be stable, and all other intersections will be unstable.

It is clear that the major effect of instability will be to “filter” the possible sets for the “allowed” values. This effect highlights the major difference between physical devices and mathematical devices. Physical devices include processes that mathematical devices do not have, and these processes “forbid” certain values. This fact should not be a surprise, however—it is familiar in the band gap of semiconductors and insulators, the eigenmodes of confined systems, the discrete spectra of atoms, etc. This circumstance is one more reminder of the necessity to be careful when establishing the analogue between physical devices and sets suggested by incomplete models of those devices.

A general property of nonlinear devices is that their states form a single curve in the appropriate phase space. For instance, a complex device with multiple regions of NDC will still have a single curve connecting these regions, and while the curve can be twisted, bent, and wrapped into tight Curves, it cannot intersect itself. Thus, if we connect such devices, we are equivalently overlaying two curves, one which asymptotically goes from (−∞,−∞) to (+∞,+∞), i.e., up to the right, the other of which asymptotically goes from (+∞,−∞) to (−∞,+∞), i.e., down to the right. In the region of interest, these curves may be very complicated, and may have many intersections, of which some will satisfy the criterion described previously.

### Accessibility

One of the device axioms listed above is accessibility: the ability to reach all states that define the device or circuit. Indeed, if certain states are inaccessible, we would be justified in omitting them from the definition of the device. However, if the curves have isolated stable intersections, we may ask how we can jump from one stable state to another, i.e., select one member of the analogue set or another.

FIG. 11C shows how the circuit can be switched between two different stable discrete states. Assume for the moment that the circuit is in one state (“1”). If either the IN or OUT variable (the current I or voltage V), or both, is suddenly changed to different values, the circuit momentarily (“virtually”) goes to that point. Very quickly, however, the circuit senses that it is unstable, and it relaxes to some stable point. The process of relaxation will be to find “allowed” values for both devices. The exact trajectories are not important (and not generally known), but the choice of virtual point determines the final stable state.

FIG. 11D shows the characteristic functions for two complex devices in series. Of the 15 intersections, only 4 are stable. Jumps between these 4 stable states can be made by pulsing the circuit into the vicinity of a different state, allowing it to relax to the stable state;

### Discrete Sets

Here we show how a circuit can generate discrete sets.

The stable intersections of two devices in series provide a simple means to obtaining discrete sets; the members of the sets are just the circuit variables at the inters characteristic curves.

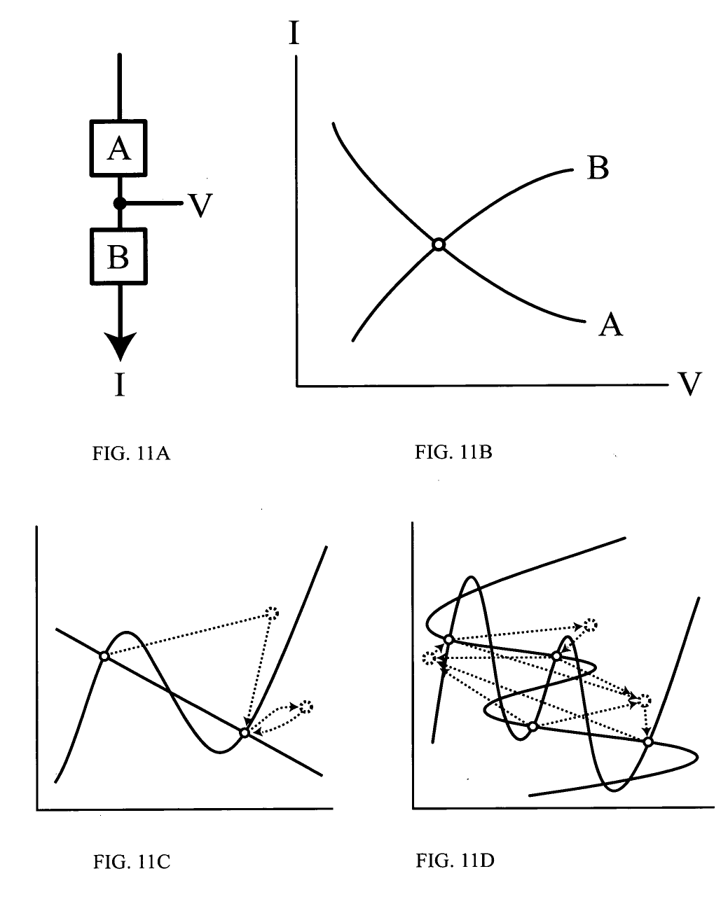

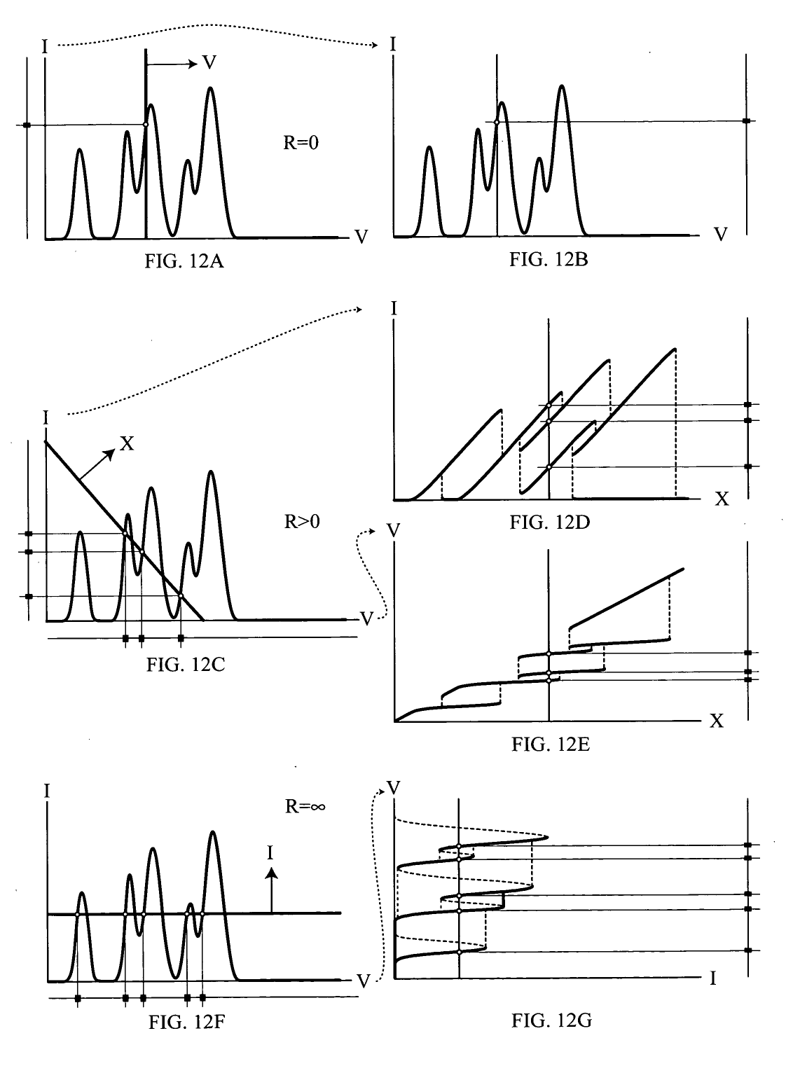

FIG. 12 shows how a simple circuit can produce a variety of discrete sets. The circuit consists of a resistor in series with an arbitrary device, the latter having a relatively complex characteristic curve consisting of 5 peaks.

FIG. 12A shows the current-voltage relation in the case R=0, i.e.; the resistor is just a short circuit. The characteristic curve for this resistor is a straight vertical line, positioned at an arbitrary voltage V. The value of the independent variable V can be set arbitrarily; the value of the current I is the value of the characteristic curve at that V. Thus, at any value of V, the set is a single discrete value of I. We can scan V to trace out the curve I(V) representing a continuum of discrete sets, shown in FIG. 12B.

FIG. 12C shows the case when the resistance R>0 is finite. The characteristic curve for the resistor is now a straight line with negative slope. Either intercept I(V=0) or V(I=0) can be set; the resistance then determines the slope and the other intercept. The intersections of the load line and the drive curve define a discrete set of the current I and another discrete set of the voltage V. These sets can be generated for any placement of the resistor load line, but its slope must always be the same (for a given value of the resistance). Thus, we can imagine scanning this line transverse to itself (X) to trace out the curves I(X) and V(X) representing two continua of discrete sets. FIG. 12D shows the stable states I(X) and FIG. 121E shows the stable states V(X).

FIG. 12F shows the case that the resistance is infinite. The characteristic curve for this resistor is a straight horizontal line, positioned at an arbitrary current I. The intersections of this line and the device characteristic define a discrete set of the voltage V. This sets can be generated for any placement of the load line. Thus, we can imagine scanning I to trace out the curves V(I), representing segmented continua of discrete sets, shown in FIG. 12G.

### Multi-Interval Sets

Here we show how a simple circuit can be used to generate multi-interval sets.

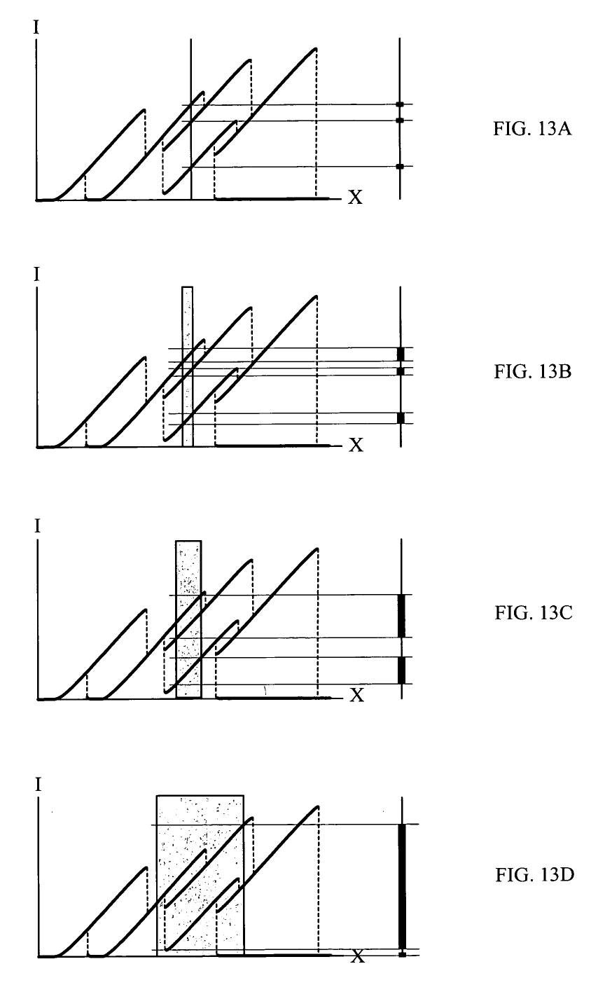

FIG. 13 shows how a simple circuit can generate multi-interval sets.

FIG. 13A reproduces the case shown in FIG. 12D, showing a collection of values of the current I obtained as the operating point X of the circuit with finite resistance is scanned. The selection of one operating point X defines a finite set of discrete values.

Now, however, let us assume that the operating point X can be set arbitrarily within a range of values. The result is that the current sets defined by the intersections are broadened into intervals, and these intervals expand, eventually merging into a single interval, as shown in FIGS. 13B,C, D.

The price we pay to obtain the interval sets is that we have to introduce additional circuitry to generate the scan. This example illustrates two very general principles:

(1) The constraint introduced by connecting devices together results in reduction of the dimension of the analogue sets. The intersections of curves results in points, and the intersection of curves with an interval results in an interval.

(2) The combination of even(very simple nonlinear devices with continuous behavior can lead to discontinuous behavior. It is the existence of NDC that enables the discontinuities.

From the discussion above about using data as control, we can imagine the interval sets generated with this circuit to be available for scanning the operating point of another circuit. Thus, we can imagine a sequence of interval sets, potentially arbitrarily complicated, deriving from relatively simple circuits containing one or more nonlinear devices. Conceptually, this is the simple process of iteration, or nested functions, and here we find the usual situation: unlimited iteration leads to unlimited complexity. We stipulate that such complexity is equivalent to computation.

Obviously there is a complementary collection of voltage sets that behave similarly.

### Device Parameter Analogue Sets

Here we show how we can generate analogue sets by changing the device parameters.

Previously, we generated the sets by setting the operating point of the simple circuit, and scanning that operating point within a finite range, but assuming that the circuit devices have fixed values. Thus, for the simple circuit described just previously, we assumed the resistor had a fixed resistance R. Now we consider changing the resistance, holding some part of the circuit operating point fixed.

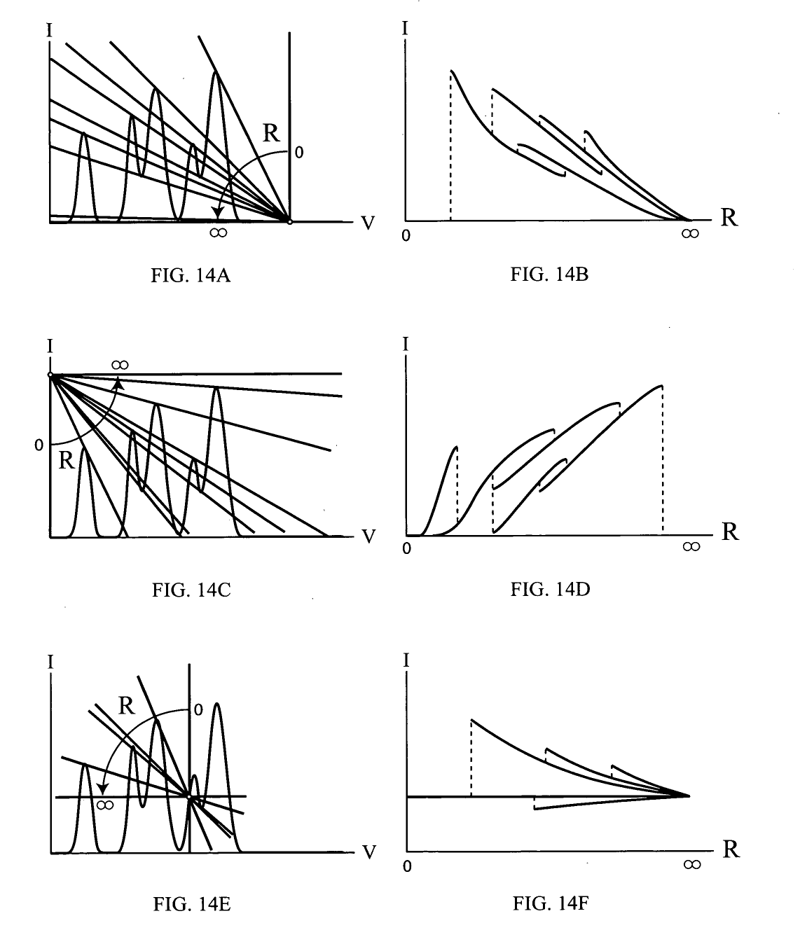

FIG. 14 shows the effects of changing the resistance in the series circuit.

We consider three cases, in each biasing the circuit to a fixed value of I,V, and increasing the resistance R from zero to infinity to scan across the characteristic functions. As R varies across 0→∞, the characteristic function (line) rotates from vertical (R=0) to horizontal (R=∞); its stable intersections with the characteristic function of the other device determine the points in the analogue sets.

FIG. 14A shows the effect of setting the operating point to I=0,V>0.

FIG. 143B shows the effect of setting the operating point to I>0.V=0.

FIG. 14C shows the effect of setting the operating point to I>0.V>0.

All these cases exhibit a set of 5 curves, each generated by the rising portion of the curve on one of the 5 peaks in the device function. The values of these curves at any value of R constitutes a discrete analogue set. If we consider scanning the resistance within a range, we will define interval sets as done above.

Another way to operate this circuit is to set the operating point on one peak, and then scan only along that peak, the limits being when the circuit jumps discontinuously to another peak). This scan defines a single interval set that is one of the curves shown in FIGS. 14B,D,F.

### Analog Precision

Precision is usually associated with the number of significant digits, or the number of bits defining a data structure. What is the comparable concept for analog data?

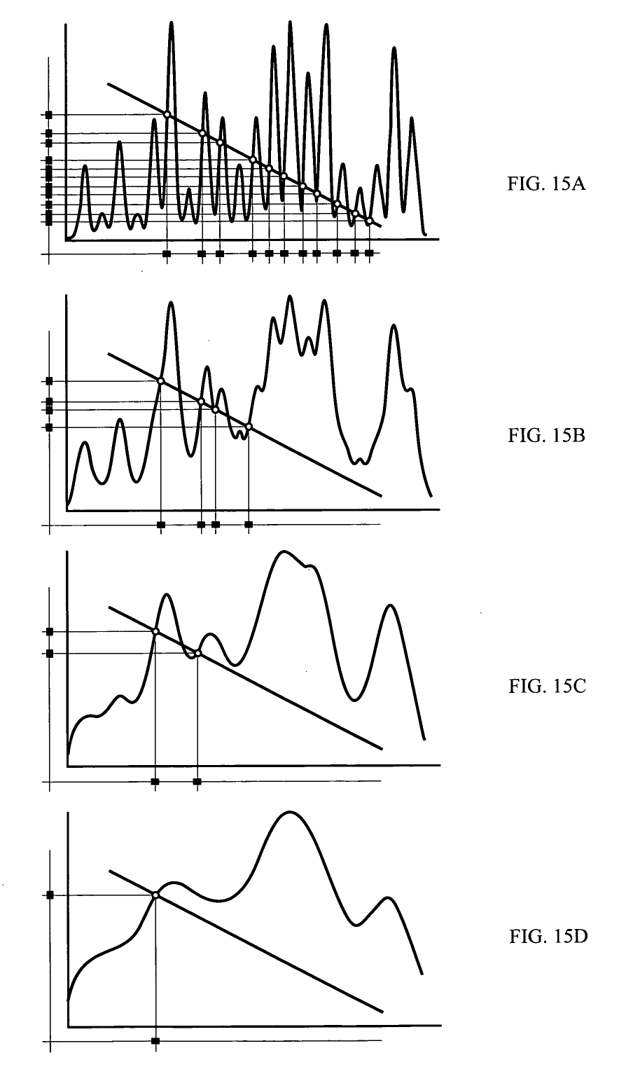

FIG. 15 shows how we can conceptualize analog precision.

The figure shows a sequence of functions with decreasing detailed structure. The functions are “fuzzy digital numbers,” by which we mean a digital number whose digits are replaced by peaked functions. Each peak has the value of the corresponding digit, and its width w is defined to be the same for all digits. For a number N, we define its fuzzy digital number as N*w, where w is the common Gaussian width. In this case, the number is pi=3.1415926535897932385 and the width is 1, so the fuzzy digital number is (neglecting the decimal point) pi*w=31415926535897932385* 1. The function is generated by adding Gaussians of the same width for each digit, the position of the peak being the position of the digit.

FIGS. 15A,B,C,D show functions of successively lower detail. These functions are generated by increasing the width of the Gaussians. Intuitively, the smoother functions correspond to lower precision, and this is borne out by the fact that the bottom function can be generated with significantly fewer digits: this function corresponds acceptably well to the fuzzy digital number 3695*7.

The figures also show a resistive load line intersecting each function. The intersections of the drive and load lines define various discrete sets for the input and output variables.

The correspondence of functional structural detail with precision is also consistent with the use of devices in circuits defining analogue sets. The first function generates a set with 11 members, while successive functions generate 4, 2, and 1 members, respectively. This is consistent with the idea that complex devices or circuits correspond to high precision analog data, while simpler devices and circuits correspond to lower precision data.

The concept of analog precision will be crucial to implementing this invention for practical computation. As noted elsewhere, computation consists of various cycles of aggregation and evaluation. In evaluation we replace a complicated, high-precision analog function with a simpler, lower-precision function, thereby keeping the circuit from growing uncontrollably. Controlling precision will be a crucial part of designing the circuits.

### Circuit Analogues of the Empty and Universal Sets

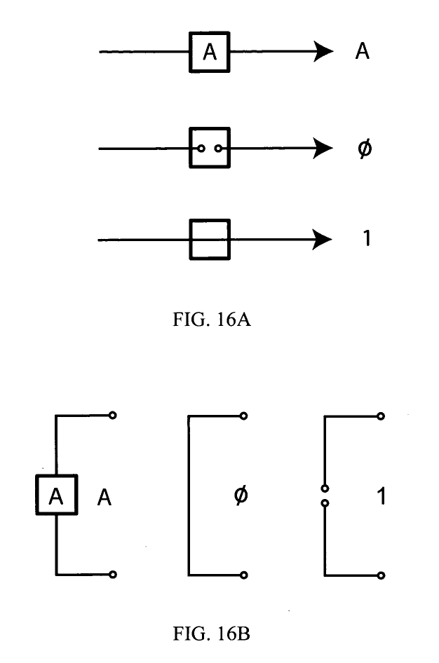

FIG. 16 shows circuit analogues for null and universal sets.

FIG. 16A shows these analogues in current-mode.

The close formal relationship between the empty set Ø and the number zero, and between the universal set 1 and the number one, suggests that we can assign circuit analogues for these special sets. In current-mode, zero current (I=0) would flow through an open circuit, while any current (I=1) could flow through a short circuit. Therefore, we identify the physical analogues of the null set Ø and the universal set 1 for current-mode circuits as

A(I=0) [symbol] Ø (open circuit)

A(I=1) [symbol] 1 (short circuit)

where by I=1 we mean that the current can have any value.

FIG. 16B shows these analogues in voltage-mode.

Similarly, in voltage-mode, zero voltage (V=0) would appear across output terminals that are shorted together, while any voltage (V=1) could appear across terminals that are open. Therefore, we identify the physical analogues of the empty set Ø and the universal set 1 for voltage-mode circuits as

A(V=0) [symbol] Ø (short circuit)

A(V=1) [symbol] 1 (open circuit)

In I,V-mode, both the voltage across the device and the current through it will be observed. A particular state of this device will be {I,V}. Using the analogues above, we have

A(I0,V=0) [symbol] <Ø,Ø> 9nullator) (e.g., ground short)

A(I=1,V=0) [symbol] <1,Ø> (current source) (e.g., superconductors)

A(I=0,V=1) [symbol] <Ø,1> (voltage source) (e.g., batteries)

A(I=1,V=1) [symbol] <1,1> (norator) (e.g., fixator)

We see quite generally that zero (the null state) is the analogue of the empty set, and any (the unity state) is the analogue of the universal set:

(zero value) 0 [symbol] Ø (empty set)

(any value) 1 [symbol] 1 (universal set)

### Circuit Analogues of Logical Implication

Set Theory includes first-order logic, which includes logical implication, norm indicated with the symbol a→b, where a→b means “if a, then b.” We are able to define simple devices and circuits that are the analogues of implication, and we present these here. These are not, however, part of this invention, since they are elementary and common knowledge.

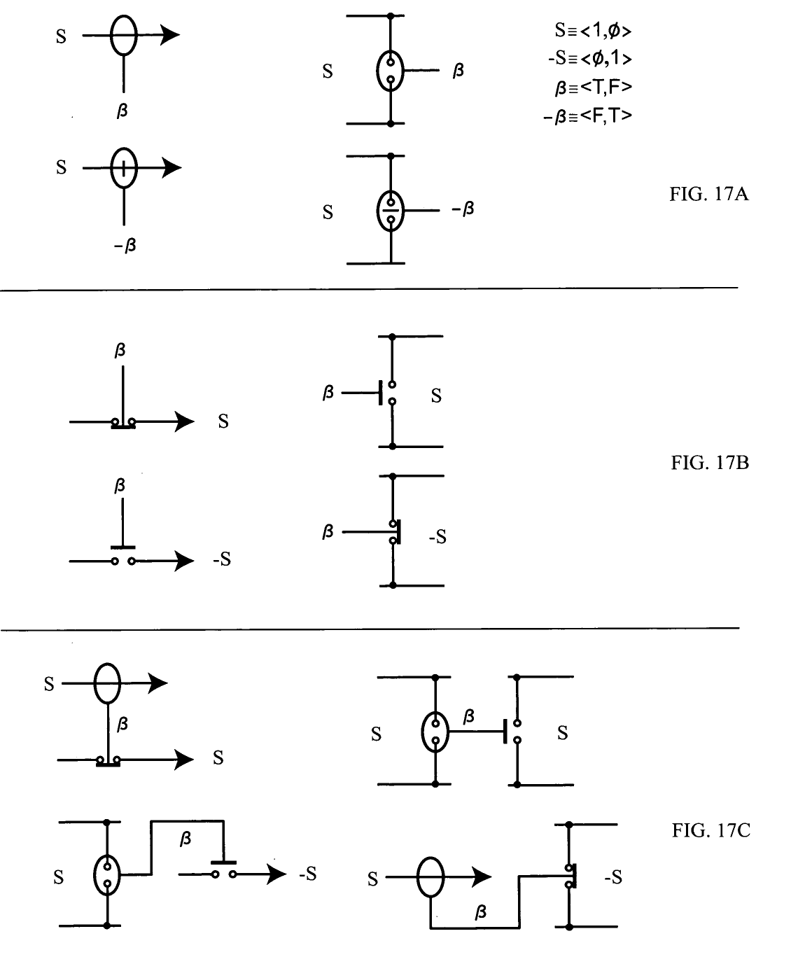

FIG. 17 shows circuit analogues of involving logical implication.

FIG. 17A shows devices that are commonly called sensors. These devices sense the currents and voltages, and generate a signal β that is TRUE if the variable is nonzero and FALSE if it is zero. Thus, these devices are the circuit analogues of the logic expression

S→β

where S is the circuit state S=<1,Ø> and β=<T,F> is a Boolean variable. These circuits therefore implement Boolean implication: the circuit S implies the Boolean β. The two symbols with the additional bar in the symbol imply inversion, that is, the logical output is the complement of the normal implication. By convention, −S<Ø,1> and −β=<F,T>.

FIG. 17B shows devices that are commonly called switches. These devices sense a logical input β and convert it into a signal that modifies currents and voltages. If β is TRUE, the “handle” on the switch is “pulled,” resulting in opening or closing the switch, which in turn either fixes the current or voltage to zero, or allows an arbitrary value of the current or voltage. If, however, β is FALSE, the switch handle is “pushed,” having the complementary effect on the circuit. Thus, these devices are the circuit analogues of the logic expression

β→S

where β is a logical variable and S is a circuit state. These circuits therefore implement set implication: the Boolean β implies the circuit S.

FIG. 17C shows circuits that combine sensors and switches. The input circuit S generates a Boolean β that in turn generates the output circuit S′. These 2-part circuits are the analogues of

S→β→S′

which is referred to as transitive implication. These circuit analogues will be essential for implementing circuits using this invention.

### Circuit Analogue of the Membership Relation

All forms of Set Theory are predicated on a single relation that introduces a new 2-operator ∈(x,X):

x∈X,

which is taken to mean that “the object x is a member of the set X.” The entire set comprises all possible instances of x, viz.:

X≡{x|x∈X}.

Among the conditions we assumed in this invention is that the states of devices and circuits are stable, and we have given numerous examples of stable sets, as well as the consequences of instability. Here we consider a specific circuit that implements the membership relation.

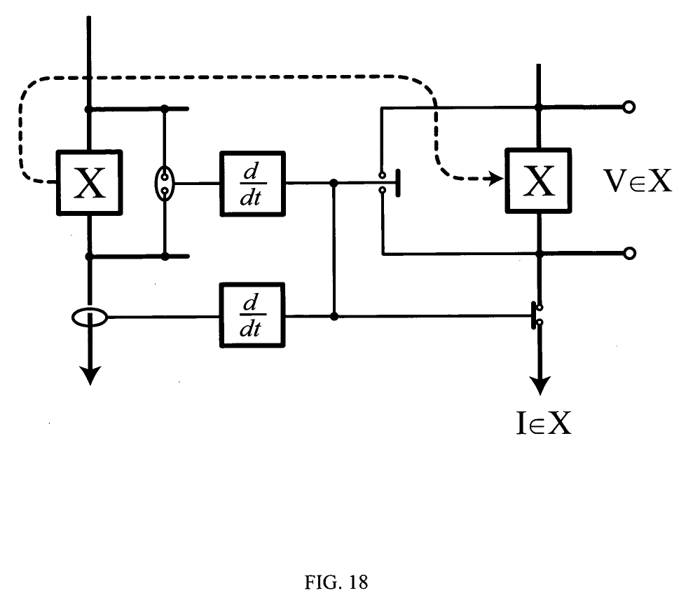

FIG. 18 shows a circuit that is the analogues of the set membership relation. This circuit is both current-mode and voltage-mode. That is, it represents two data sets: the current through it and the voltage across it. In order to have an output uncoupled from the input, we create a clone of the device. The circuit has a sensor for the current and one for the voltage. These signals are brought into modules d/dt that generate the time-derivatives. If either the voltage or the current is time-varying, the switches are operated (the current switch opens and the voltage switch closes), and the current and voltage outputs of the clone circuit are set to zero.

We reiterate that this invention assumes that I=0 and V=0 are values associated with the empty set Ø, not with members of any nonempty set. Thus, setting them to zero is the analogue of replacing a nonempty set with the empty set. The net result of this arrangement is that for the output of the circuit to represent a nonempty set, that set must be constant, which is the requirement we set in this invention. The intrinsic time constant of these circuits will be determined by their inductance and capacitance; computation is meaningful in this invention only if the circuits are allowed to settle to stationary states after a change.

Ordered vs. Unordered Sets

The question arises whether we should represent the device analogue set X as an ordered set or an unordered set. That is, in conventional notation, should the elements X of a device set

[symbol]

{X|X∈ [symbol] } be X=<V₁,V₂,I,R> or X={V₁,V₂,I,R}?

The answer is that it can be either.

The argument in favor of unordered sets is: A particular set of measurements of the state of the device is represented as {V₁,V₂,I,R}. This is shorthand for more information, such as {“the value of V₁ is . . . ” [symbol] “the value of V₂ is . . . ” [symbol] “the value of I is . . . ” [symbol] “the value of σ is . . . ”}. This set of statements is the same, regardless of the order in which they appear, because by definition, V₁,V₂,I, and R are distinct variables [Megill, 2009]. Thus, whatever set we construct to hold the members V₁,V₂,I,R, it must be the unordered set {V₁,V₂,I,R }.

The argument in favor of ordered sets is: Consider the {V₁,V₂,I,R}-mode device ^{V}₁,^{V}₂,^{I,σ} [symbol] A specfic state of this device might be {a₁,b₁, c₁,d₁}, while another specific state might be {c₂,a₂,d₂,b₂}, etc. We could very well decide to rearrange all these sets in the specific order {b,a,d,c}. Having done so, all the sets representing the states would be in this specific order. This means that the set of all such state sets, namely {{b₁,a₁,d₁,c₁},{b₂,a₂,d₂,c₂}, . . . ,{bₙ,aₙ,dₙ,Cₙ}}, in which a,b,c,d take on all possible values satisfying the membership relation <b,a,d,c>∈ [symbol] would have all its members in the same order, and would therefore be the ordered set {<b,a,d,c>|<b,a,d,c>∈ [symbol] }. Note that any other ordered set is equally satisfactory: <c,a,b,d>∈ [symbol] <d,c,b,a>∈ [symbol] etc. These seemingly different sets are actually just different forms of the same functional relationship between a,b,c,d. For instance, they might represent the functions a(b(c(d))), b(c(d(a))), etc.

Thus, we find that we can represent the set of states of the device as {X|X∈ [symbol] }, where X is either an unordered or ordered set of the physical variables (or as subset thereof).

Of course, all these remarks apply equally well to circuits as to devices.

### Higher Dimension Sets and Dimensional Reduction

In this invention, we have emphasized the use of 2-terminal devices to generate 1D discrete and interval sets. However, it should be clear from the general formulation of modal devices and sets that circuit-set analogues can be defined for any number of variables. Obviously, if we use N devices each with M circuit variables, the maximum dimension sets are N×M, and this occurs when the devices are totally unconnected. Connecting any devices together introduces physical constraints in the circuits and corresponding constraints in the sets that reduce the dimensionality. Defining and managing the dimensionality will be a critical aspect of implementing and using this invention.

### Meaning of the Analogue Symbol

The symbol [symbol] was introduced to be suggestive of equality, but also to emphasize that the two objects in [symbol] A are very different. One of the objects [symbol] which we generally indicate in bold type, is a physical device or circuit. It is defined by a set of values which are accessible only by measurements with defined means and procedures. The other object A is a set, whose members are values that have a one-to-one correspondence with the physical values.

Formally, the symbol [symbol] signifies an equivalence relation, for which there are three requirements, all of which are satisfied for [symbol] :

Reflexivity: [symbol] and A [symbol] A

Symmetry: [symbol] A [symbol] A

[symbol]

Transitivity: [symbol] and B [symbol] then

[symbol]

In fact, [symbol] is essentially the same as the bi-implication [symbol] (“if and only if . . . ”). This is sensible, because by definition, every value valid for a device A has a corresponding member of the set A, and there are no “orphan” or “extra” values in either the device or the set. This means that the observation of any value in either object implies ( [symbol] ) the corresponding value in the other object.

### Circuit Anagloues of Set Operations

In the description above, we defined circuit-set analogues. In Set Theory we can combine sets to form compound sets, and in the laboratory we can combine devices to form compound devices (circuits). Intuitively, we sense that joining the devices physically is in some way analogous to combining the sets that they individually represent. But can we find compound sets and compound devices that are actually analogues?

In this section we answer this question affirmatively by showing circuits that are the analogues of all of the fundamental operations in Set Theory. This section contains the material that forms the core of this invention and on which the claims are based.

### The Fundamental Set Operations

All versions of Set Theory include a small number of fundamental operations for generating new sets. The most important of these are:

| Given set(s) | Operation | Expressions | Resultant set |
|---|---|---|---|
| A, B | Intersection | A ∩ B | Combination |
| A, B | Union | A ∪ B | Combination |
| A | Complement | 1\A | Combination |
| A, B | Difference | A\B | Combination |
| A, B | Symmetric Difference | A ÷ B | Combination |
| A, B | Equality | A = B | Boolean |
| A, B | Subset | A ⊂ B | Boolean |
| A, B | Proper Subset | A ⊂ B | Boolean |

In this section, we will introduce circuit analogues for all of these expressions. These circuits comprise the substance of the claims in this invention.

### Combination Sets

The first 5 relations in the table above, A∪B, A∩B, 1\A, AB, and A÷B, are combination set relations. These relations enable us to generate new sets from input sets A,B, and 1. Suppose we have two devices A,B representing sets A,B as described above. While Set Theory guarantees that we can combine A,B to form new sets, it is by no means obvious that we can combine the physical devices A,B to form compound devices that correspond to the combined sets. That is, given

A [symbol] A

B [symbol] B,

and a combined set S(A,B), can we combine the devices such that the combined devices form the analogue of the combined set, i.e.,

C(A,B) [symbol] S(A,B)?

This is only one of many similar questions that could be posed regarding sets and analogues. We answer this question in the affirmative by providing explicit circuits that implement analogues of the fundamental operations. Elsewhere in this specification, we discuss a variety of other similar questions.

Boolean Sets

The last 3 relations in the table above, A=B, A⊂B, and A⊂B, are Boolean set relations. Each of these relations will be either TRUE or FALSE, i.e., they map the input sets A,B to the Boolean set {TRUE, FALSE}. The task is to define circuits that will accept A,B as input and give either TRUE or FALSE as output.

We will implement these circuits using the analogues already developed, making use of certain bi-implications from Set Theory. We chose to implement first the test for equality A=B (and its trivial dual A≠B), and then use it to define subset A⊂B and then proper subset A⊂B. Thus, we will use the implication series A÷B=Ø→A=B→A⊂B→A⊂B. Any other sequence that uses identities from Set Theory is also a valid means to generate circuit analogues of these set tests.

### Analogues Rigorously Defined

We collect here our definitions of circuit analogues of sets and set operations.

### Circuits and Sets

Circuits (in which we include individual devices) are defined by the allowed values of their physical variables, which consist of tuples of values of the independent physical variables: voltages, currents, material parameters, and external fields.

Sets are defined by their members, which in this invention means values corresponding to real numbers (or the numbers themselves).

Set operations are defined by asserting that the members of a set are given by a rule for combining the members of two or more sets.

### Simple Analogues

A circuit is the analogue of a set (A→A) if, for every valid combination of some of the physical variables, there is a corresponding member of the set, i.e., x∈A→x∈A.

A set is the analogue of a circuit (A→A) if, for every member Of the set, there is a corresponding valid combination of some of the physical variables, i.e., x∈A→x∈A.

A circuit and a set are analogues if A [symbol] A.

### Compound Analogues

A circuit C(A,B) compounded from circuits A,B that are the analogues of sets A,B provides the analogue of the set operation S if the circuit is the analogue of the set S(A,B), i.e., C(A,B)→C(A,B).

A set S(A,B) compounded from sets A,B that are the analogues of circuits A,B provides the analogue of the circuit C if the set is the analogue of the circuit C(A,B), i.e., S(A,B)→C(A,B).

A compound circuit and a compound set are analogues if C(A,B) [symbol] S(A,B).

### Multiple Devices

Consider the set analogue of assembling multiple devices, without any connections between the devices. Imagine we merely place a collection of devices on the table, but do not connect them, or even number them. What set might correspond to this collection?

Before any constraints are introduced, the devices have completely independent physical variables. Thus, three devices might be

A [symbol] {{V₁,V₂,I,σ}|{V₁,V₂,I,σ}∈A}

B [symbol] {{V₁,V₂,I,σ}|{V₁,V₂,I,σ}∈B}

Z [symbol] {{V₁,V₂,I,σ}|{V₁,V₂,I,σ}∈Z}

Note that the membership relations {V₁,V₂,I,σ}∈A, etc., ensure that the values of {V₁,V₂,I,σ} are valid for the devices. Therefore, a complete set of physical variables for all 3 devices taken together is (omitting the membership relations):

C [symbol] {{V₁,V₂,I,σ}_{A},{V₁,V₂,I,σ}_{B}, . . . ,{V₁,V₂,I,σ}_{Z}}

which is equivalent to

C={A,B, . . . ,Z}.

That is, multiple unconnected devices are the circuit analogue of the unordered set of the individual device sets. Connecting the devices together will introduce constraints in the sets, viz.:

C={{A,B, . . . ,Z}|{A,B, . . . ,Z}∈C}.

FIG. 19 shows circuit analogues of an unordered set of sets in current and voltage-mode:

^{I}C={{I_{A},I_{B}, . . . ,I_{Z}}|{I_{A},I_{B}, . . . ,I_{Z}}∈C}.

^{V}C{{V_{A},V_{B}, . . . ,V_{Z}}|{V_{A},V_{B}, . . . ,V_{Z}}∈C}.

As usual, we abbreviate these expressions by omitting the full membership relations. Written out in full for 2 devices, we have (letting the notation be a bit loose):

^{I,I}C={{I_{A},I_{B}}|∃{V₁,V₂,σ}_{A}|{V₁,V₂,σ}_{A}∪I_{A}={V₁,V₂,I,σ}_{A}∈A|∃{V₁,V₂,σ}_{B}|{V₁,V₂,σ}_{B}∪I_{B}={V₁,V₂,I,σ}_{B}∈B}.

This is easily generalized to an arbitrary number of devices.

### Operation: Intersection

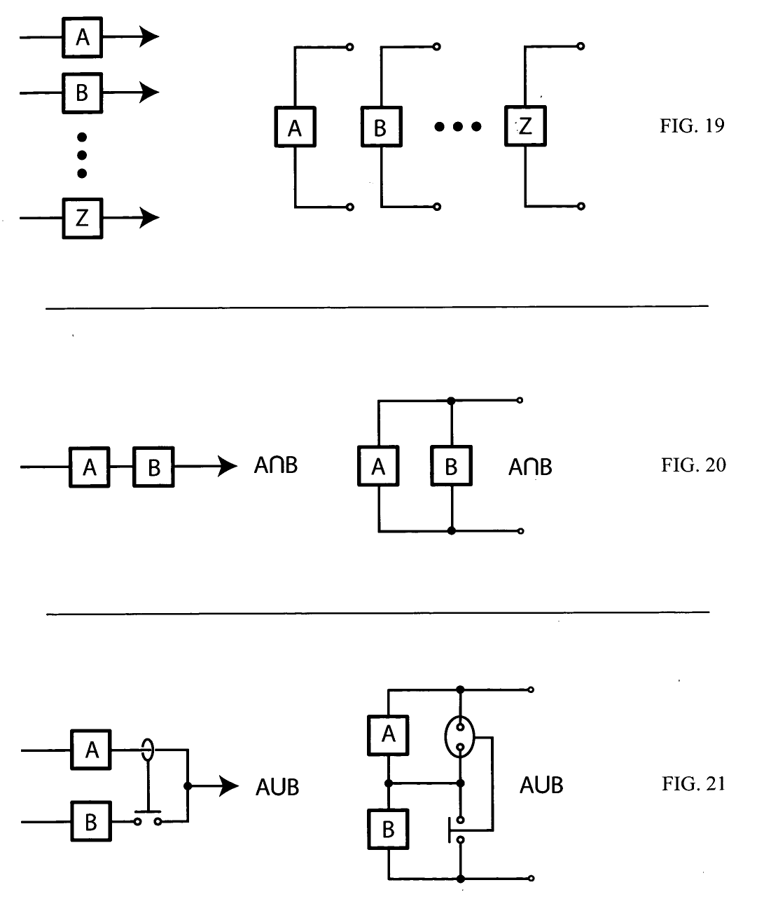

FIG. 20 shows circuit analogues of set intersection

A∩B.

These are very simple, being merely parallel and series combinations of two devices.

The argument that these circuits are the analogues of set intersection goes as follows. First, consider the current-mode circuit (FIG. 20, left). The current through each device must be a valid current for each device, i.e., I_{A}∈A and I_{B}∈B. But because the currents must be equal (Iₐ=I_{b}), the combination is

$$\begin{matrix}C ( A , B ) = \{ \{ {I}_{A} , {I}_{B} \} \vert {I}_{A} ∈ A \\ = \{ I \vert I ∈ A I ∈ B \} \\ = A ⋂ B\end{matrix}$$

where again the last step follows directly from the definition of the intersection. Thus, the series combination is the analogue of the intersection (for current-mode).

The argument for the voltage-mode devices (FIG. 20, right) is similar: We assume that there are controls on the devices that force establishing the voltage across each device. Thus, V_{A} must be a valid voltage for device A, i.e., V_{A}∈A, and V_{B} must be a valid voltage for device B, i.e., V_{B}∈B. Connecting the devices together in parallel forces these two voltages to be the same, V_{A}=V_{B}. In Set Theory, this is written

$$\begin{matrix}C ( A , B ) = \{ \{ {V}_{A} , {V}_{B} \} \vert {V}_{A} ∈ A \\ = \{ V \vert V ∈ A V ∈ B \} \\ = A ⋂ B\end{matrix}$$

where the last step follows directly from the definition of the intersection. Thus, the parallel combination is the analogue of the intersection (for voltage-mode).

One should take care with the direction of various implications. Thus, suppose the devices A,B represent sets A,B, and A∩B=Ø. If we were to connect A and B in series, we would always expect to find I=0, because if the devices truly are the analogues of disjoint sets, there cannot be any common current through them. Therefore, we can correctly write

A∩B=Ø→{I=0}

where the form {I=0} means that I=0 for all settings of the controls for the devices A,B.

Suppose we know all the values of the controls for each device A,B independently. If we connect the devices together to form the intersection and scan the two sets of controls, and we find I=0 for all combinations of the controls, we can conclude that A∩B=Ø. Thus,

{I=0}→A∩B=Ø

is also correct. Taken together, these two implications give the bi-implication

{I=0} [symbol] A∩B=Ø

which says that if the current is always zero the sets are disjoint, and vice versa.

Suppose we make only one observation I=0 for a pair of devices in series. Can we conclude that A∩B=Ø? The answer is no, since a different set of controls might give A∩B≠Ø. Therefore, I=0→A∩B=Ø is incorrect.

Suppose we find any set of controls for which I≠0 (even one solitary value), can we conclude that A∩B≠Ø? The answer is yes, because there must be at least that value of I_{A}=I_{B}≠Ø in common with both sets. Thus,

{>I≠0<}→A∩B≠Ø

where by {>x<} we mean “at least one value of x.” Furthermore, if we know that A∩B≠Ø, we also know that there must be at least one value I≠0, hence the reverse implication is also valid:

A∩B≠Ø→{>I≠0<}.

Taken together, these two implications give the bi-implication

{>I≠0<} [symbol] A∩B≠Ø.

These remarks should serve as both explanation and warning about the subtleties of making analogues between devices, circuits, and sets.

### Operation: Union

FIG. 21 shows circuit analogues of set union

A∪B.

These circuits involve a sensor-switch that implements the “or” relation.

The argument that these circuits are the analogues of set unions goes as follows: First, consider the current-mode circuit (FIG. 21, left). If there is any current through A, the switch in series with B is open, so the output current is I=I_{A}. If I_{A}=0, the switch closes, and the output current is I_{B}. The output current is the sum of the currents flowing through A and through B, but the switch forces there to be current through only one or the other branch: either (I_{A}≠0, I_{B}=0) or (I_{A}=0, I_{B}≠0), but (I_{A}≠0, I_{B}≠0) is prevented by the switch. The Set Theory expression describing that is

$$\begin{matrix}C ( A , B ) = \{ \{ {I}_{A} , {I}_{B \}} > \vert {I}_{A} ∈ A \\ ( I ≡ {I}_{A} \vert {I}_{A} \neq 0 I ≡ {I}_{B} \vert {I}_{A} = 0 ) \} \\ = \{ I \vert I ∈ A I ∈ B \} \\ = A ⋃ B\end{matrix}$$

where again the last step follows directly from the definition of the union. Thus, this circuit is the analog of the union (for current-mode).

The argument for the current-mode union circuit is the dual: As before, we assume that V_{A} must be a valid voltage for device A, i.e., V_{A}∈A, and V_{B} must be a valid voltage for device B, i.e., V_{B}∈B. Now suppose V_{A}=0. By design, the voltage sensor across A reads V_{A}=0, hence sets the switch across B to be open, allowing B to set the voltage across it. The total output voltage is men 0+V_{B}=V_{B}. Now suppose V_{A}≠0. The sensor across A now reads a nonzero voltage and closes the switch across B, setting V_{B}=0. Now the output voltage is V_{A}+0=V_{A}. The Set Theory expression describing this is

$$\begin{matrix}C ( A , B ) = \{ \{ {V}_{A} , {V}_{B} \} \vert {V}_{A} ∈ A \\ ( V ≡ {V}_{A} \vert {V}_{A} \neq 0 V ≡ {V}_{B} \vert {V}_{A} = 0 ) \} \\ = \{ V \vert V ∈ A V ∈ B \} \\ = A ⋃ B\end{matrix}$$

where the last step follows directly from the definition of the union. Thus, this circuit is the analog of the union (for voltage-mode).

These circuits clearly show the significant difference between the intersection (which is implemented as a simple parallel or series combination of the devices), and the union, which requires a logical operation (transitive implication):

V_{A∪B}=(V_{A}≠0) [symbol] V_{B} [symbol] 0

I_{A∪B}=(I_{A}≠0) [symbol] I_{B} [symbol] 0.

The asymmetric roles of A and B in A∪B should be noted. In both modes we accept the entire domain of A if it is non-null. If the domain of A is null, we accept the domain of B. If the domains of A and B are both null, we accept null. In contrast, for the intersection, there is only one domain, that in which neither A nor B is null.

The Euler-Venn diagrams for the union, valid for both voltage-mode and the current-mode, show how the circuit first attempts to explore the entire domain of device A, and if the particular value is valid for A, the circuit yields A. If A=Ø, the circuit searches the domain of B, and if the particular value is valid for B, the circuit yields B. If neither A nor B is valid, the circuit yields Ø. This combination corresponds to the union A∪B.

We could, of course, reverse the roles of A and B in the union, accepting the entire domain of B if it is non-null, and A if B is null.

The remarks made about the directions of implications for intersection analogue circuits also apply here.

### Operation: Complement

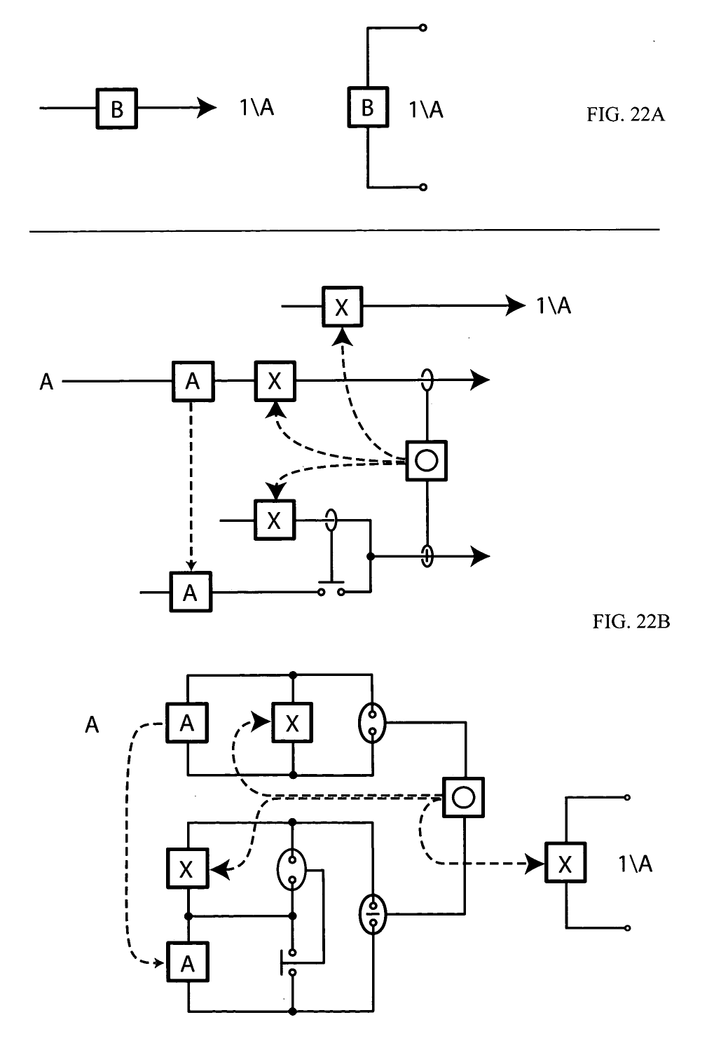

FIG. 22 shows circuit analogues of set complementation

1\A.

FIG. 22A shows one (brute force) way to generate the complement: we simply synthesize (fabricate) a new device B such that its allowed values are not allowed in A:

B [symbol] 1\A≡{{V,I}|{V,I}∉A}.

The device B is the analogue of the complement set, by definition of the complement. However, for very complicated devices A, fabricating B might be very time-consuming or expensive, and as we now remark, unnecessary.

Consider the two set-level equations

A∩X=Ø

A∩X=1.

It is a theorem of Set Theory that these equations imply

X=1\A.

This means that if we can solve the two equations for X, we have the complement 1\A. But we have just developed the circuits for forming the intersection ∩ and union ∪, and we defined the analogues of Ø and 1, so we are now able to form circuit analogues of the two equations and use the circuits to solve them for the complement 1\A.

FIG. 22B shows a circuit capable of solving the two equations above to yield X=1\A, in current-mode (upper) and in voltage-mode (lower).

Here is a description of how the current-mode circuit works: The circuit contains two identical devices A for the known set A and three identical devices X for the unknown set X. The module O represents a scanning device capable of setting the control values of X: If X satisfies both equations, X is disconnected, and therefore; does nothing. If X does not satisfy either equation, O is activated and searches for another value of X, continuing until it finds a satisfying value, then turns off.

The upper branch generates the intersection A∩X. For this to equal Ø the current through this branch must be zero. If it is, the switch is open and O is inactive. If A∩X becomes nonzero, the module O is activated, and scans the controls of X until A∩X is returned to zero, when it again becomes inactive.

The lower branch generates the union A∪X. For this to equal the universal set, it must be nonzero. If it is, the switch is open, and O is inactive. If A∪X becomes zero, the switch closes and O is activated, scanning the controls of X until A∪X again becomes nonzero, when it again becomes inactive.

Therefore, for any current into A, the circuit generates a set of correct controls for X such that it satisfies both equations. This is just the condition

X={x|xØA}

which is the definition of the complement.

The reason for the third X device is that we want it to be available as a separate device for use in subsequent circuits needing the complement of a given set A.

The operation of the voltage-mode circuit can be similarly described.

This circuit introduces a potentially great advantage: we may not actually need complete sets to carry out a specific calculation. For instance, suppose a set A contains both positive and negative values, but a specific calculation only uses positive values. Clearly it would be wasteful to compute the full complement 1\A, only to leave part of it unused. What we would like is a means to automatically generate the complement as needed, but neglect to complete the generation if it is not needed. This is equivalent to generating a subset.

The circuit just described has this character: it searches for a set X for which the complement relation is satisfied, but if some other part of the computer indicates that it is no longer needed, it can stop its search.

### Operation: Set Difference

Given the complement 1\B, we can use an identity to obtain the set difference:

A\B=A∩(1\B).

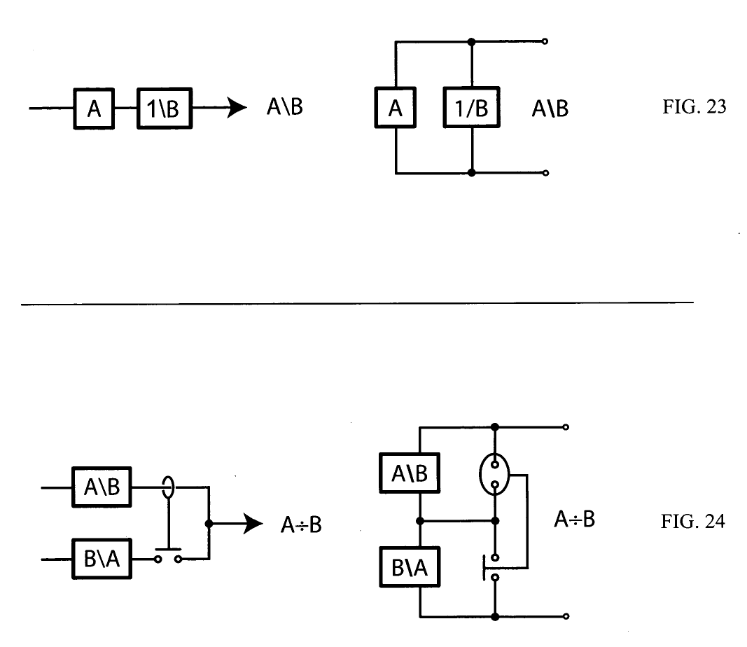

FIG. 23 shows hierarchical circuit analogues of the set difference A\B, in current-mode (left) arid voltage-mode (right). The device-level circuits for A\B are easily obtained by substituting the circuit for 1\B.

### Operation: Symmetric Set Difference

Given the set differences A\B and B\A of arbitrary sets A,B, we can use another identity to obtain the symmetric set difference:

A÷B=(A\B)∪(B\A).

FIG. 24 shows hierarchical circuit analogues for generating the symmetric set difference A÷B, in current-mode (left) and voltage-mode (right). The device-level circuits for A÷B are easily obtained by substituting the circuit for 1\B.

### Operation: Equality

Given the symmetric set difference, we can use a bi-implication to test for set equality:

A=B [symbol] A÷B=Ø.

A bi-implication means that if we can demonstrate that either side is valid, then the other side is valid.

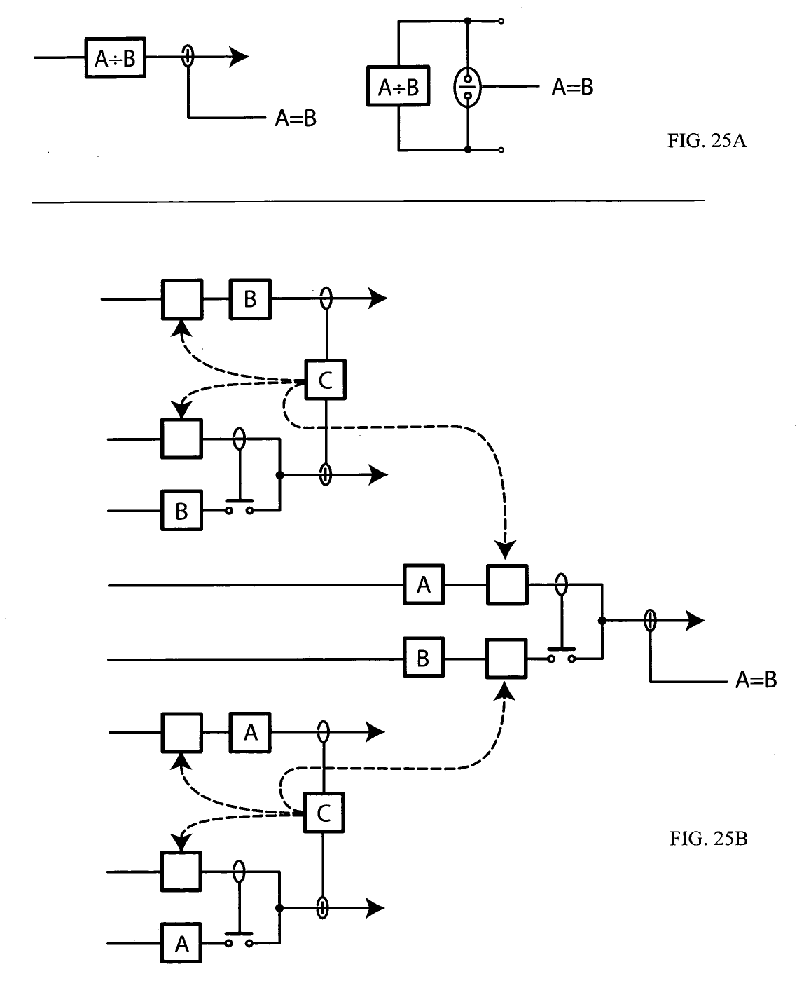

FIG. 25 shows circuit analogues for testing whether A=B.

FIG. 25A shows hierarchical circuit analogues for testing set equality, in current-mode (left) and voltage-mode (right).

Here is a description of how these circuits work: If A÷B=Ø, the output (current or voltage) of the A÷B circuit will be zero, hence the output will be logical TRUE, i.e., A=B. If A≠B, the output will be FALSE. Note that in order to obtain a non-inverted logical output, the complement logical implication is used (indicated by the bar in the sensor).

FIG. 25B shows the device-level circuit for testing for equality, in current-mode. This circuit is obtained by direct substitution of the device-level circuits. The voltage-mode version is easily obtained. Testing for inequality A≠B follows by inverting the logical signal A÷B≠Ø.

### Operation: Subset

Given the equality of two sets, there are several useful bi-implications that can be used to test for the subset:

A⊂B [symbol] A∩B=A

A⊂B [symbol] A∩B=B

A⊂B [symbol] A∩(1\B)=Ø

A⊂B [symbol] (1\A)∩B=1.

Since all of these involve testing the equality of two sets, we can simply use the equality test given in the previous section to do the subset test.

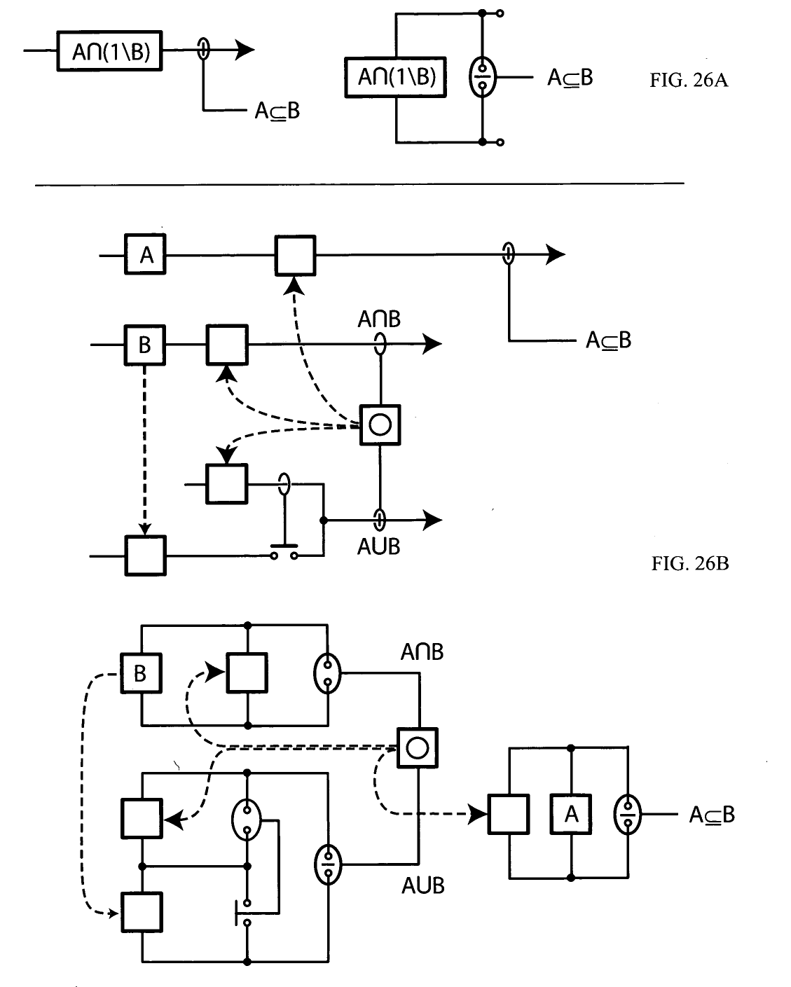

FIG. 26 shows circuit analogues for testing whether A is a subset of B.

FIG. 26A shows hierarchical circuit analogues of the third bi-implication above, as a test for the subset relation, in current-mode (left) and voltage-mode (right).

Here is a description of how these circuits work: If A∩(1\B)=Ø, the output (current or voltage) of the A∩(1\B) circuit will be zero, hence the output will be logical TRUE, i.e., A=B. If A≠B, the output will be FALSE. Note that in order to obtain a non-inverted logical output, the complement logical implication is used (indicated by the bar in the sensor).

Substituting the circuit for the intersection and complement will give the device-level circuit for testing A⊂B.

FIG. 26B shows the device-level circuit analogues of the third bi-implication above, a test of the subset relation, in current-mode (upper) and voltage-mode (lower).

Testing for non-subset A⊂B obviously follows trivially from A⊂B by merely inverting the logical signal, i.e., A⊂B≠Ø.

### Operation: Proper Subset

Given the subset and inequality of two sets, we can use another bi-implication to test for proper subset:

A⊂B [symbol] A⊂ [symbol] A≠B.

We can satisfy the right-hand side by implementing circuits A⊂B and A≠B, and using a Boolean to test for both being TRUE.

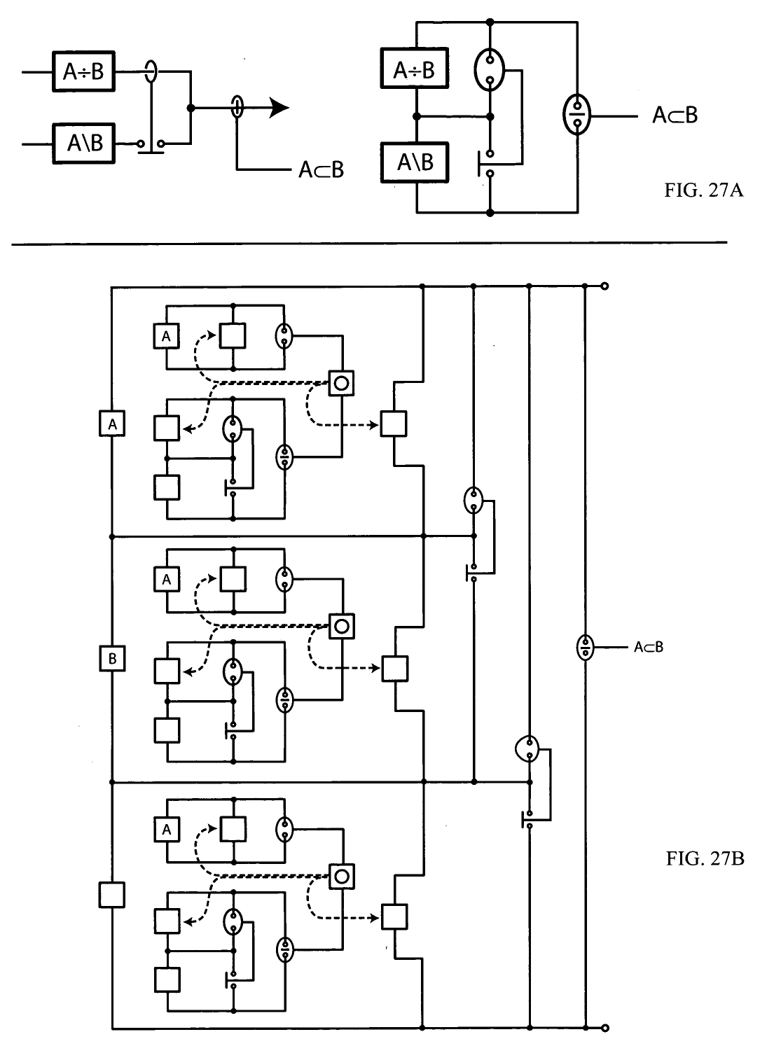

FIG. 27 shows circuit analogues of for testing whether A is a proper subset of B:

FIG. 27A shows hierarchical circuit analogues of the bi-implication above, which is the test for the subset relation, in current-mode (left) and voltage-mode (right).

Here is a description of how these circuits work: For both the voltage-mode and current-mode circuits, if A÷B≠Ø, the sensor will be TRUE and the switch will close, enabling the output to be A⊂B=FALSE. If A÷B=Ø, the sensor will be FALSE and the switch will open, enabling the output to be A⊂B=TRUE. Note that in order to obtain a non-inverted logical output, the complement logical implication is used (indicated by the bar in the sensor).

Substituting the circuit for the intersection and complement gives the device-level circuit for testing A⊂B.

FIG. 27B shows the device-level circuit analogues of the bi-implication above, a test of the proper subset relation, in voltage-mode. The current-mode version is easily obtained.

Testing for non-proper subset A⊂B obviously follows trivially from A⊂B by merely inverting the logical signal, i.e., A⊂B≠Ø.

### Summary: Current-Mode Circuit Analogues

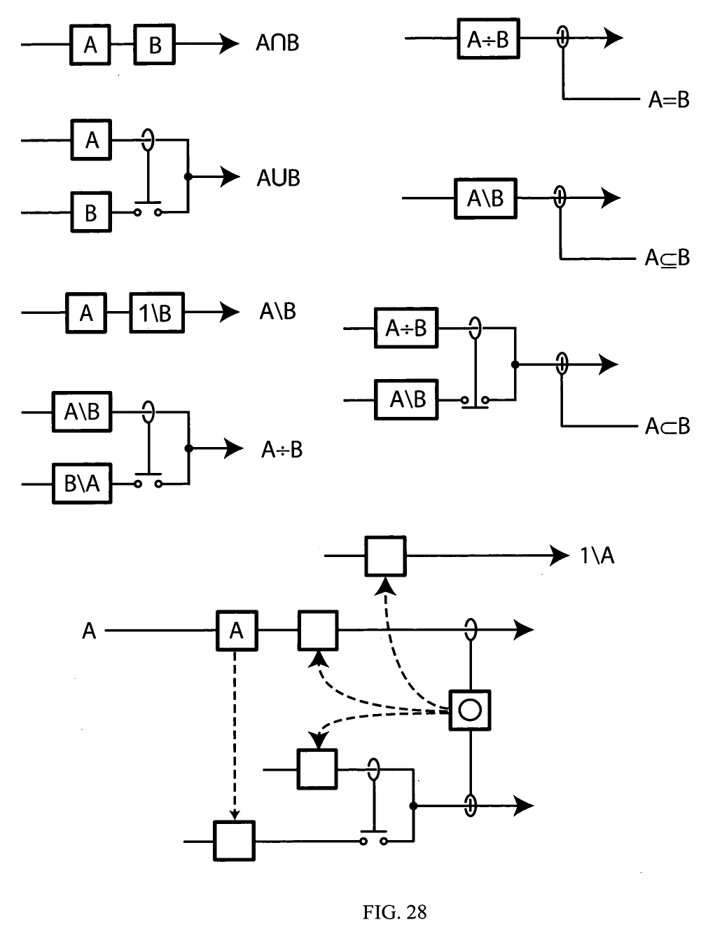

FIG. 28 shows the 8 fundamental circuit analogues, in current-mode. These circuits form the core current-mode modules from which analogues of almost all expressions in Set Theory can be assembled.

### Summary: Voltage-Mode Circuit Analogues

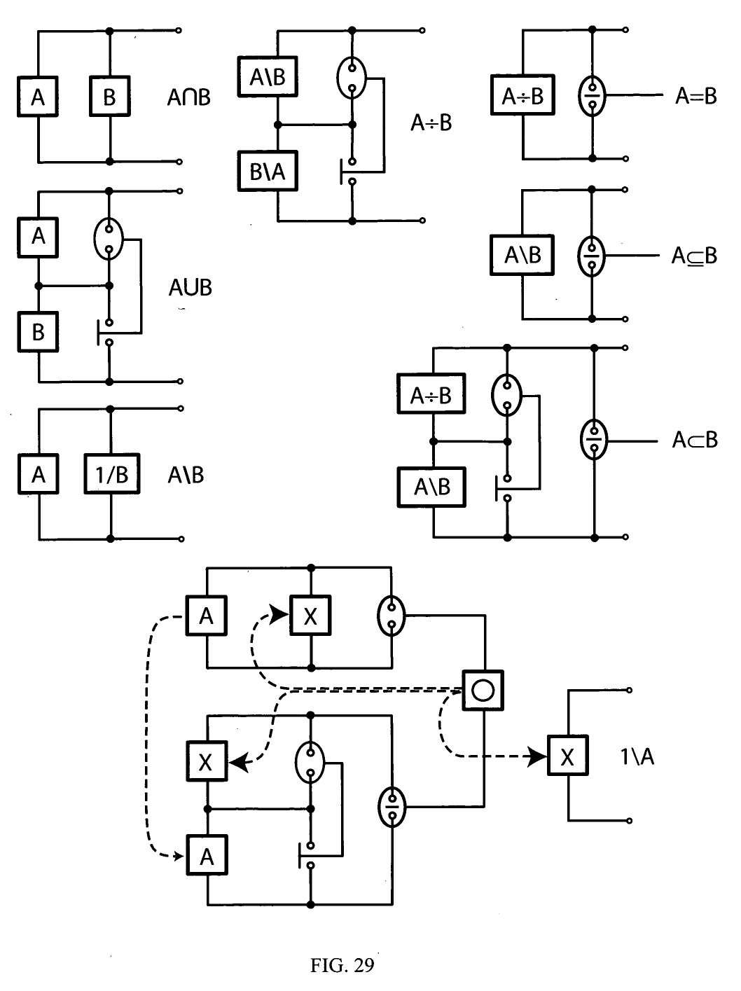

FIG. 29 shows the 8 fundamental circuit analogues, in voltage-mode. These circuits form the core voltage-mode modules from which analogues of almost all expressions in Set Theory can be assembled.

### Summary: Transfer Modules

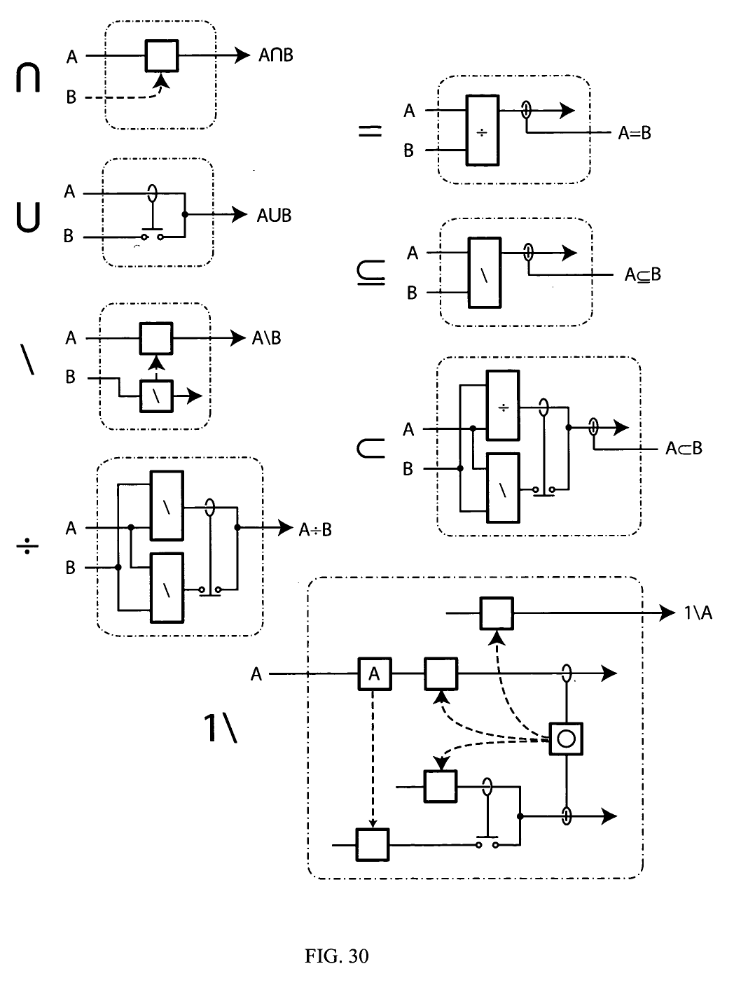

FIG. 30 shows the 8 fundamental circuit analogues, in current-mode, drawn in a uniform input/output modular form. The letters indicate input and output sets, under the operation indicated by the large symbol. Analogous circuits for the voltage-mode are easily drawn.

### Summary: Dataflow Modules

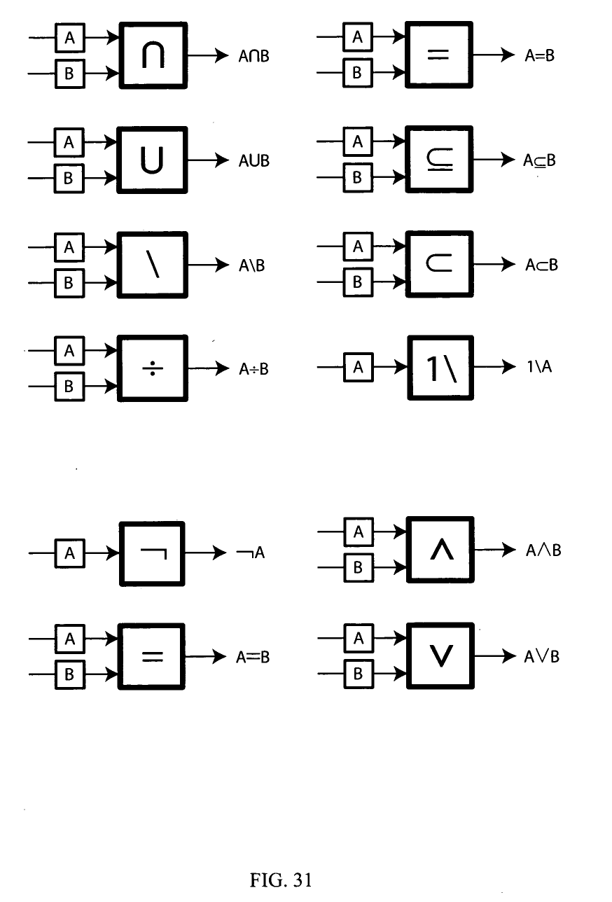

FIG. 31 shows the 8 fundamental modules together with the basic logical operations, drawn as dataflow modules convenient for designing circuits described in this invention. Circuits for manipulating and combining the Boolean variables are common knowledge and are included here only for reference.

### Assembling Set Analogue Circuits

In the previous section we defined circuits that are the analogues of fundamental operations in Set Theory. This material is the basis for most of the claims in this invention.

In this section we show various ways to use these circuits to assemble complete circuits that are the analogues of arbitrarily complex expressions in Set Theory. This material forms part of the basis for claims in this invention.

### Assembling Analogue Circuits

The process of assembling the circuit analogues into a full circuit is very simple. Essentially it involves successive substitution of a module corresponding to the set or operation in the expression. This process is a form of aggregation.

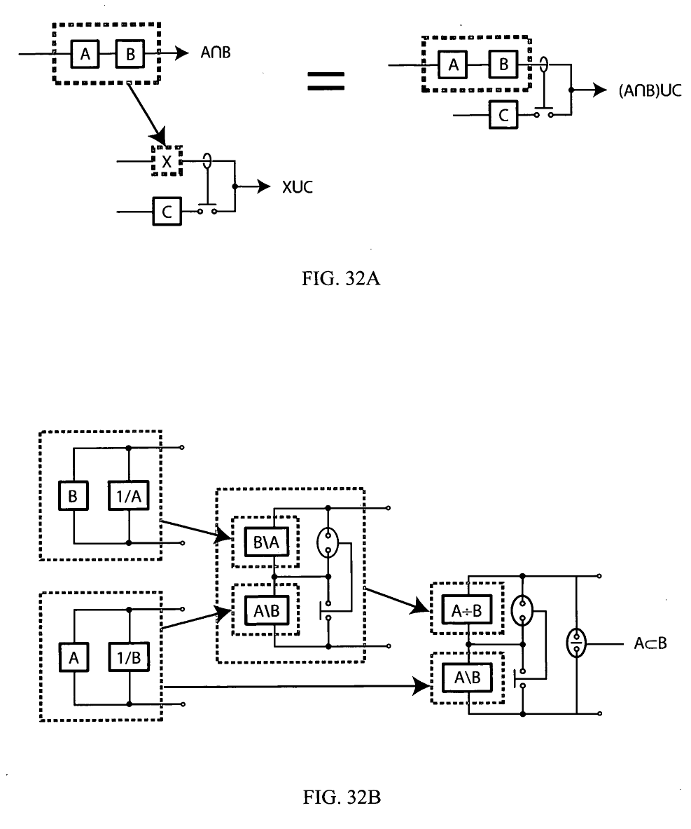

FIG. 32 shows examples of circuit aggregation, in current-mode.

FIG. 32A shows two circuit modules, the intersection and the union, in current-mode. Suppose we want the circuit for the expression

(A∩B)∪C.

One obvious procedure (shown) is to start with X∪C, and substitute X=A∩B for X. This is done in the circuits by simply connecting the module for A∩B in place of X.

FIG. 32B shows the circuit for generating the expression for proper subset, in voltage-mode

A⊂B.

This expression involves A\B and B\A, as well as the union of sets. While the circuit for generating the complement 1\B is fairly complicated, the process is exactly the same as before: substitute the appropriate circuit for the placeholder for the desired expression.

### Circuits: Tautologies

Using the basic circuit analogues, it is easy to verify that they can be combined to form small compound circuits that satisfy all the basic tautologies found in Set Theory.

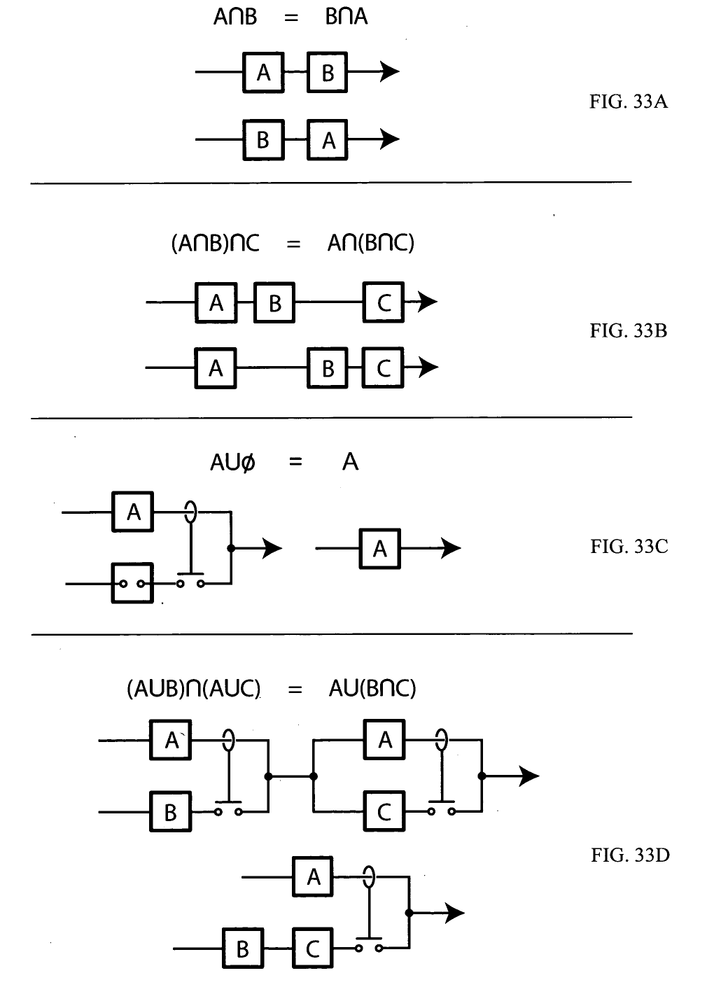

FIG. 33 shows examples of circuit analogues of identities, in current-mode. Each pair of circuits represents the same set, i.e., the analogue of the identity. The validity of these can be verified by enumerating the cases.

Here are descriptions of how these circuits work:

FIG. 33A. The current flowing through 2 devices in series is the same if the devices are interchanged, which is the analogue of the tautology

A∩B=B∩A.

FIG. 33B. The current through 3 devices is the same regardless of how the devices are grouped, which is the analogue of the tautology

(A∩B)∩C=A∩(B∩C).

FIG. 33C. The sum of the current flowing through a device A and zero current flowing through another device is just the current through A, which is the analogue of the tautology

A∪Ø=A.

FIG. 33D. The circuit is the analogue of the expression (A∪B)∩(A∪C). If the current through A is nonzero, it causes the both switches to open, preventing current through C and making the output equal to the current through A. If the current through A is zero, both switches are closed, and the output current is the current through B and C. The output current is therefore either the current through A or the current through B and C, which is the analogue of the expression A∪(B∩C). Hence, the circuit is the analogue of the tautology

(A∪B)∩(A∪C)=A∪(B∩C).

Comparable voltage-mode circuit analogues of these and other tautologies are easily drawn and understood.

### Circuits: Device-Level

Starting from the fundamental circuit analogues as given in the summaries above, and using the rules illustrated above, it is easy to assemble circuit analogues for any expression, no matter how complicated. These are referred to as device-level, because they are built using individual devices that represent sets.

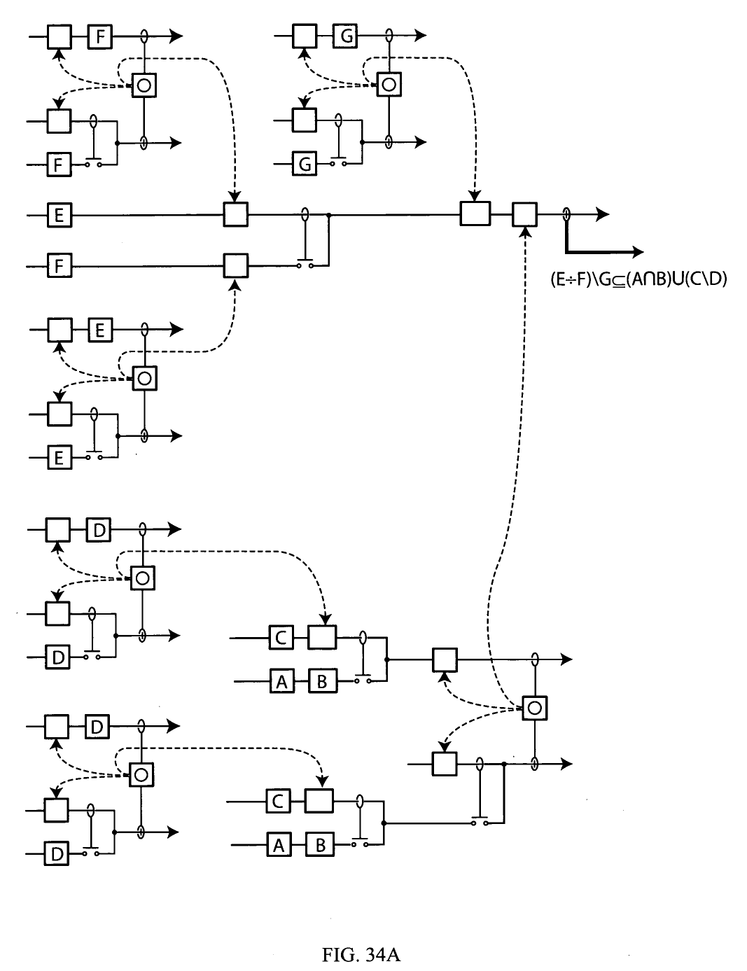

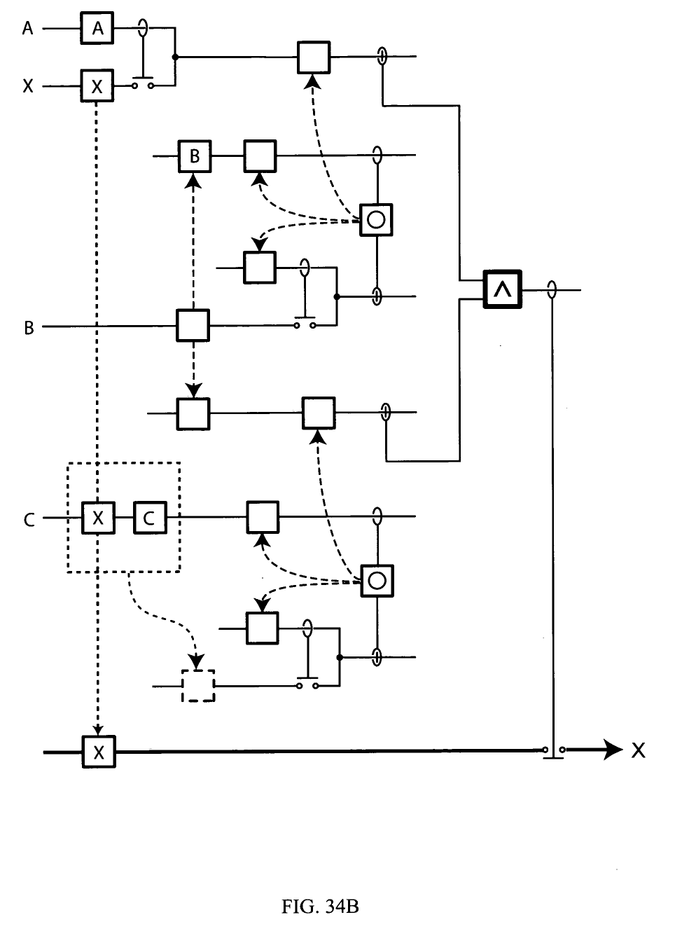

FIG. 34 shows examples of device-level circuit analogues, in current-mode.

FIG. 34A shows a device level circuit analogue of the expression

(E÷F)\G⊂(A∩B)∪(C\D)

which we interpret to be Boolean, in current-mode. The hierarchical nature of this circuit can be seen in the repeated structures, especially the modules for generating complements. The final output of this circuit is a Boolean; however, if we interpret the expression to mean a set (E÷F)\G under the condition that it is a subset of (A∩B)∪(C\D), then we could simply eliminate the output sensor and replace the last module before that sensor with a switch. This would have the effect of zeroing the current if the condition is not satisfied.

The same procedure can be used to assemble device-level circuits for multiple coupled constraints. The coupling links the circuits into a single circuit.

FIG. 34B shows device-level circuit analogue of the coupled expressions

(A∪X)\B≠Ø

B⊂X∩C.

This circuit implements a Boolean that verifies that both conditions are satisfied, and uses that Boolean to enable current through the set device X, which thereby determines X.

### Circuits: Canonical

It is sometimes useful to rewrite the set expression in a canonical form. For example, the chain set expression

A\X⊂(B∪X)∩C

can be re-written as

⊂(\(A,X),∩(∪(B,X),C))

in which the operations are all written in the form O(S,S). Another example is the expression

(A∪B)\C)∩D

which can be re-written as

∩(\(∪(A,B),C),D)

in which the operations are written in the form O(O(O( . . . ( . . . S,S),S),S). This form brings all operations to the left, and all sets to the right. The grouping of this expression is

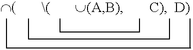

which makes it easy to assemble the circuit modules.

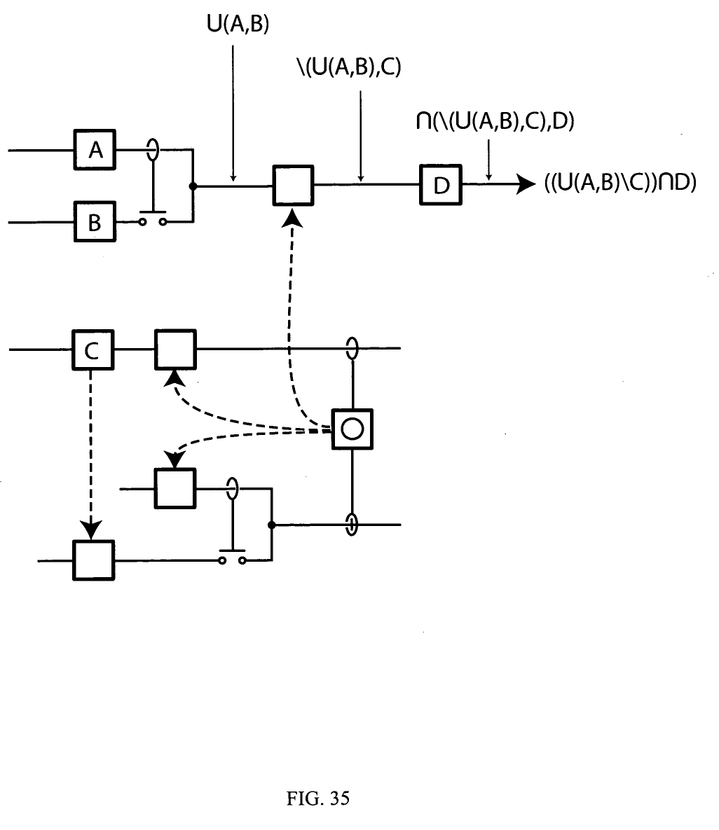

FIG. 35 shows a device-level circuit analogue for the canonical set expression ∩(\(∪(A,B),C),D), in current-mode. This circuit produces an output that is a set.

Here is a description of how this circuit works: The two devices A,B generate the union of the sets A,B in the upper circuit, while the lower circuit generates the set 1\C. The intersection of A∪B) and 1\C is (A∪B)C, and the intersection of that set with the set D is the desired set (A∪B)\C)∩D.

It is obvious that we could provide feedback from any point in this computation, including the output (A∪B)\C)∩D to modify the O module (which varies the clone sets to find 1/C), thus obtaining an adaptive circuit.

### Circuits: Hierarchical

It is sometimes convenient to assemble the circuits in hierarchical form, in which the various terms assembled according to convenience and connected by arrows. For instance, the chain set expression

(A\X)⊂((B∪X)∩C)

is of the form S⊂S, hence would have two circuit modules connected by arrows to a module that tests the subset relation.

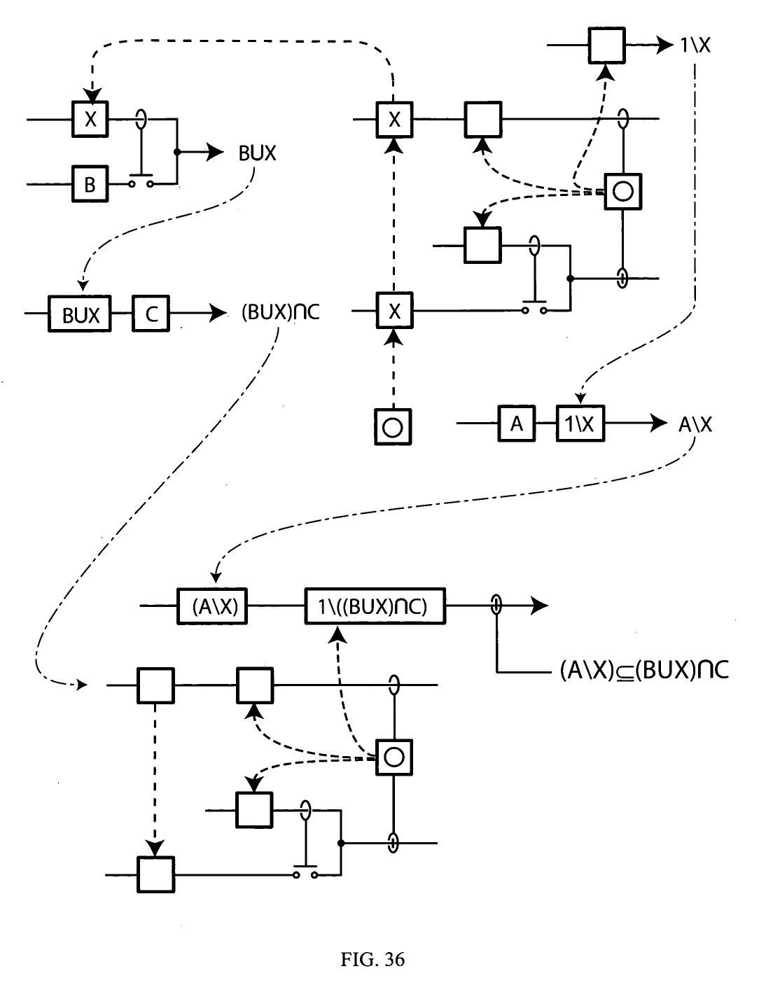

FIG. 36 shows a hierarchical circuit analogue of the set expression (A\X)⊂((B∪X)∩C), in current-mode. This circuit produces output <T,F> (due to the ⊂ relation).

Here is a description of how this circuit works: The two O modules generates an instance of a set X and the complement 1\X of that set. The set X is combined with B to generate the union B∪X, and then the set (B∪X)∩C, using the sub-circuit at right. The complement 1\X is combined with A to generate the set difference A\X. The two sets A\X and (B∪X)∩C are then combined to form the difference (A\X)\((B∪X)∩C). The sensor then detects if this set is null (the current is zero), which implies (A\X)⊂((B∪X)∩C).

It is obvious that we could provide feedback from any point in this computation, including the output (A\)⊂((B∪X)∩C) to modify the O modules (which varies the sets X and 1/X), thus obtaining an adaptive circuit.

### Circuits: Flattened

Another convenient procedure is to replace a compound expression with a set of canonical unary and binary expressions/This is referred to as flattening [Cantone, et al., p. 308]. We illustrate this with the following example. The set-level expression.

((E÷F)\G)⊂((A∩B)∪(C\D))

is equivalent to the following collection of expressions:

P=A∩B

Q=C\D

R=P∪Q

S=E\F

T=F\E

V=S∪T

W=R\G

X=<W\R>

U=TRUE→((E÷F)\G)⊂((A∩B)∪(C\D)).

In the expression for X, the form <W\R> means that X=TRUE if the expression W\R is TRUE, and FALSE otherwise. Thus, X is a set bit: X=<TRUE,FALSE>=<T,F>.

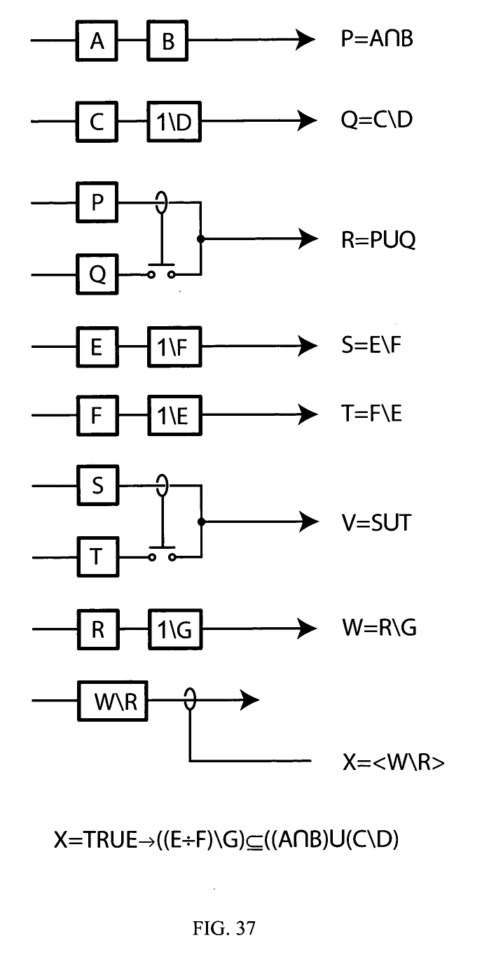

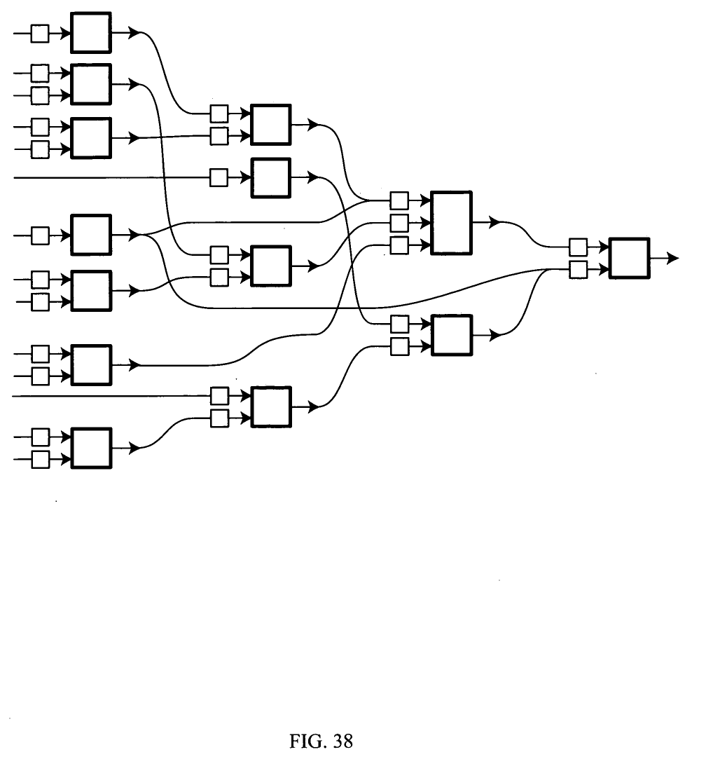

FIG. 37 shows circuit analogues of the flattened form of the set expression ((E÷F)\G)⊂((A∩B)∪(C\D)), in current-mode. Clearly flattening reduces the circuit analogue to a collection of simple canonical modules. In this case, the only operations needed are ∩,∪, and the complement 1\, plus the logical sensor for ⊂. A device-level version of the circuit is obtained straightforwardly by substituting the explicit modules for each operation.

In fabricating such circuits, there will be a trade-off between the hierarchical and device-level versions. The former will be easier to implement and more versatile using configurable analog arrays, but the latter will have better performance.

### Circuits: Modular

It is sometimes convenient to use the circuit analogues in the form of modules. Any of the modules shown FIG. 30 can be connected to any others to form chains and general networks, always assuming the signal flows from left-to-right.

FIG. 38 shows an arbitrary manifold of modules, converging on a single module.

It should be remembered that some of the modules (e.g., intersection) require connecting the output of one device to the input of another device. The modular diagram is therefore a guide for design, not a literal for current flow and voltage values.

### Circuits: Boolean

Another convenient procedure is to reduce all expressions to Booleans, By stipulation, all expressions in Set Theory must be TRUE (otherwise the constraints are not satisfied, by definition). For coupled set constraints, we can generate a Boolean for each constraint, and then use an AND gate to test whether all constraints are TRUE.

For example, earlier we considered the problem specified by the constraints

(A∪X\B≠Ø

B⊂X∩C

in which we consider A,B as given and X to be determined (this is the computation). If we can generate the Set Theory expressions with circuit analogues, and then simply test whether both are TRUE, we have the solution to the problem.

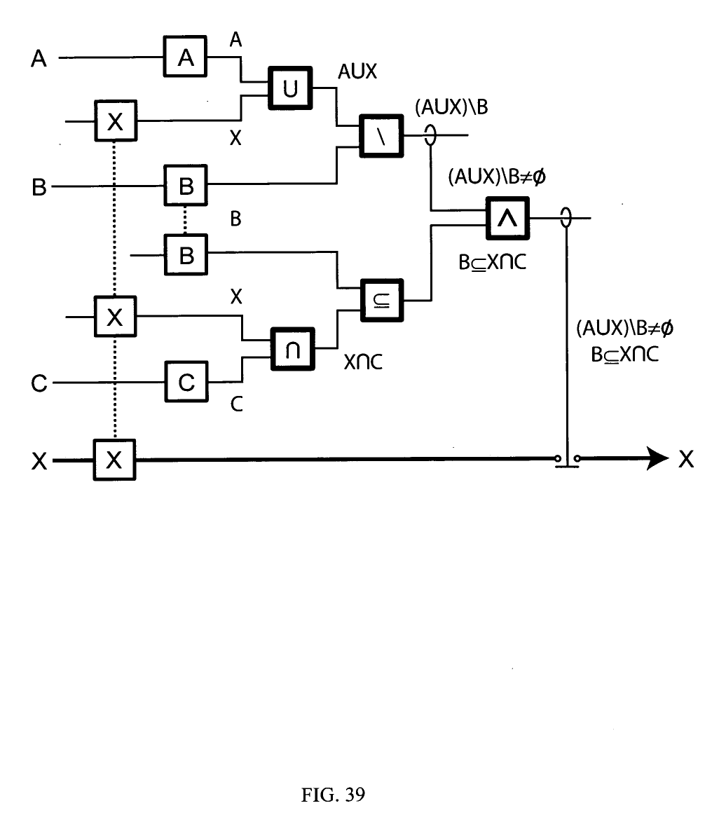

FIG. 39 shows a modular circuit that generates the solution to the set constraints (A∪X)B≠Ø, B⊂X∩C. This may be compared with the device-level circuit for the same problem, shown earlier (FIG. 33B).

### Circuits: Logic Flow

Another technique is to represent the set analogues in terms of logic flow modules.

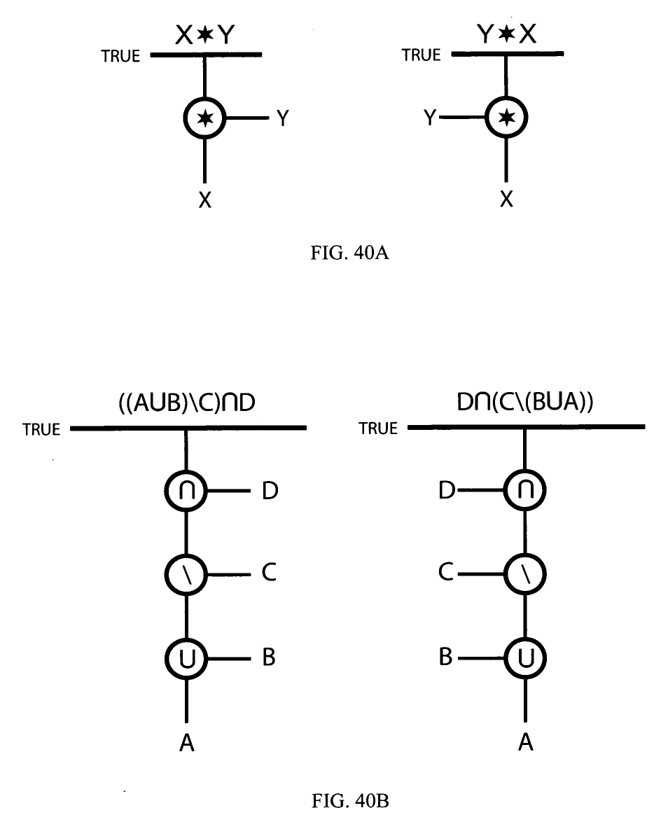

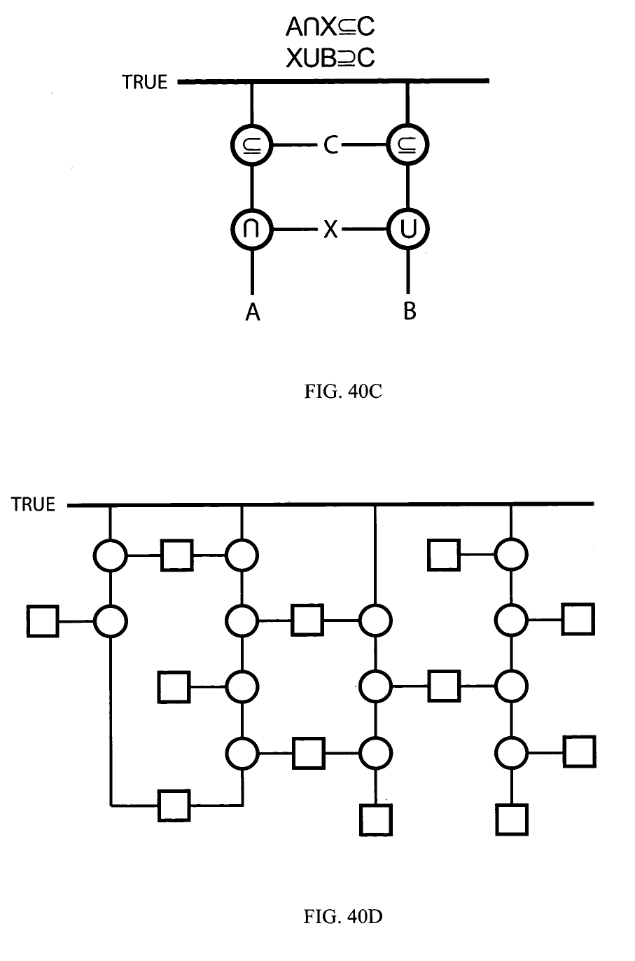

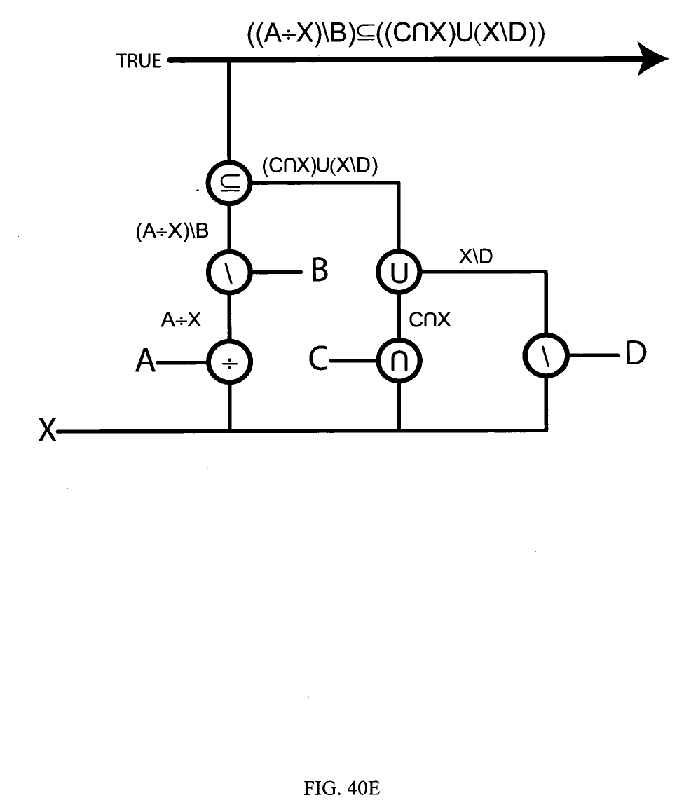

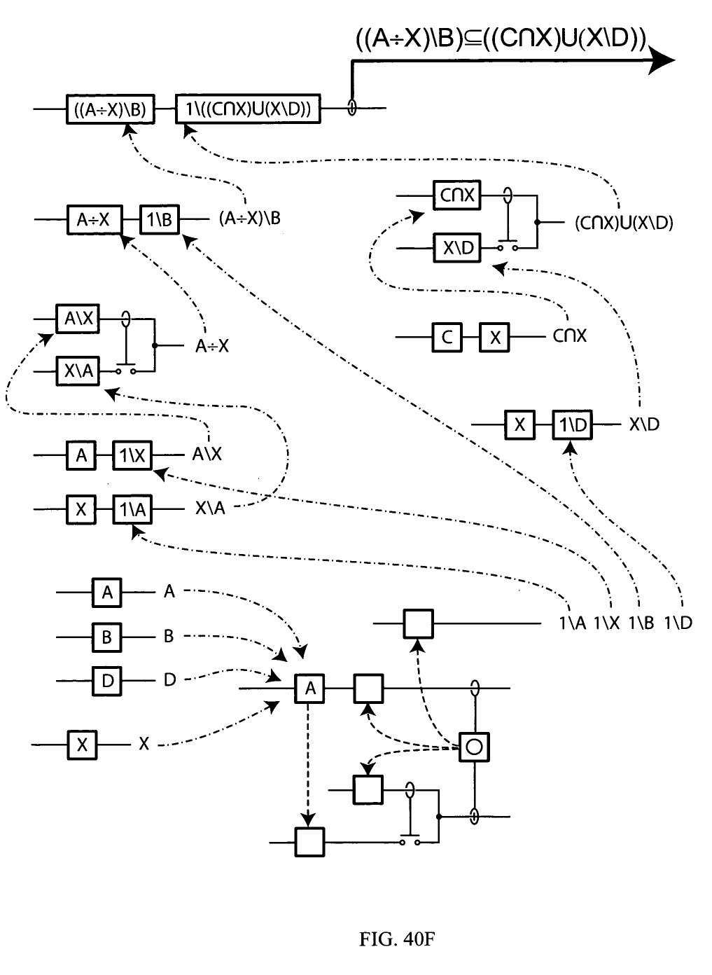

FIG. 40 shows the definition and examples of logic flow diagrams that display the topology of Set Theory expressions. These diagrams are examples of graphs.

FIG. 40A shows the definition of the diagrams. We establish a horizontal line that represents the logical constant TRUE; every expression must connect to this line. Any expression can be reduced to a canonical form involving only the form O(S,S). We represent such operations with circles, and the sets as letters, say A,B, attached to the operations. The result of the operation, O(A,B) is represented by an exiting vertical line segment. We make the convention that the flow is always from the bottom up.

FIG. 40B shows a diagram for two expression: ((A∪B)\C)∩D and D∩(C\(B∪A)). These expressions are constructed by repeated operations from the right and left, respectively.

FIG. 40C shows how coupled expressions can be diagrammed. The problem here is to determine X, given A, B, and C.

FIG. 40D shows the generalization of these diagrams to arbitrary topology and size. In this figure, the circles represent binary set operations and the squares represent sets. The procedure used in this invention maps the set expressions to a graph or network.

FIG. 40E shows the logic flow diagram for the expression

((A÷X)\B)⊂((C∩X)∪(X\D)),

which involves a single unknown set X (sets A,B,C,D are assumed known). The diagram is arranged to be suggestive that X is an input, which is processed by the graph to generate the output (=TRUE). Diagrams are interpreted to mean that the set X comprises all members (values) that generate TRUE.

FIG. 40F shows the hierarchical current-mode circuit analogue for this expression. While it may appear complicated, it is actually very easy to assemble step-by-step using the circuit modules for the fundamental operations described above. For each operation, the two circuit modules for the two set arguments are connected, using the circuit analogue for the respective operation.

### Circuits: Set Bits

Here we implement simple circuits that allow choosing between two or more sets. We call the ordered set S=<A,B> a set bit: <T,F> [symbol] <A,B> means T→A and F→B.

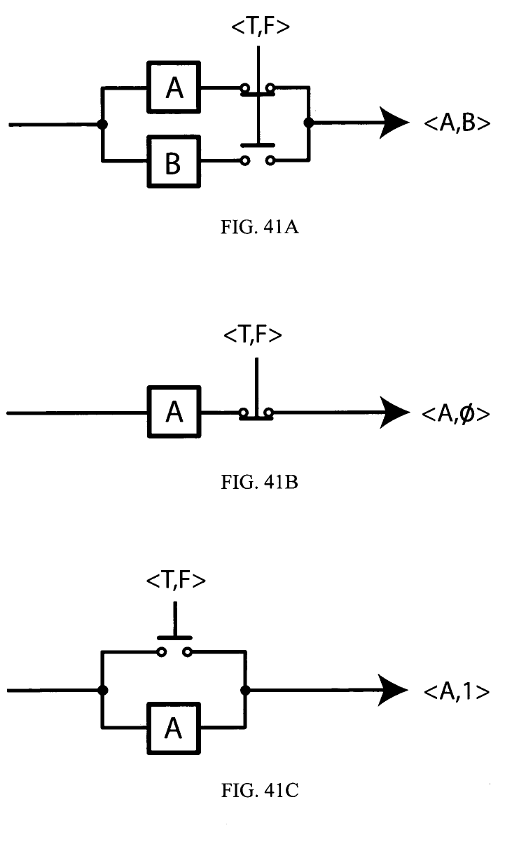

FIG. 41 shows circuits that implement set bits, in current-mode.

FIG. 41A implements the basic set bit. If the logic bit <T,F> is T, the switch is “pulled,” connecting A to the output. If the logic bit <T,F> is F, the switch is “pushed,” connecting B to the output. Thus,

T→A [symbol] A

F→B [symbol] B.

and the circuit logic bit <T,F> is the circuit analogue of the set bit <A,B>:

<T,F> [symbol] <A,B>

so this circuit is the analogue of the set bit

<A,B>.

FIGS. 41B,C show two simple special cases:

<A,Ø>

<A,1>.

Set bits can be nested, essentially because the input of a set bit is an ordered set (the Boolean set <T,F>), and the output is also an ordered set (<A,B>). If the output is also logical bits, we can use them as input to another set bit module. The nested ordered sets can be flattened in the usual manner to give a depth-1 ordered set circuit that is the analogue of a depth-1 ordered set. For example, <<A,B>,C>→<A,B,C>.

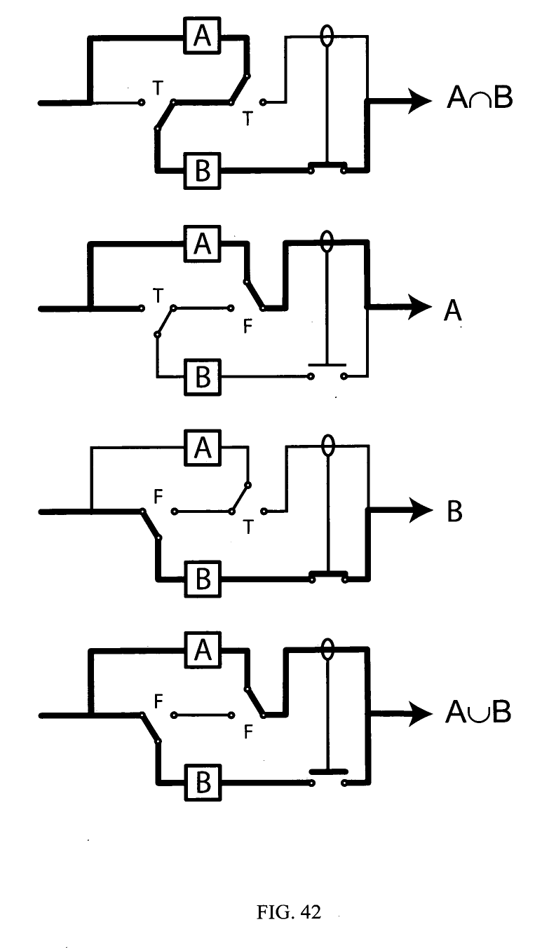

FIG. 42 shows an example of circuit that implements the following 4-member ordered set analogue, in current-mode:

<<T,T>,<T,F>,<F,T>,<F,F>> [symbol] <A∩B,A,B,A∪B>

The following notation is convenient: If E is a Boolean expression (e.g., E=A⊂B), and ∈ is a circuit analogue of E, then we write

<T,F>∈ [symbol] <E>→<A,B>

to mean that the circuit ∈ is the analogue of the set bit <A,B>.

### Circuits: Mixed-Mode

We have so far assumed that the circuit analogues would be either current-mode or voltage-mode. However, we could ask whether it is feasible, and possibly desirable, to assemble mixed-mode circuits? The answer is, of course, yes, for both questions. In fact, we showed an example of a mixed-mode circuit in FIG. 18, namely the circuit analogue of the set membership condition.

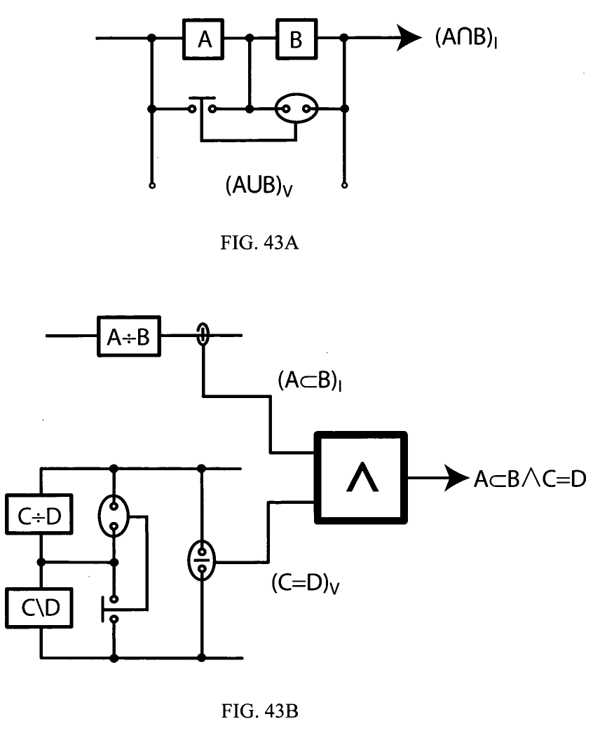

FIG. 43 shows two simple examples of mixed-mode circuit analogues.

FIG. 43A shows perhaps the simplest circuit that can generate both the intersection and the union for 2 devices. The current flowing through the devices is the intersection (in current-mode), and the voltages across them generates the union (in voltage-mode). Obviously, these electrical signals can be used in subsequent operations by appropriately connecting additional devices and circuits.

Another way to generate mixed-mode is based on assuming that the signal from the Boolean operations A=B, A⊂B, and A⊂B are not specified as to mode. That is, the Boolean signals can be either current or voltage-mode, and for the logical diagrams presented in this invention, we do not differentiate them. Thus, we can combine any Boolean signals in an AND gate to obtain a resultant Boolean signal. Such circuits are mixed-mode.

FIG. 43B shows an example of combining A⊂B in current-mode with C=D in voltage-mode, and forming the logical product of them, to be used subsequently.

Computation with Set Analogue Circuits

In the description above, we have defined and given examples of circuits that are electronic analogues of sets and the fundamental set operations such as intersection, union, etc. These can be used to assemble circuits that are analogues of (almost) any expression in Set Theory. This is the basis on which the claims in this invention are made.

In this section we describe and give examples of computation using these circuits. This material goes beyond the claims of this invention, but is provided to indicate both the process and the potential of using this invention in practical applications.

The purpose of this invention is to provide a means for realizing set computation, which can be defined as determining sets that satisfy a collection of set constraints. For example, given sets A, B, and C, what set X will satisfy (A∪X)(B⊂C∩X)≠Ø? This invention provides a means for building an electronic circuit whose behavior corresponds to such set expressions, and therefore can be used to determine the unknown sets, i.e., perform computation.

### The Process of Computing

Earlier we have shown that in general an X-mode circuit is associated with the set

^{X}C [symbol] {X|∃Y|X∪Y=Z|Z∈C}

and we interpreted this expression to mean that we must examine all input sets Y in order to generate all possible output sets X. In the absence of set-level evaluation schemes such as that described in the previous sections, there is no alternative to this examination, and it implies that we must examine all members of the input set. Thus, if Y={y₁,y₂, . . . yₙ}, we must scan through all possible values of the members of Y. However, this process does provide a reliable procedure for determining all members of the sets X, hence for computation.

### Possible-Value Computing

We emphasize the conceptual difference between conventional (value) computing, by which is usually meant transformations of a value within a fixed manifold of allowed values, and possible-value computing as used in this invention, by which we mean transformation of the manifold of allowed values. An example of the former is finding a path through a maze, while an example of the latter is finding a set of possible mazes. Another example of the former is shooting at a fixed target; for the latter the target is allowed to move and change shape. Other examples of the latter include self-gravitating bodies, structural oscillations, flocks, panics, epidemics, etc.

The movement of a state point around a fixed manifold is generally called dynamics. It is concerned with the path taken across a fixed landscape. Here, the landscape itself is allowed to change. Thus, this invention generalizes the concept of dynamics to dynamics of possible states. Another way to think of this is that the states of the system are comprised of multiple points, defined as sets and manipulated as single entities.

### EXAMPLE

### A Simple Fixed Constraint

Consider the following problem: What set X satisfies the following constraint relation:

A∪X⊂B?

Using the diagrams for the circuit analogues shown in the previous section, it is rather easy to convert this expression into its circuit analogues. The procedure was described earlier: assemble the modules together in the same topology as the Set Theory expression.

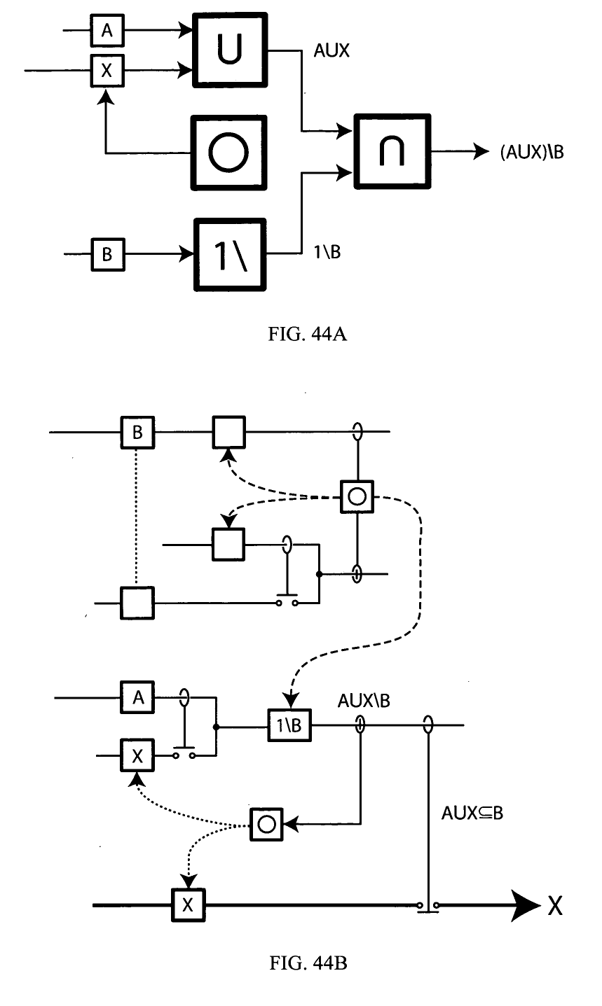

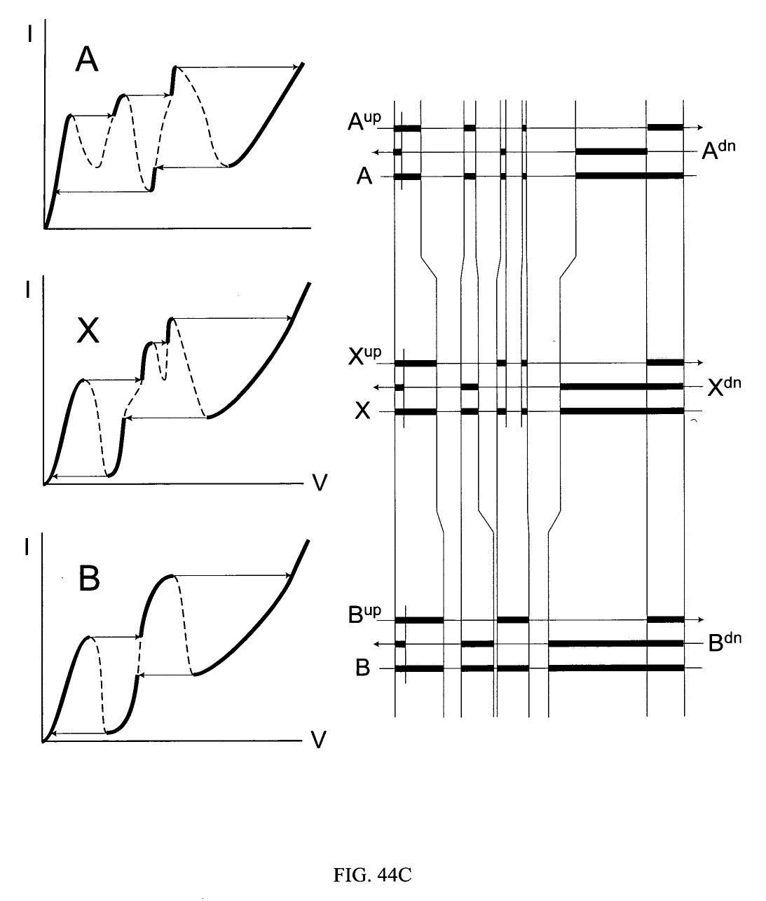

FIG. 44 shows a circuit analogue of the Boolean Set Theory expression A∪X⊂B. The sets A,B are considered constants, and are generated by devices assumed given,

FIG. 44A shows the dataflow modular circuit, assembled from the modules shown in FIG. 30.

FIG. 44B shows the device-level circuit, obtained by substituting the circuit equivalents of the modules.

FIG. 44C shows a solution to the problem defined above. Here, sets A,B are assumed given, and set X is generated by parameter variation using the O module until a set satisfying A∪X⊂B is obtained.

### Circuit Analogues of Solutions

The entire presentation so far has been phrased in terms of assembling a circuit analogue of a collection of expressions in Set Theory, and using that circuit to solve the problem by finding sets that satisfy the expressions (including expressions regarded as constraints). However, in general, both the problem specification and its solution are expressions in Set theory, so both the problem and its solution will have circuit analogues.

For instance, consider the constraint examined earlier, as a problem specification:

A∪X⊂B (Problem)

where the sets A,B are known and we desire to find X. In fact, the general solution is known from elementary analysis:

X⊂B|A⊂B (Solution)

which means that any set X⊂ is a solution, so long as AcB. Clearly, the expression X⊂|A⊂B is a perfectly valid expression in Set Theory, so there will be a circuit analogue for this expression.

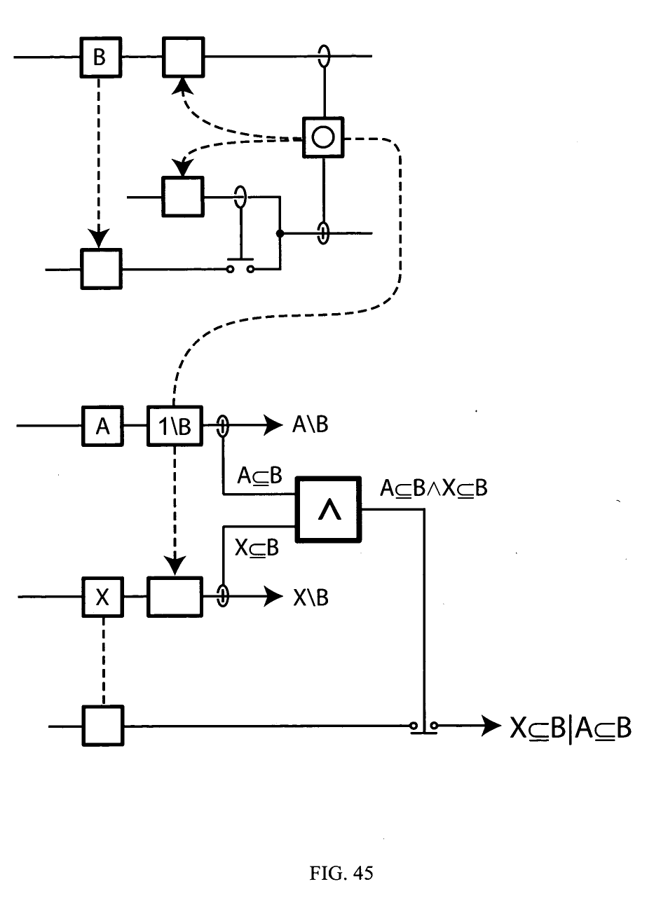

FIG. 45 shows a circuit analogue for the expression X⊂B|A⊂B in current-mode. This circuit is somewhat more complicated than the circuit for specifying the problem, shown in FIG. 43B. It seems intuitively reasonable that the circuits for solutions will be more complicated than the circuits for problem definitions, particularly if the solutions involve additional constraints, as does this example. It is also intuitively reasonable (but not yet proven) that the circuit for the problem and for its solution will be different:

C(Problem)≠C(Solution).

However, both the problem and solution expressions are valid, hence the circuits will be bi-implicants:

C(Problem) [symbol] C(Solution).

In principle, at any intermediate step in a series of transformations, the expressions will have a valid circuit analogue, and any circuit Will have a valid set analogue: Thus, in principle we could shift back and forth between expressions in Set Theory and circuits in arriving at a desired result.

### Intractable Problems

There is a vast literature on computational complexity, and on classes of problems that are so hard they are effectively intractable. Among 30+ complexity classes, NP-complete is considered the most difficult. Such problems are often (and always can be) phrased in the language of Set Theory, and as such, we expect the present hardware approach to be of use in attacking such problems. We show here by example how to design circuits that are the analogues of such problems.

### EXAMPLE

### Set Packing

A typical NP-complete problem is the following, which appears in the classic list by [Garey and Johnson]:
[SP3] SET PACKING
INSTANCE: Collection C of finite sets, positive integer K≦|C|.
QUESTION: Does C contain at least K mutually disjoint sets?

While we intend to formulate the circuit analogue of this as a purely mathematical problem, the solution has practical applications to routing and delivery problems, location and scheduling problems, switching theory, testing of VLSI circuits, and line balancing. Thus, we consider this example to be more than an exercise; it is exemplary of large numbers of very hard problems of technological importance.

To develop the circuit analogue for this problem, we first translate it from words to conventional Set Theory notation. First, the INSTANCE specifies a collection C of finite sets. Suppose there are N of these sets Sₙ, where n∈ [symbol] ={1,2,3, . . . ,N}. Thus,

C={Sₙ|Sₙ∈C,n∈ [symbol] }

The INSTANCE also specifies that we pick an integer K≦|C|, that is, K≦N.

Next, the QUESTION asks whether C contains at least K sets (members of C), so let X be a set:

X=Sᵢ|Sᵢ∈S,i∈

[symbol]

where [symbol] ={1,2,3, . . . ,K}.

The QUESTION also calls for the Sₖ to be mutually disjoint, i.e., Sᵢ∩S_{j≠i}=Ø for all Sᵢ∈X.

The set X is therefore

X={Sᵢ|Sᵢ∈C,i∈ [symbol] Sᵢ∩S_{j≠i}=Ø,j∈ [symbol] }.

Now we associate current-mode circuit devices Sᵢ with all the members Sᵢ of the set C. To make an analogue circuit, we incorporate each device in a set bit, i.e., Bᵢ [symbol] Bᵢ=<Sᵢ,1>, and connect all Bᵢ in series.

We then seek a circuit that is the analogue of the intersection B₁∩B₂∩B₃ . . . B_{N-1}∩B_{N}.

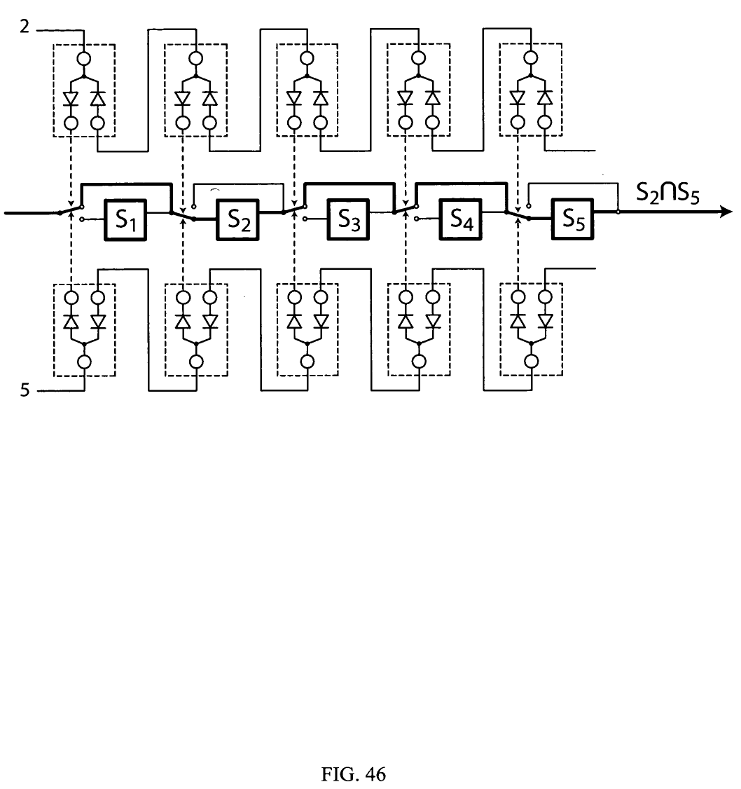

FIG. 46 shows a circuit analogue of the intractable problem SP3.

Here is an explanation of how this circuits works: Each set bit Bᵢ is either Sᵢ or 1, determined by a Boolean logic variable βᵢ. According to the QUESTION, at least K of these variables must be βᵢ=TRUE, and all others βᵢ=FALSE. Note that at least K sets is satisfied if there are exactly K sets. Thus, we can set up an external switching network to select exactly K of the βᵢ to be TRUE. What we do not know, and therefore must test for, is whether

B₁∩B₂∩B₃ . . . B_{N-1}∩B_{N}=Ø

where exactly K of the Bᵢ are Sᵢ and the other N-K are 1. If this expression is null, then This directly suggests that we set up circuits to select K of the β, arid use the circuit in FIG. 46 to test for nullity. If any combination of K settings of βᵢ=TRUE produces the null set, the QUESTION is answered affirmatively. To satisfy the at least clause of the QUESTION (“at least K . . . ”), we merely start with K and increase it until we find constraint satisfaction.

A problem closely related to this is framed by the QUESTION: What is the maximum K such that X is disjoint? It is clear that the circuit analogue can relatively easily solve this problem, merely by increasing K until the nullity condition is violated.

Both QUESTIONS are considered NP-complete intractable problems. The analogue circuits described here can solve both problems, at least in principle, although actual hardware solution times will of course depend on the particular circuit technology.

### EXAMPLE

### Set Splitting

Consider another NP-complete problem from the list by [Garey and Johnson]:
[SP4] SET SPLITTING
INSTANCE: Collection C of finite subsets of a finite set S.
QUESTION: Is there a partition of S into two subsets S₁ and S₂ such that no subset in C is entirely contained in S₁ or S₂?

The INSTANCE specifies a collection C of finite subsets of a finite set S:

C={Cᵢ|Cᵢ⊂S,i∈ [symbol] }.

The QUESTION asks whether there is a partition of S:

S₁∪S₂=S

S₁∩S₂=Ø.

Given S₁, we can generate S₂ as the set difference:

S₂=S\S₁.

The QUESTION also demands that no subset in C is entirely contained in S₁ or S₂:

Cᵢ [symbol] S₁

Cᵢ [symbol] S₂.

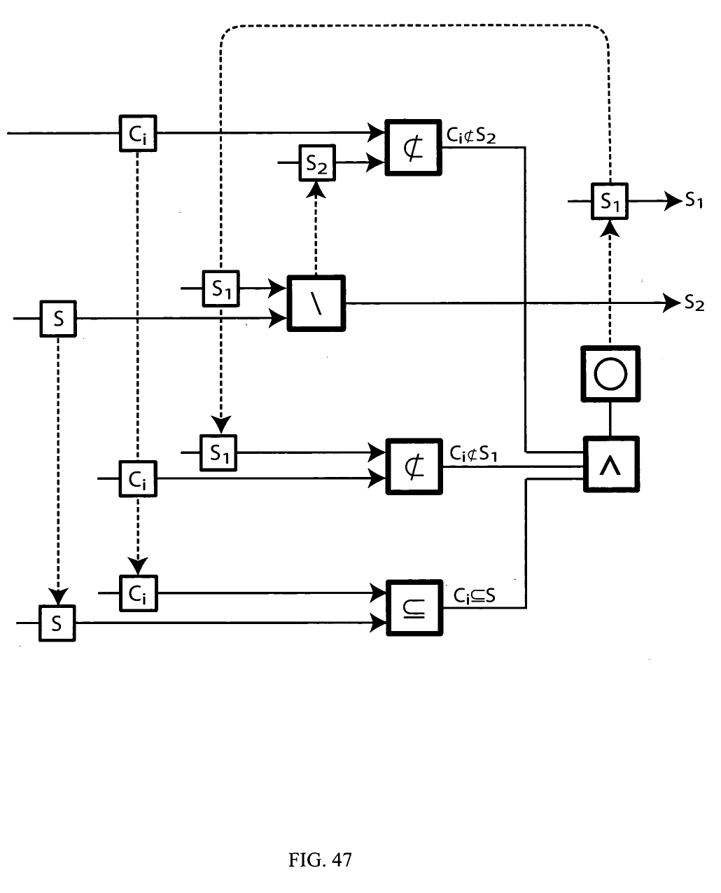

FIG. 47 shows a circuit dataflow analogue of the intractable problem SP4. The device-level circuit analogue can be obtained easily by substituting fro the individual modules.

Here is an explanation of how this circuit works:

First, the set S is specified and a subset Cᵢ is selected. The inputs Cᵢ and S are cloned to provide inputs to modules testing whether Cᵢ⊂S (the INSTANCE specification). Next, a candidate set S₁ is generated by the scanning module. Given S₁ , the set difference module generates S₂=S\S₁. The two proper subset modules (obtained using subset modules with logical inversion) test whether Cᵢ [symbol] S₁ and Cᵢ [symbol] S₂. The three logical tests Cᵢ⊂S, Cᵢ [symbol] Sᵢ, and Cᵢ [symbol] S₂ together provide a logical “enable” for the scanning module, which generates a new candidate set S₁. Thus, once initialized with Cᵢ and S, the circuit will generate S₁,S₂ until the constraints are satisfied (if that is possible), and these two sets constitute the solution to the problem. Thus, given the input {Cᵢ⊂S}, the output (if it exists) is S₁,S₂.

It should be noticed that the circuits in FIGS. 46,47 are relatively simple. The main reason for this simplicity is that the Set Theory specification of the problem is so simple, which is the case for most standard intractable problems.

### Infinite Sets

We have defined 1D data in this invention as being those values that are in one-to-one correspondence with an arbitrary subset of the real numbers. This is easily visualized as being multiple intervals of a single variable. Thus, even though the number of intervals might be finite, the number of values of any non-degenerate interval is infinite.

The literature on intractable problems normally assumes the sets are finite. However, a key advantage of the analogue circuits described in this invention is that they can represent and manipulate arbitrary data sets, including intervals, nonlinearities, and discontinuities. They can therefore handle both finite and infinite sets, at least in principle. This raises the intriguing possibility that these circuits could attack a new class of intractable problems, namely those for which the values range over a finite number of intervals. This would require extending the traditional definition of intractable problems, but could very well lead to large numbers of problems that are not simple extensions of finite problems.

### Dynamic Constraints

In the discussion so far, we have assumed that the expressions are fixed; computation means finding the sets that make the expressions TRUE. However, this invention makes it almost trivially easy to alter the connections in the circuits, hence the analogue set expressions themselves. If such alteration is done depends on the result of a previous stage in the computation, we have a dynamical system.

For example, consider the expression

(AO₁X)O₂(BO₃Y)O₄C

where sets A,B,C are assumed known, sets X,Y are assumed unknown, and the operations O₁,O₂,O₃,O₄ are given by

O₁∈{\,÷}

O₂∈{=,⊂,⊂,\,∪,∩,}

O₃∈{∩,∪}

O₄∈{∩,∪,\}.

Some examples of these expressions are

A\X=(B∪Y)∩C

A÷X⊂(B∪Y)\C

(A÷X)∩(B∩Y)∪C

A single computation might start with the first expression, and find sets X,Y that make it TRUE. Given this, we might use the second expression to compute new sets A,B,C, which (together with X and Y) can then be inserted into the third expression to find new X,Y that make this expression TRUE. The dynamical system is realized by continuing this process indefinitely.

Problems of this kind are hybrid—they involve both the manipulation of sets involving intervals and enumerated steps involving tests. Thus, they have a hybrid analog/digital character that will inevitably be characteristic of this kind of computation. For this reason, the circuits implementing such analogues will be more properly described as mixed signal.

### Algebras

The term algebra refers to a set and a collection of operations on the set, which is exactly the subject of this invention. This invention therefore intrinsically implements algebra, including all specific forms of algebra.

By imposing constraints on the sets, it is possible to find certain relations between members of the sets mat provide more direct or more convenient means for manipulating the sets. We argue on very general grounds mat any expression specific to a specialized algebra can be represented by a circuit analogue. The argument is simple: the algebra derives from Set Theory, which is the subject of this invention.

### Preconditioning

Given a problem expressed as set constraints, preconditioning, that is, algebraically re-arranging the constraints, will often be useful and may significantly simplify the circuit analogues. However, a danger exists in incautiously applying specialized algebraic relations to general set relations. The danger stems from the fact that such relations habitually produce incorrect results due to a phenomenon called dependence. It arises when a variable appears more than once in an expression.

The dependence error occurs in counting members of the sets. For example, suppose we have an expression A², which we are accustomed to thinking of as meaning A-times-A. However, in Set Theory these mean different things. If x means a value,

A²≡{x²|x∈A}

A×A≡{xy|x∈A [symbol] y∈A}.

Thus, the Set Theory expression ((A∩X)∪(C\X))⊂(X÷F)\G (which has three instances of X) should actually be interpreted to mean all values of the individual sets X,Y,Z that are members of X:

{((A∩X)∪(C\Y))⊂(Z÷F)\G}|X={x|x∈X} [symbol] Y={x|x∈X} [symbol] Z={x|z∈X}}.

There is a large literature on approximation and errors associated with dependence. It remains to be seen how these issues should be handled in the set analogue circuits.

### EXAMPLE

### Interval Set Algebra

Interval sets are defined by

A=[a,b]≡{x|a≦x≦b}

Interval sets have their own peculiar algebra. For example, two interval sets A,B, and the operations ·∈{+,−,×,÷}, we have [Hansen and Walster, 2004, p. 17] the definition:

A·B={a·b|a∈A [symbol] b∈B}

which leads to algebraic relations such as:

A×(B+C)⊂A×B+C×C (distributivity).

Because intervals are sets, we can use the invention to cast such sets into circuit analogues, and use those circuits to solve problems phrased in terms of interval algebra.

### Example: Fuzzy Set Algebra

Fuzzy sets are defined by

[symbol]

≡{<x,μ>|x∈A [symbol] μ∈[0,1]},

where μ is interpreted to mean fractional membership in the set.

Fuzzy sets also have their own peculiar algebra. For example, certain fuzzy sets can be considered numbers, in the sense that they allow defining relations that are the same as (or similar to) ordinary real arithmetic [Hanss, 2005]. For instance, the algebraic product, defined by

μ [symbol] B)≡μ( [symbol] )μ( [symbol] )

leads to the set relation

[symbol]

B⊂ [symbol] ∩

[symbol]

Certain identities for fuzzy sets are the analogues of those for crisp sets (μ∈{0,1}). For instance, the following relation is valid for fuzzy sets (and for crisp sets):

[symbol]

∩( [symbol] ∪ [symbol] )=( [symbol] ∩ [symbol] )∪( [symbol] ∩ [symbol] )

Because fuzzy sets are sets, we can use the invention to cast such sets into circuit analogues, and use those circuits to solve problems phrased in terms of fuzzy set algebra. This is a. particularly attractive prospect, because many human-important problems, which tend to be less precise in their specification and less demanding in their solution than problems phrased in terms of crisp sets.

### Set-Level Computation

In the preceding development, we have demonstrated that electronic devices can be physical analogues of sets (in the sense that their states are in one-to-one correspondence with the members of the set), and that they can be connected together to form circuits that are the analogues of compound sets. This process can be iterated hierarchically to assemble more and more complicated circuits mat are the analogues of moire and more complicated sets. We refer to this process as aggregation.

However, this process implies unlimited scaling up to unreasonably large circuits. At some point, it will be necessary to replace some parts of the circuit with simpler circuits that have effectively the same behavior. This process is called evaluation, and it is an essential part of computation in any form.

Thus, computation can be conceptualized as a series of aggregation and evaluation steps. For example, given the set {1,2,3,4,+,−,/}, we could write ah aggregate E=2−(3+1)/4 and then evaluate it to obtain E=1. This aggregation/evaluation cycle may be carried out many times during the course of a computation.

### Set-Level Evaluation

We reiterate that our central goal, and requirement for this invention, is that the sets be manipulated without examining their members, a process we refer to as set-level. Aggregation is intrinsically set-level (just connect set devices together), but evaluation is not. Suppose we wanted to replace a complex circuit analogue of a complex set with a simpler circuit or single device that fairly (but not perfectly) represents the complex set. How should we approximate a set, and how should we do it?

Evaluation not only keeps the circuits within defined engineering bounds; it also imposes a defined precision on the data. For instance, suppose we use a computer to multiply two 10-digit numbers together: πe=3.141592654×2.718281828=8.539734223, which is also 10-digit number. What happened to the other 10 digits? The answer is that they were automatically dropped by the computer hardware in order to keep the necessary circuit to manageable size. This process imposes a machine-defined precision oh all data stored and processed by the machine. In digital machines, this is done by stopping the algorithm that generates new digits by having a fixed number of bit register, e.g., 64-bits. In an analog computer the same process can be implemented by restricting the complexity of the sets, which can be done by low-pass filtering, averaging, selective elimination, and other means.

Here is one way to implement set-level evaluation: Consider a collection of individual modules A,B,C . . . that contribute current to a common output, in amounts depending on their individual characteristics. Suppose further that each module has a built-in sensor/actuator that can sense the current through it and take some action based on the value of that current. Suppose further that the module can be disconnected from the common output if a certain criterion is satisfied, and that all modules have the same criterion. Now suppose we provide a common signal to all modules that instructs them to drop out if their current is below a threshold. The signal constitutes a set-level instruction, so the evaluation is set-level.

### Distributed Computing and Emergent Behavior

The scheme for evaluation just described introduces the concept of distributed computing and collective behavior of minimally cognitive individuals. To the extent that the modules are endowed with greater complexity, they will assume a greater influence on the computation. Thus, suppose those modules are able to take any of several actions, depending on the signal passed to them. Suppose finally that we use the output current to modify the devices and/or the modules. The behavior of a collection of such sensor/actuator/device modules will exhibit collective effects, since the devices are coupled through the feedback, and their behavior is modified by the collective behavior (the output current).

Emergent collective behavior of populations of minimally cognitive individuals has been investigated by the present author [Schmieder, 1995, 4 refs]. Examples of such systems include artificial life, insect colonies, robots populations, etc. Computer simulation of such systems is notoriously challenging, due to the large number of individuals calculations heeded. This invention provides a favorable alternative: the entire computer evolves simultaneously, the system is self-modifying, and meaningful global properties (e.g., the output current) emerge without additional computational overhead.

Implementation of this Invention

In this section we discuss implementation of this invention, including its preferred embodiment in nanoelectronic analog array electronics.

### The Language

This invention is implemented by a set of language constructs, viz.,

| | |
|---|---|
| Set definition | A ≡ {x\|x∈A} |
| Modal set | ^{X}A ≡ {X\|∃Y\|Z = X ∪ Y\|Z∈A} |
| Clone | B ≡ B = A |
| Null Set | Ø ≡ {x\|x ≠ x} |
| Universal Set | 1 ≡ {x\|x = x} |
| Complement | 1\A ≡ {x\|x∈1 [symbol] x∈A} |
| Intersection | A ∩ B ≡ {x\|x∈A [symbol] x∈B} |
| Union | A ∪ B ≡ {x\|x∈A [symbol] x∈B} |
| Difference | A\B ≡ {x\|x∈A [symbol] x∈B} |
| Symmetric Difference | A ÷ B ≡ (A\B) ∪ (B\A) |
| Equality | A = B ≡ {x\|x∈A→x∈B [symbol] x∈B→x∈A} |
| Subset | A ⊂ B ≡ {x\|x∈A→x∈B} |
| Proper Subset | A ⊂ B ≡ {x\|x∈A→x∈B [symbol] A ≠ B} |
| Boolean implication | A→β ≡ [symbol] A [symbol] β = T [symbol] β = F |
| Set implication | β→B ≡ [symbol] β = T [symbol] B [symbol] Ø |
| Transitive implication | A→β→B ≡ [symbol] A [symbol] (β = T [symbol] B) [symbol] (β = F [symbol] Ø) |
| Set bit | <S> ≡ <T, F>→<A, B> |
| Logic (first-order) | [symbol] →, [symbol] |

This invention applies to both crisp sets (x∈A)∈{0,1} and fuzzy sets (x∈A)∈[0,1].

### Computational Tasks

A key task underlying this invention was:
Given 2 set-analogue devices A [symbol] A and B [symbol] B, and a set C(A,B) constructed by combining sets A,B, find a way (if possible) to connect the devices A,B such that the compound device C(A,B) is the analogue of the set C, i.e., C(A,B) [symbol] C(A,B).

This is only one of many similar tasks. Tasks like this are in forms such as:
Given_P_, is _Q_?
Given_P_, find (if possible)_Q_.
Given_P_, find (if possible)_Q_such that_R_.

Some of these tasks are strictly Set Theoretical, such as:
Given an individual x and a set X, is x∈X?
Given a set X, find the complement set 1/X.
Given sets X,Y, find a set S(X,Y) such that S⊂(A∪B)\(A∩B).

In this invention we are especially interested in tasks that involve both devices and sets, since they commonly will be encountered in implementing this invention. Some examples of such tasks are:
Given a circuit C and a set X, are they analogues, i.e., C [symbol] X?
Given a circuit C, find its set analogue C [symbol] C.
Given a set C, find its circuit analogue C [symbol] C.
Given 2 set-analogue devices A [symbol] A and B [symbol] B, and a circuit C(A,B) constructed by combining devices A,B, find the analogue set C(A,B) [symbol] C(A,B).
Given a set A, find a set circuit B [symbol] B such that A∩B=Ø.
Given a device A and a circuit C(A,B), find a device set B [symbol] B such that the set C [symbol] C(A,B) satisfies B⊂C.

These and many similar tasks are addressable using this invention. The design procedure and the circuit analogues will depend on which task, of the kind listed here, is being addressed.

### Design Procedure

Generally, this invention will be implemented by a process involving some or all of the following steps (of which the first two are preparatory):

(Mathematics) Express the computational problem (INSTANCE) and define the desired result (QUESTION) in any mathematical language;

(Set Theory) Rewrite the problem in the language of Set Theory;

1. (Analogues) Define electronic devices and circuit modules that are analogues of the sets and operations in the problem;

2a. (Aggregation) Assemble the complete circuit as the analogue of the problem by assembling the modules as the topological analogue of the set expressions.

2b. (Evaluation) Limit the size of the circuit by replacing large or complex modules with equivalent smaller or simpler ones.

3. (Solution) Initialize the circuit and exercise it to determine the sets constituting the solution to the problem.

### Design Issues

The design procedure will depend somewhat on issues such as the following:

(1) Data and control. This invention blurs the distinction between data and control, hence will require a more integrated architecture. This provides both more design challenges and opportunities for more powerful processors.

(2) Adaptable architecture. Data-control fusion enables the “wiring” of the circuit to be altered at computation time, providing the opportunity for the solution algorithm to change, which will enable functions such as adaptability, learning, stability, and self-monitoring. There will be challenges to algorithm design for this kind of processor.

(3) Multiplicity. This invention exploits the advantages of casting parts of algorithms into hardware. In particular, by replacing iterations by multiples of identical modules. This will require fabricating this invention with VLSI, at least for high performance.

### Purely Graphical Transformations

In most of this specification, we described the procedure for assembling a circuit that defines the problem expressed in the language of Set Theory, and using it to find the solution to the problem. However, we also pointed out that some problems have closed-form solutions expressible in the language of Set Theory, and these also must have circuit analogues. Thus, for certain problems we can find two circuits, one expressing the problem, the other its solution. This begs the question: Can we use purely graphical transformations to convert a problem-circuit into a solution-circuit?

We can argue on very general grounds that this is possible: the solution is the result of a series of transformations, each expressible in Set Theory, hence every step, including the last, must have its circuit analogue: The challenge is finding a convenient graphical algebra that will allow us to mechanically carry out this transformation. Clearly, such an algebra must include not only the aggregation operations we have described in this specification, but also evaluation operations. We will also find transformations that enable Us to move, combine, and interchange devices, modules, and circuit fragments. These can be used to manipulate circuit diagrams into alternative forms that are analogues of different set expressions. In particular, this procedure could be used to derive, or prove, certain identities in Set Theory, purely by manipulating the circuit diagram.

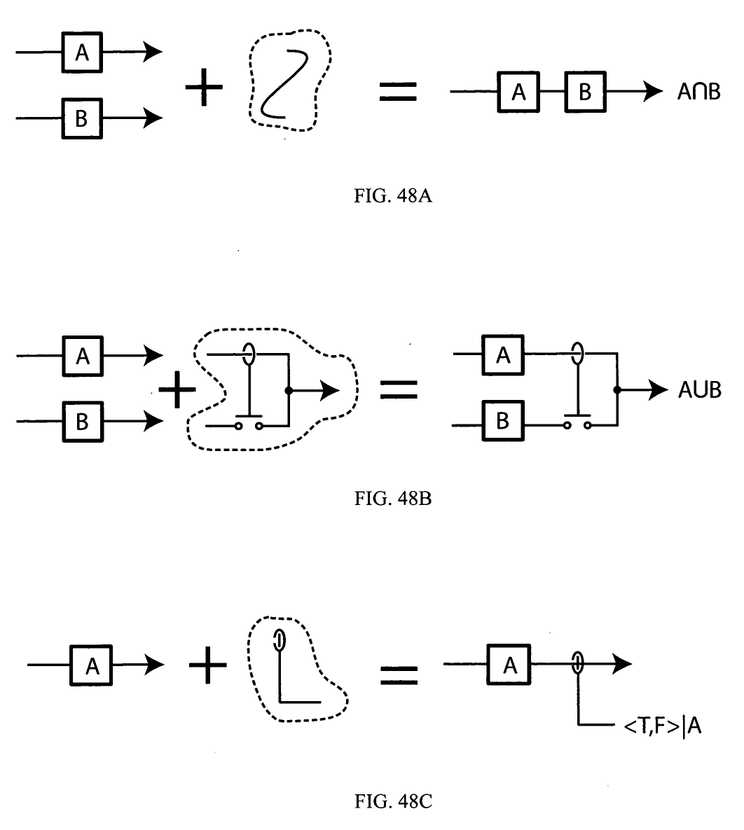

FIG. 48 shows examples of circuit transformations that add circuit fragments. In each of these 3 cases, we start with 1 or 2 devices, and add some components, thereby creating a circuit that represents an operation with the given set(s). These transformations enable us to build larger and larger circuits, which is the process of aggregation.

FIG. 48A shows the addition of the identity link between two devices produces the analogues of the intersection.

FIG. 48B shows how the addition of the logical implication circuit across two devices produces the analogue of the union.

FIG. 48C shows how the addition of a sensor to a device produces the analogue of a Boolean bit subject to the condition defined by the device.

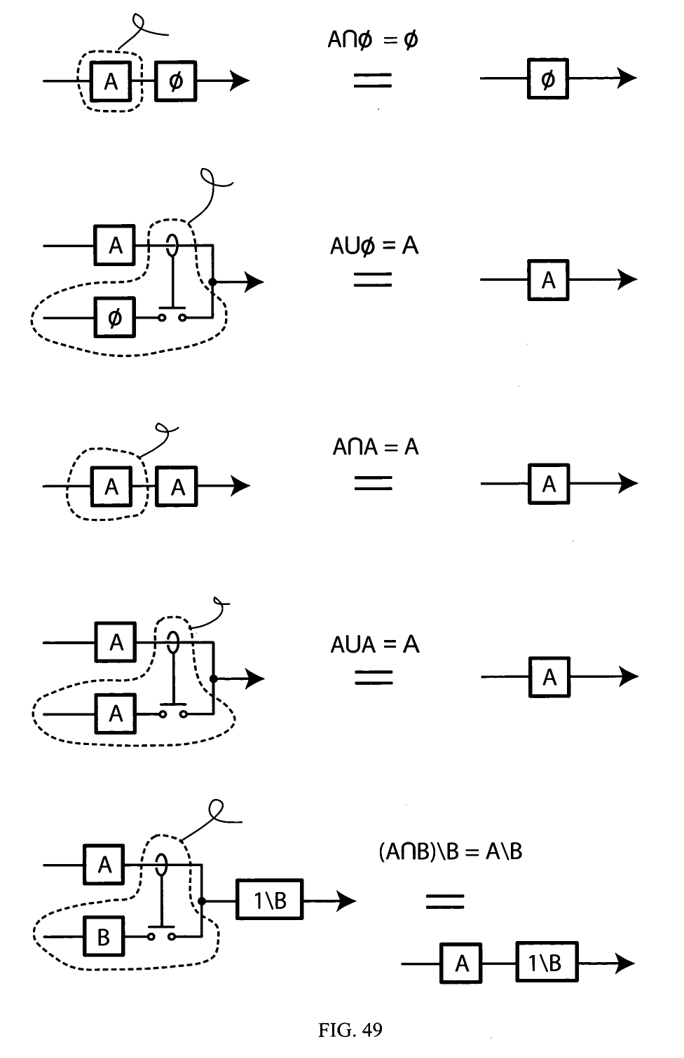

FIG. 49 shows examples of transformations that remove fragments. In each of these examples, part of the circuit can be simply eliminated, leaving a simpler circuit that is the analogue of the same set. These transformations enable us to reduce the size and complexity of circuits, which is the process of evaluation.

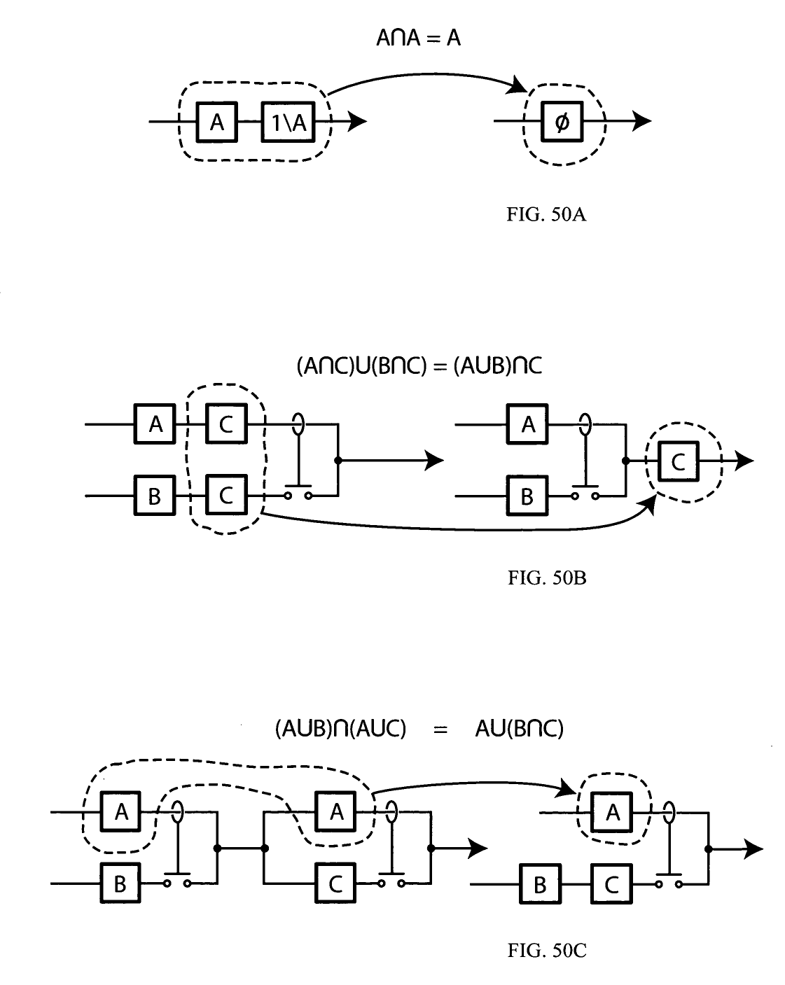

FIG. 50 shows examples of transformations that combine and move components.

FIG. 50A shows an example of combining components. The series combination of A and 1\A is A∩(1\A)=Ø, which is a tautology in Set Theory. In the circuits, whenever we encounter such a combination we can always replace it with the empty set.

FIG. 50B shows an example of moving and combining components. This example implements another tautology: (A∩C)∪(B∩C)=(A∪B)∩C. In the diagram, the 2 devices C can be “slid” to the right, and merged into a single device C on the series output.

FIG. 50C shows an example that is not quite as obvious. If the current through A is nonzero, both switches are open, and the output is A. If A is zero, both switches are closed, and the current is the intersection of B and C. Thus, the output is the union of A and B∩C.

The value of these graphical transformations is that they provide an alternative, and perhaps easier, means for designing circuits for applications. We envision building tip an inventory of such transformations, in the same way we built up ah inventory of modules for sets and set operations. These inventories will be useful for transforming circuits, entirely graphically. We anticipate that in certain cases we will be able to transform a circuit specifying a problem to another circuit that will be more convenient for computing the solution. In other cases, such transformations will result in another circuit that is no simpler or more convenient than the problem, which would thereby be an alternative specification of the problem. However, we do claim that purely graphical transformations of the kind shown in here correspond exactly to analogous transformations in Set theory, and therefore have the potential for being a powerful tool for the practical implementation of this invention.

### Preferred Embodiment

It is intended that this invention be implemented with electronics. While these circuits can be fabricated using conventional microelectronics (and simulated using digital electronics), the high performance goal for these computers suggests that analog nanoelectronics is the preferred technology. We discuss these two aspects now.

### Analog Circuits

We believe that this invention is best implemented using analog circuits. This arises from several considerations:

(1) Compatibility of analog data with human-important problems, especially involving systems found in Nature;

(2) Greater speed due to processing of the problem in full parallelism using the entire machine;

(3) Compatibility Of analog circuits with nanoelectronic devices, which have complex behavior that is difficult to force into simple discrete or linear behavior.

Many of the circuit analogues comprising this invention make use of switches, which are intrinsically discrete devices. However, switches can be implemented entirely with analog circuits, for instance using level shifters and reversed diode pairs, so the circuits could still be considered to be entirely analog.

Devices are readily available that could be considered hybrid continuous/discrete, or analog/digital. For example, a sawtooth transfer function could be described as everywhere (except at one point) linear and continuous (which is an analog concept), and having a simple discontinuity at one point (which is a digital concept). Any device that exhibits NDC can be operated in continuous mode or with one or more discontinuous jumps. Such devices should be described as hybrid analog/digital. Using such devices in a processor will endow that processor with the ability to store and process hybrid analog/digital data, which is the province of this invention.

We expect that these circuits will be fabricated as VLSI chips containing many analog functional blocks. Hence we envision the chip as being a configurable analog arrays (CAA). There is a currently vigorous research and development activity in the field of analog array processors [Mead, 1989; Gray, et al. 2001; Liu, et al., 2002]. Experience suggests the feasibility of an array of 10⁴ configurable analog blocks on a single chip [Twigg and Hasler, 2008].

### Nanoelectronics

The requirements for large numbers of modular circuits, with potentially many repetitions of identical or similar modules, and the need for high speed and interconnectivity, drive us to believe that the preferred technology for this invention is nanoelectronics.

### Nanoelectronic Devices

There is an extensive literature on nanoscale electronic devices. These devices have been developed extensively since the 1980s, and now offer a wide range of functionality [Kirk and M. Reed, 1992; H. Mizuta and T. Tanoue, 1995; Dragoman and Dragoman, 2006].

A typical nanoelectronic device is the resonant tunneling diode (RTD). This device consists of multiple nanoscale-thick layers of doped semiconductors. Application of a voltage V across the device causes current I(V) to flow, but the current is a highly nonlinear function of the voltage due to the quantization of energy levels in the very small structure. Combinations of tunnel-diode devices, easily achieved by stacking multiple layers, can produce compound characteristics that can approximate very complex mathematical functions. Discontinuities and hysteresis are commonly observed, and can be designed. RTDs and other nanoelectronic devices can be reliably manufactured with repeatable characteristics.

Besides RTDs, many other nanoelectronic device classes provide options for generating complex discontinuous functions, including quantum dots, superconducting quantum interference devices (SQUIDs), electrostatic corrals, and single-electron transistors. Many of these devices, as well as RTDs, can generate multi-peak functions representing a fairly high-order polynomial. For instance, devices that operate using coulomb blocking typically have a quasi-periodic I(V) characteristic.

### Nanoelectronic Circuits

Two aspects of nanoelectronic devices will be important to achieving a high-performance set-logic circuit: nonlinearity and discontinuities.

Nonlinearities result from the nanoscale atomic structure modifying the electron flow, generally referred to as quantum effects. It provides the opportunity to generate very complex functions with single, relatively simple devices.

Discontinuities result from extreme motion described as negative differential resistance. It can produce gaps in the I(V) curve, causing sudden switching between otherwise stable states. This can enable such devices to implement analog switches, and to represent sets with arbitrary mixtures of discrete and interval values.

Nonlinearities and discontinuities also enable simple nanoelectronic circuits that approximate standard analog computer modules. For example, an RTD can approximate an operational amplifier (OP AMP), which is useful as an analog signal processor. Consistent with the precision imposed by the analog circuits, such functional modules can be incorporated within the nanoelectronic circuits, requiring far less space, power, latency, and design effort.

### Advantages

Nanoelectronics offers significant advantages over microelectronics:

(1) Nano advantages: fewer devices, lower power, higher speed, simpler architecture, etc.;

(2) Logic advantages: intrinsic machine representation of data as analogues of human-meaningful entities, extremely high expressivity, universality, etc.

A major advantage of nanoelectronic devices is that they are more complicated than simple switches (used to implement digital computers) and linear amplifiers (used to implement analog computers). Using devices of greater complexity gives greater logic density and fewer devices in logically simpler arrays, and by using nanoscale devices we get reduced device size, increased device number, lower power, and higher speed.

### Disadvantages

Nanoelectronics has some disadvantages, including:

(1) The need for a conceptually new procedure for programming, control, monitoring, and evaluation of the performance;

(2) The relatively high expense of nanoelectronics;

(3) The need for devices to represent specific set data;

(4) The need for new design tools.

We believe that all of these can be overcome by engineering development.

### Alternative Technologies

The circuits described in this invention will be most efficient when cast into electronic circuits. However, these circuits could be fabricated using any analog medium capable of representing and manipulating quantities corresponding to the mathematical sets. This includes, but is not limited to optical, magnetic, fluid, and other media.

### Programming

Because this invention blurs the distinction between data and control, it blurs the distinction between programming and execution. If the processor reconfigures itself during a computation, it can be thought of as being reassembled or reprogrammed. In this invention, these distinctions lose their significance.

Thus, in order to use this invention efficiently, we should abandon the idea of setting up a problem and then solving it. Rather, we should think in terms of assembling a processor whose structure and functions are analogues of the system that defines the problem. Solutions to problems will therefore emerge as the collective behavior of the circuit, rather than from a set of initial conditions and a fixed algorithm producing a result. In this aspect, this invention is particularly suited to control, in which evolving conditions reconfigure the processor, which then gives new control signals.

### Discussion

In this section we provide remarks of a general nature to indicate expectations of the general nature, quality, advantages, performance, and applications of this invention.

### The Nature of Set Analogue Computing

We describe here some general properties of set analogue computing as implemented in this invention.

(1) If is neither numerical nor symbolical. One may ask whether set analogue computing is “numerical” or “symbolical.” In fact it is neither.

The data used by these analogue circuits are neither values nor symbols, but instances of sets of values. One may think of the data as being functions; the machine manipulates instances of functions.

As described above, computation is a series of aggregation/evaluation steps. Aggregation is always a set-level operation, hence it directly manipulates the entire function, without examining the values of the function (i.e., the members of the set). This particular process is more akin to symbolical manipulation than numerical, although it involves manipulation of the sets themselves, not symbols for the sets.

Evaluation, on the other hand, cannot always be done at the set-level: sometimes it may be necessary to examine selected members (subsets) of the sets. This process is more akin to numerical manipulation than symbolic, although it involves manipulation of quantities (subsets) that are not numbers.

In this sense, this invention defines a new class of data processing that is neither numerical nor symbolical. If “numerical” implies numbers and “symbolical” implies symbols, then perhaps the processing in this invention should be called “setical.”

(2) It is discrete/continuous hybrid. For a single variable, the most general data is a subset of the real numbers. Discrete values are Considered to be intervals of zero width. Such data has a hybrid character: it has a finite number of intervals, but the number of values within each interval is infinite. We have remarked above that this is both burden and opportunity: we must have a machine capable of manipulating such data (this invention), and it provides a means for extending solvable problems to new classes (e.g., interval-defined intractable problems).

(3) It can handle hybrid data format. A particularly difficult class of problems are those defined with mixed data and/or expressions. For instance, suppose we have a problem in which some entities are numbers, others are differential equations, others are intervals or fuzzy numbers, etc. By casting all these parts into Set Theory, the problem can be expressed in the uniform language that is implemented by this invention.

(4) It is adaptive. This invention blurs the distinction between data and control, which raises the opportunity for the computation to be adaptive, that is, the computation itself depends on the data. For small data/control variations, the circuit can respond with changes in the analog signals, e.g., if a set becomes too large the computation would limit further expansion. For larger data/control variations, we might change the topology of the circuit, thereby introducing large and sudden changes in the algorithm.

(5) It performs only necessary computation. In searching for sets that satisfy the given constraints, a computer built according to this invention will have the ability to recognize that a partial set is sufficient, hence will terminate evaluation of the complete set. Thus, the circuit will perform only the operations necessary to obtain the solution, and no more.

(6) It defines a universal computer. Any mathematical expression can be written in the language of Set Theory, hence in principle any mathematical problem that can be expressed in Set Theory could be cast into the circuit analogues described here. Therefore, this invention defines a universal computer.

However, this invention may be more efficient if it takes advantage of the formalism of a specific algebra. For example, if the sets are restricted to intervals of integral width, certain relations between the members of the sets, and between different sets, will be valid and can be exploited to make computations more efficient. In this case, the computer is not universal—it can solve only problems within the domain of such sets.

Thus, while this invention defines a universal computer in principle, in practice any particular implementation of this invention will necessarily be a specific-purpose computer, hence not universal. Commercial interests invariably dictate that an engineering compromise be found between casting the algorithms for a given problem class info special-purpose circuits on the one hand, and general-purpose circuits on the other.

### Fidelity of the Analogue

The question may be asked: How do we know that the circuit analogues faithfully represent the sets? For instance, suppose we construct a very complex circuit from many devices and sub-circuits as the analogue of a complex set expression. Is it guaranteed to have states in one-to-one correspondence with the members of the set?

The answer is yes, which follows from the argument:

First, the individual devices are analogues of sets, by definition and by design.

Second, connecting the devices together to implement the fundamental set operations creates circuits that are faithful analogues of the sets.

Finally, we could replace any circuit with its equivalent device, which then can be connected to other equivalent devices. Thus, at every hierarchical level, the circuit can be considered to be faithful set devices connected to form circuits that are faithful set analogue circuits. Ultimately, the entire circuit can be considered a single device that is the faithful analogue of the set represented by the set expression used to assemble the circuit.

### Modal Logic and Modal Circuits

This invention is based on conventional Set Theory, which is comprised of classical first-order logic plus one or another set of axioms enabled by introducing the membership relation x∈X. However, there is an extensive literature on non-classical logics, in particular modal logic, generally deriving from additional language constructs such as necessity. It is possible to extend the traditional Set-Theoretic interpretation of the propositional connectives [symbol] →, [symbol] to such additional operators. For instance, the modal operator for necessity ? can be identified as the power set [symbol] [Cantone, et al., 2001, p. 326]. We can call such theory modal Set Theories.

We may therefore ask whether we can establish circuit analogues of such additional operators, and the answer is yes. Thus, the circuit analogue given above for p⊂ [symbol] combined with a scanning module, can be used to search for, and identify all subsets of a given set, hence we can define a circuit analogue for this logical term.

We defined modal circuits as subsets of the full sets of physical variables defining the device. Therefore, there will be a direct correspondence between modal Set Theories and modal circuit analogues.

### Advantages

We reiterate here several advantages of the present invention.

(1) Simplification. One advantage will be that problem specification and casting the algorithm into hardware will be simplified, especially when the problem involves badly-behaved variables (which normally engender large numbers Of tests and branches). The analog circuits described in this invention will function automatically, without regard to whether or not the data is well-behaved.

(2) Parallel execution. Another advantage of using analog rather than digital circuits is that the computation can be (at least partially) converted from a serial (iterative) operation to a parallel one. That is, we achieve very high speed by implementing many copies of the same device or circuit module.

(3) Scalability. Another advantage of the present invention is the fact that it would be very difficult to assemble the device-level circuits without using the hierarchical analogues described herein. The present approach forms a set of functional blocks useful for assembling structures of arbitrary size, hence implements scalability, a key requirement for any large-scale computer.

### Disadvantages

We mention here several disadvantages of the present invention.

(1) Conceptual unfamiliarity. Conventionally, problem-specification is thought to require numbers, and problem-solving to require number manipulation. Efficient use of this invention will require overcoming this limiting concept.

(2) Lack of design tools. No software tools exist for effecting aggregation of these circuit modules, much less for designing circuits for evaluation. The full power of this invention will be appreciated only when effective design tools are developed.

(3) Potential inefficiency. This invention describes a universal computer. However, efficiency is obtained by exploiting additional relations that arise with specific data formats. For instance, interval sets and fuzzy sets generate different collections of relationship specific to these data formats. Circuits that do not exploit these forms will likely be less efficient than expected.

### Performance

In this invention, we have described a class of computers with internal states that are significantly more flexible than conventional computers. Such computers have the potential to be far more efficient in processing data for several reasons:

(1) The data are manipulated in significantly larger blocks;

(2) The manipulation is done with significantly less external control;

(3) Structure in-the data is converted to structure in the machine.

Computers built according to these principles thus are significantly more autonomous man stored-program computers—the entire machine is engaged in moving toward the solution, in contrast to developing the solution in small, pieces and sequential steps.

The advantage of using more complex devices to represent the fundamental logical data entities cannot be over-emphasized. If a single analog gate can store a set with the equivalent information of k bits, then N such gates can store information equivalent to k^{N} bits, Thus, a nanologic computer with N=10 gates, each with k=8 equivalent bits, would have slightly over 10⁹ times the logical capacity of a binary computer with the same number of gates. This indicates the enormous potential of analog circuits for storing and processing complex data. It is not unreasonable to expect speedup factors greater than a million.

This invention provides a means to implement machine-assisted computations in Set Theory. However, the actual performance of the circuits on any of these problems will, of course, depend on the detailed design of the circuits, and on the fabrication technology used to render them.

Because Set Theory is used to formulate all higher-level mathematical structures, this invention should have application to any problem that can be cast into the language of Set Theory. That is, this invention described a universal (analog) computer. However, set analog circuits may not be the most efficient means for performing any particular computation. Any mathematical system, say fuzzy sets, that has its Own algebra, may be more efficiently performed with circuits in which this algebra is built into the circuits.

### Appropriate Applications

Most human-important problems are qualitative: we neither have complete and precise input, nor do we want complete and precise output of instances of solutions. Rather, we need qualitative information about the system, its general dependence on controls, and discovery of unexpected features. Problems in the following areas are often of this kind: artistic expression, climate and weather, control, engineering, image processing, pattern recognition, language, medicine, politics, and psychology.

As an example, consider the challenge of planning for global climate change. This system has many aspects that would make it a good candidate for the kind of approach we describe in this invention. What we seek is relatively coarse simulations that generate scenarios, together with indicators of their dependence on controls (e.g., petroleum exhaustion, introduction of nuclear energy, deforestation, land use changes, etc.), rather than a detailed high-precision description of a single instance.

Appropriate applications for this invention will have the following characteristics:

(1) The problem is important;

(2) Input data is qualitative, incomplete, ambiguous, etc.;

(3) Physical models probably do not exist;

(4) The system behavior is complex;

(5) It has both local and global character;

(6) It involves numerous dynamic processes;

(7) The system may exhibit catastrophes or other discontinuities;

(8) The dynamics may involve periodicity, chaos, etc.;

(9) We can't solve the problem with conventional computers;

(10) The system behavior contains structure and recognizable patterns;

(11) We do not need or want detailed precise data as output;

(12) We are interested in understanding the system prerequisite to controlling it;

(13) We don't care about the details.

It may be asked how we can specify circuits and problems in this seemingly vague, nonspecific domain. The answer is inherent in the topological foundation of this approach: we are not demanding numerical agreement of a simulation with a real physical system, but the qualitative behavior of a set of systems connected by control parameters. Thus, we can be rather cavalier in the details—we can miss the behavior quantitatively by a lot—but we look for qualitative aspects of the behavior, in the hope arid expectation that the simulation will give us some insight into the behavior of the system and how to control it. We need not be concerned with whether the fragments agree in detail with a real physical system. Although this may sound hopelessly sloppy, it is not—it is in fact the central motive for attacking intractable simulations, namely to find out (roughly!) “what's happening.”

An example of an appropriate application is to the extension of traditional intractable problems, normally defined on discrete data, to multi-interval data.

Another example of an appropriate application is to problems with mixed data types. It will be common to include some constraints defined on discrete data and some constraints defined on continuous data, or some finite and some infinite sets.

### Mathematical Applications

In principle, this invention can be used for mathematical Theorem proving. However, because it operates by manipulating instances of sets, such computations are more similar to exhaustive search than to symbolic manipulation. This implies the possibility that such search would miss an exception, hence a theorem would be “proved” which in fact is not valid.

We therefore introduce the concept of domain-restricted proof, a theorem may be valid within a defined domain but not necessarily outside that domain. For example, the geometry in the vicinity of a point on a regular surface is Euclidian, but globally it is not. This invention would be able to demonstrate that a theorem is TRUE within the domain, but would be unable to make any statement about its validity outside the domain.

A closely related concept is approximate proof, a theorem might be valid for approximations to sets but not necessarily valid for the set itself. For example, the number of local maxima of a highly smoothed function might be a small number, but the function itself may have a large number of such local maxima. In implementing computation with this invention, we have described evaluation as a process of replacing a complex set with a simpler one. Thus, we can envision proving a theorem approximately by proving it for simplified sets.

### Conclusion

This invention traces it core advantage to topology: an analog circuit that is the topological equivalent of the system being simulated. It is the similarity between topology and human-important problems that enables this to be realized in practical circuits.

This invention represents a qualitative departure from conventional computer design, and rests on fundamental analogies between sets and the electrical behavior of devices. In particular, the invention is fundamentally based on the association of a set with a device, and on the definitions of the intersection, union, complement, and other relations. In comparison, digital computers are based on the ordered Boolean set <T,F>, and conventional analog computers are based on the analogy between circuits and expressions in calculus, e.g., addition, multiplication, integration, and differentiation.

It is emphasized that in this invention, the data are instances of sets, not members of sets and not symbols of sets. It is therefore hybrid, having a numerical character in dealing with instances, but a symbolic character in dealing with sets.

Practical realization of this invention will require development of inventories of functional analog modules mat implement the basic Set Theory relations, and combinations thereof that hierarchically implement complex structures, enabling scaling to arbitrary size. Due to the large number of devices and connections needed for such circuits, the use of nanoelectronic devices and circuits is indicated.

The circuits described herein will be most efficient when cast into electronic circuits. However, these circuits could be fabricated using any analog medium capable of representing and manipulating quantities corresponding to the mathematical sets. This includes, but is not limited to optical, magnetic, fluid, and other media.

### Bibliography

D. Cantone, E. Omodeo, and A. Policriti, Set Theory for Computing: From Decision Procedures to Declarative Programming with Sets, Springer, 2001.

M. Dragoman and D. Dragoman, Nanoelectronics: Principles and Devices, Artech, 2006.

M. R. Garey and D. S. Johnson, Computers and intractability: A Guide to the theory of NP-completeness, W. H. Freeman, San Francisco, 1979.

R. L. Geiger, P. E. Allen, and N. R. Strader, VLSI: Design Techniques for Analog and Digital Circuits, McGraw-Hill, 1990.

P. R. Gray, P. J. Hurst, S. H. Lewis, and R. G. Meyer, Analysis and Design of Analog Integrated Circuits, Wiley, 2001.

E. Hansen and G. W. Walster, Global Optimization using Interval Analysis, Marcel-Dekker, New York, 2004.

M. Hanss, Applied Fuzzy Arithmetic,Springer, New York, 2005.

P. Hasler, et al., U.S. Pat. App. Nos. 20070040712, 20070007999, 20060261846.

S. L. Hurst, VLSI Custom Microelectronics: Digital, Analog, and Mixed-Signal, Marcel-Dekker, 1999.

W. P. Kirk and M. Reed, Eds., Nanostructures and Mesoscopic Systems, Academic Press, 1992.

G. Klir and B. Yuan, Fuzzy Sets and Fuzzy Logic, Prentice Hall, 1995.

S. Liu, J. Kramer, G. Indiveri, T. Delbruck, and R. Douglas, Analog VLSI: Circuits and Principles, MIT, 2002.

N. Megill, Metamath, http://us.metamath.org.

C. Mead, Analog VLSI and Neural Systems, Addison-Wesley, 1989.

H. Mizuta and T. Tanoue, The Physics and Applications of Resonant Tunneling Diodes, Cambridge University Press, 1995.

C. E. Shannon, “Mathematical theory of the differential analyzer,” J. Math. Phys. MIT, 20:337, 1941.

M. P. Shaw, V. V. Mitin, E. Scholl, and H. L. Grubin, The Physics of Instabilities in Solid Sate Electronic Devices, Plenum, 1992.

R. R. Stoll, Set Theory and Logic, Dover Publications, Inc., 1979.

P. Suppes, Axiomatic Set Theory, Dover Publications, Inc., 1972.

R. W. Schmieder, U.S. patent application Ser. No. 12/284,640, 2009.

R. W. Schmieder, “Simulating Living Organisms with Populations of Point Vortices,”Sandia National Laboratories Report SAND8527, 1995.

R. W. Schmieder, “Metastable States and Intermittent Switching of Small Populations of Confined Point Vortices,” Sandia National Laboratories Report SAND95-8488, 1995.

R. W. Schmieder, “Population Dynamics of Minimally Cognitive Individuals. Part I: Introducing Knowledge Into the Dynamics,” Sandia National Laboratories Report SAND8505, 1995.

R. W. Schmieder, “Population Dynamics of Minimally Cognitive Individuals. Part II: Dynamics of Time-Dependent Knowledge,” Sandia National Laboratories Report SAND8489, 1995.

N. R. Scott, Analog and Digital Computer Technology, McGraw-Hill, 1960.

E. Tsang, “Foundations of Constraint Satisfaction,” available at; http://www.cs.essex.ac.uk/CSP/papers/Tsang-Fcs1993-Toc.pdf.

G. Timp, Nanotechnology, Springer, 1999.

C. Twigg and P. Hasler, “Configurable Analog Signal Processing,” 2008.

E. F. F. Zermelo, 1913. “On an Application of Set Theory to the Theory of the Game of Chess,” in Rasmusen E., Ed., Readings in Games and Information, Wiley-Blackwell: 79-82, 2001.

### FIGURE REFERENCES FOR CLAIMS

1. [Analogues, FIG. 1]
2. [Hierarchy, FIG. 32]
3. [Discrete sets, FIGS. 10,11,12,15]
4. [Interval sets, FIGS. 8,13]
5. [Hybrid sets, FIGS. 7B,44C]
6. [Fuzzy sets]
7. [Set bits, FIG. 41]
8. [Ordered sets, FIG. 42]
9. [Boolean, FIG. 34]
10. [Membership, FIG. 18]
11. [2-terminal devices, FIG. 19 ]
12. [Current-mode intersection, FIG. 20]
13. [Voltage-mode intersection, FIG. 20]
14. [Current-mode union, FIG. 21]
15. [Voltage-mode union, FIG. 21]
16. [Complement, FIG. 22B]
17. [Set Difference, FIG. 23]
18. [Symmetric set difference, FIG. 24]
19. [Set equality, FIG. 25]
20. [Subset, FIG. 26]
21. [Proper subset, FIG. 27]
22. [Mixed-mode, FIG. 43]
23. [Analog circuits]
24. [Nanoelectronics]
25. [Method]

What is claimed is:

1. Circuits for Computational Set Theory, comprising:
(a) A set of individual electronic circuit modules, each with one or more inputs arid one or more outputs,
said inputs and outputs constituting a set of circuit variables,
said circuit variables comprising experimentally accessible electronic quantities such as voltage and/or current,
said circuit modules being joined by connections between the outputs of preceding circuit modules and the inputs of succeeding circuit modules to form complete circuits,
said connections implementing equality of outputs of one module and inputs of another module,
said circuit modules and said connections being chosen such that said complete circuits are the analogues of expressions in Set Theory,
said analogues defined as one-to-one correspondence between some or all of said circuit variables and some or all of the parts of said expressions in Set Theory,
(b) means for establishing values of a subset of said circuit variables thereby constituting a set of independent variables, and
means for measuring values of the complementary subset of said circuit variables thereby constituting a set of dependent variables, and
means for determining functional relationships between said independent variables and said dependent variables, said functional relationships constituting computation;
whereby said Computational Set Theory is accomplished.

2. The circuits recited in claim 1, wherein said modules are comprised of one or more modules.

3. The circuits recited in claim 2, wherein the circuits are analogues of sets having only discrete values.

4. The circuits recited in claim 2, wherein the circuits are analogues of sets having one or more continuous intervals.

5. The circuits recited in claim 2, wherein the circuits are analogues of hybrid sets having some discrete values and some continuous intervals.

6. The circuits recited in claim 2, wherein the circuits are analogues of fuzzy sets.

7. The circuits recited in claim 2, wherein the circuit is in the form of two modules and a switch used to connect either of the modules to the output, the output thereby being the analogue of either one module or the other, the circuit thereby constituting the analogue of a set bit.

8. The circuits recited in claim 2, wherein the circuit is in the form of two modules A,B and three switches used to connect both modules to the output as the analogue of the intersection A∩B, or just A, or just B, or both modules as the analogue of their union A∪B, the output thereby being the analogue of the ordered set <A∩B,A,B,A∪B>.

9. The circuits recited in claim 2, wherein the circuit is in the form of one or more modules, each module having a single Boolean output, all said Boolean outputs being used as inputs to a logical gate whose output is a Boolean function <T,F> of the inputs.

10. The circuits recited in claim 2, wherein one or more of said modules have means to detect time-variation in the value of one or more circuit variables, and means to set one or more outputs to zero if such variation is detected, the result being a module that has nonzero output only if it is static, thereby implementing the membership relation in Set Theory x∈X.

11. The circuits recited in claim 2, wherein said modules are 2-terminal devices defined by the relationship between the two terminal voltages and the current through the device.

12. The circuits recited in claim 11, wherein 2 devices are connected in series so that the current through both devices is the current analogue of the intersection of the sets represented by the individual devices.

13. The circuits recited in claim 11, wherein 2 devices are connected in parallel so that the voltage across both devices is the voltage analogue of the intersection of the sets represented by the individual devices.

14. The circuits recited in claim 11, wherein 2 devices that are the current analogues of 2 individual sets are connected together to form a total output current, and a current sensor is provided on the output of one device and used to open a switch zeroing the output current from the other device, such that the total output current is either the current through one device or the current through the other device, the entire circuit being the current analogue of the union of the sets represented by the individual devices.

15. The circuits recited in claim 11, wherein 2 devices that are the voltage analogues of 2 individual sets are connected together to form a total output voltage, and a voltage sensor is provided across the output of one device and used to close a switch zeroing the output voltage across the other device, such that the total output voltage is either the voltage across one device or the voltage across the other device, the entire circuit being the voltage analogue of the union of the sets represented by the individual devices.

16. The circuits recited in claim 11, wherein one clone of a device that is the analogue of an argument set and one clone of a configurable device are combined to form the analogue intersection set, and a second clone of said device that is the analogue of said argument set and a second clone of said configurable device are combined to form the analogue union set, the outputs of said intersection analogue and said union analogue being sensed and used to activate a control module that reconfigures the configurable device clones whenever either the intersection or the union is non-null, said control module also configuring a third clone of said configurable device, the output from said third clone being the analogue of the complement of the argument set.

17. The circuits recited in claim 11, wherein a device that is the analogue of an argument set and a circuit that is the analogue of the complement of another argument set are combined to form the analogue of the intersection set, the output from said circuit being the analogue of the difference of the two argument sets.

18. The circuits recited in claim 11, wherein the circuit that is the analogue of the set difference of two argument sets and the circuit that is the analogue of the set difference of the interchanged two argument sets are combined to form the analogue of the symmetric difference of the two argument sets.

19. The circuits recited in claim 11, wherein a sensor is used to sense the output of the circuit that is the analogue of the symmetric set difference of two argument sets, said sensor providing a null signal if the two argument sets are equal.

20. The circuits recited in claim 11, wherein a sensor is used to sense the output of the circuit that is the analogue of the difference of two argument sets as described in claim 10, said sensor providing a null signal if the first argument set is a subset of the second argument set.

21. The circuits recited in claim 11, wherein a sensor is used to sense the output of the circuit that is the analogue of the union of two compound sets, the first said compound set being the difference of two argument sets and the second said compound set being the symmetric difference of the same two argument sets, said sensor providing a null signal if the first argument set is a proper subset of the second argument set.

22. The circuits recited in claim 2, wherein the circuit contains portions that are current-mode and portions that are voltage-mode.

23. The circuits recited in claim 2, wherein the transfer functions of the variables are effected with circuits that are primarily analog.

24. The circuits recited in claim 2, wherein some or all of the transfer functions of the variables are effected with circuits incorporating nanoelectronics.

25. A method for Computational Set Theory, comprising:
(a) providing a set of individual electronic circuit modules, each with one or more inputs and one or more outputs,
said inputs and outputs constituting a set of circuit variables,
said circuit variables comprising experimentally accessible electronic quantities such as voltage and/or current,
providing said circuit modules to be joined by connections between the outputs of preceding circuit modules and the inputs of succeeding circuit modules to form complete circuits,
said connections implementing equality of outputs of one module and inputs of another module,
said circuit modules and said connections being chosen such that said complete circuits are the analogues of expressions in Set Theory,
said analogues defined as one-to-one correspondence between some or all of said circuit variables and some or all of the parts of said expressions in Set Theory,
(b) providing means for establishing values of a subset of said circuit variables thereby constituting a set of independent variables, and
providing means for measuring values of the complementary subset of said circuit variables thereby constituting a set of dependent variables> and
providing means for determining functional relationships between said independent variables and said dependent variables, said functional relationships constituting computation;
whereby said Computational Set Theory is accomplished.
